(19) United States
(12) Patent Application Publication
(10) Pub. No.: US 2024/0072537 A1
(43) Pub. Date: Feb. 29, 2024

(54) ENERGY SYSTEM ISLANDING DETECTION

(71) Applicant: TAE Technologies, Inc., Foothill Ranch, CA (US)

(72) Inventors: Edwin Fonkwe Fongang, Moreno Valley, CA (US); Hessamaldin Abdollahi, Alisa Viejo, CA (US)

(21) Appl. No.: 18/453,902

(22) Filed: Aug. 22, 2023

Related U.S. Application Data
(60) Provisional application No. 63/400,140, filed on Aug. 23, 2022.

(51) Int. Cl. H02J 3/00; G01R 31/40; H02J 3/01; H02J 3/38

(52) U.S. Cl. CPC H02J 3/0012; G01R 31/40; H02J 3/01; H02J 3/388

(57) ABSTRACT

Systems, devices, and methods for energy systems that include one or more modules are configured to connect to a power grid. Each module outputs a respective voltage waveform and/or a current waveform to a load. A controller is configured to periodically cause at least a portion of the one or more modules to output an increased voltage and/or current level at a specified harmonic frequency. An islanding detector is configured to detect, based on an impedance of the grid, when the one or more modules are in an island condition.

### FIELD

This specification relates generally to energy systems, and systems, devices, and methods for detecting islanding conditions.

### BACKGROUND

In electrical engineering, power engineering, and the electric power industry, power conversion is converting electric energy from one form to another, e.g., converting between AC and DC, adjusting the voltage or frequency, or some combination of these. A power converter is an electrical or electro-mechanical device for converting electrical energy. A power converter can be as simple as a transformer to change the voltage of AC (e. g., alternating current) power, but can also be implemented using far more complex systems. The term “power converter” can also refer to a class of electrical machinery that is used to convert one frequency of alternating current into another frequency. Power conversion systems often incorporate redundancy and voltage regulation.

Safety standards for grid support utility interactive inverters typically require that the inverter should cease energizing and disconnect from the area electric power system (AEPS) when an unintentional islanding condition occurs. This is often referred to as anti-islanding protection. An islanding condition is a condition in which a portion of the AEPS is energized solely by a local electronic power system (EPS) while that portion is electrically isolated from the other portions of the AEPS.

### SUMMARY

Techniques for detecting islanding conditions can be broadly classified into three categories, including passive, active, and communications-based. In the active category, harmonic-injection is one of the common approaches. Harmonic-injection islanding detection increases the harmonic content of the output waveform leading to higher total harmonic distortion (THD). Increased THD results in several performance degradations for an EPS, including lower power factor, higher peak currents, and lower efficiency.

This specification describes example implementations of systems, devices, and methods for module-based energy systems widely relevant to many applications and that include a device configured to detect islanding conditions. For example, a master control device can detect islanding conditions by causing each, or at least one, module of an array of cascaded modules to periodically inject an additional harmonic signal, e.g., harmonic current and/or harmonic voltage, on its output, and measuring an output impedance of the converters of the modules at the harmonic frequency. The described methods and systems for detecting islanding conditions can be used in other inverter topologies besides an array of cascaded modules. By injecting the harmonic signal periodically rather than continuously, the accuracy of the island detection is increased and THD introduced by the harmonic signal is reduced.

The master control device is configured to generate control information that includes a normalized reference signal for each module and a modulation index for at least one of the modules. One or more modules can be associated with and controlled by one or more local control devices configured to scale the normalized reference signal using its modulation index, e.g., dividing the reference signal by a peak value prior to outputting the reference signal to adjust a magnitude of the reference signal. To inject the harmonic signal for islanding detection, the master control device can adjust the control information to cause the local control device to adjust the switching of its module(s) to increase the amplitude of the current at the harmonic frequency.

When an islanding condition is detected, the master control device disconnects the array of cascaded modules from the grid and switches from current control mode to voltage control mode. In the voltage control mode, the master control device causes the modules to output a waveform that follows the last normal voltage, frequency, and phase of the grid. When the grid returns to normal operation, the master control module reconnects the array of cascaded modules to the grid and returns to current control mode based on the current voltage, frequency, and phase of the grid. Current controllers of the master control device adjust the fundamental current based on the demand of the load and a harmonic current controller injects the harmonic current periodically for islanding condition detection.

Other systems, devices, methods, features and advantages of the subject matter described herein will be or will become apparent to one with skill in the art upon examination of the following figures and detailed description.

### BRIEF DESCRIPTION OF FIGURES

FIGS. 1A-1C are block diagrams depicting examples of a modular energy system.

FIGS. 1D-1E are block diagrams depicting examples of control devices for an energy system.

FIGS. 1F-1G are block diagrams depicting examples of modular energy systems coupled with a load and a charge source.

FIGS. 2A-2B are block diagrams depicting examples of a module and control system within an energy system.

FIG. 2C is a block diagram depicting an example of a physical configuration of a module.

FIG. 2D is a block diagram depicting an example of a physical configuration of a modular energy system.

FIGS. 3A-3C are block diagrams depicting examples of modules having various electrical configurations.

FIGS. 4A-4F are schematic views depicting examples of energy sources.

FIGS. 5A-5C are schematic views depicting examples of energy buffers.

FIGS. 6A-6C are schematic views depicting examples of converters.

FIGS. 7A-7E are block diagrams depicting examples of modular energy systems having various topologies.

FIG. 8A is a plot depicting an example output voltage of a module.

FIG. 8B is a plot depicting an example multilevel output voltage of an array of modules.

FIG. 8C is a plot depicting an example reference signal and carrier signals usable in a pulse width modulation control technique.

FIG. 8D is a plot depicting example reference signals and carrier signals usable in a pulse width modulation control technique.

FIG. 8E is a plot depicting example switch signals generated according to a pulse width modulation control technique.

FIG. 8F as a plot depicting an example multilevel output voltage generated by superposition of output voltages from an array of modules under a pulse width modulation control technique.

FIGS. 9A-9B are block diagrams depicting examples of controllers for a modular energy system.

FIG. 10A is a block diagram depicting an example of a multiphase modular energy system having interconnection module.

FIG. 10B is a schematic diagram depicting an example of an interconnection module in the multiphase example of FIG. 10A.

FIG. 10C is a block diagram depicting an example of a modular energy system having two subsystems connected together by interconnection modules.

FIG. 10D is a block diagram depicting an example of a three-phase modular energy system having interconnection modules supplying auxiliary loads.

FIG. 10E is a schematic view depicting an example of the interconnection modules in the multiphase example of FIG. 10D.

FIG. 10F is a block diagram depicting another example of a three-phase modular energy system having interconnection modules supplying auxiliary loads.

FIG. 11A is a block diagram depicting an example of grid-connected system in which an energy system is connected to a load and a grid.

FIG. 11B is an electrical equivalence diagram depicting the example of the grid-connected system in which an energy system is connected to a load and a grid.

FIGS. 12A-12B are block diagrams depicting examples of master control devices.

FIG. 13 is a block diagram of an example of an islanding detector.

FIG. 14 is a flow diagram depicting an example of a method of detecting islanding conditions and operating an energy system based on whether an islanding condition is detected.

FIG. 15 is a flow diagram depicting an example of a method of adjusting control information for one or more modules to inject a perturbation on the output of the module(s).

### DETAILED DESCRIPTION

Before the present subject matter is described in detail, it is to be understood that this disclosure is not limited to the particular examples described. The terminology used herein is for the purpose of describing particular examples only, and is not intended to be limiting, since the scope of the present disclosure will be limited only by the appended claims.

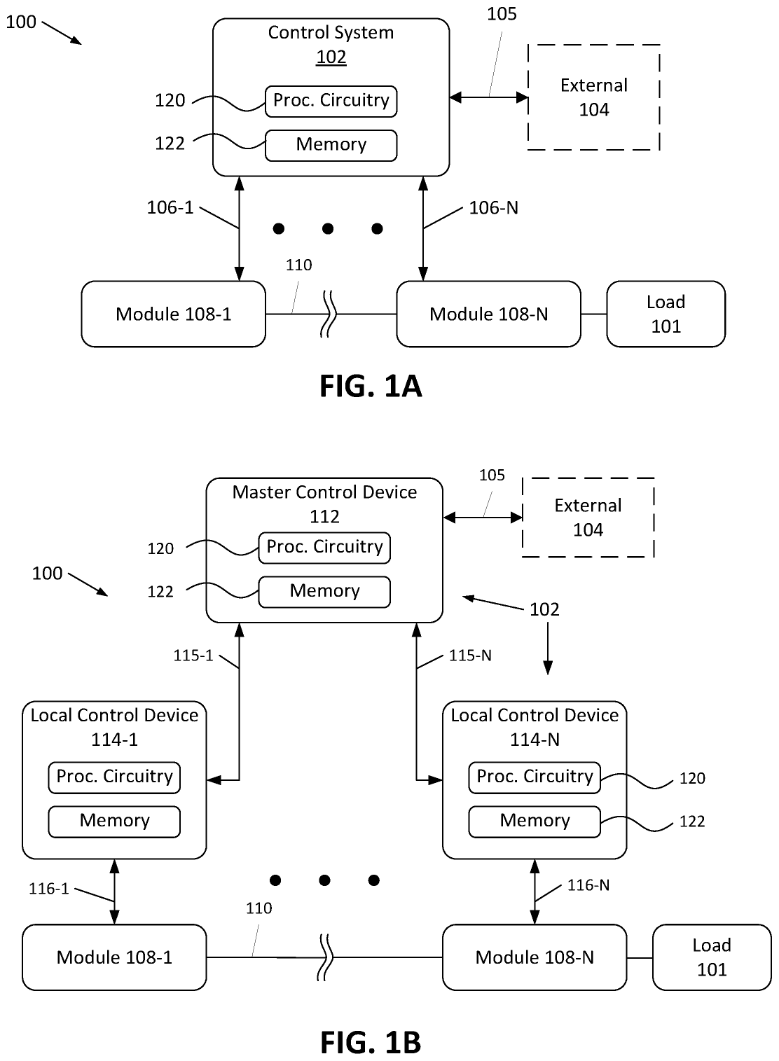

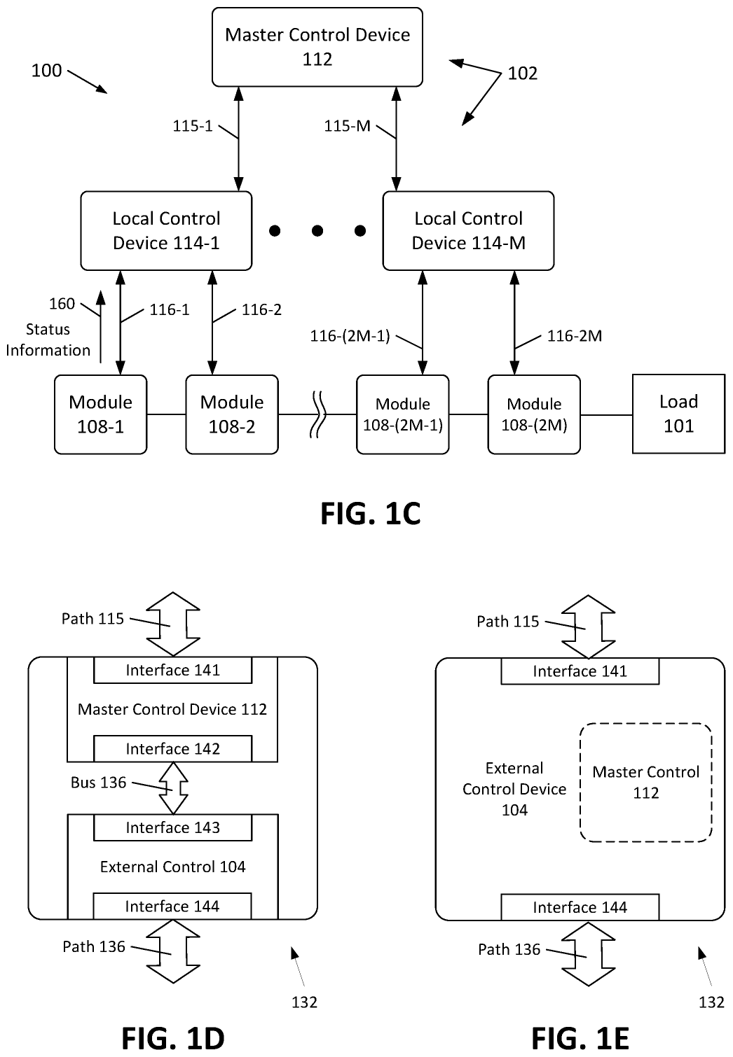

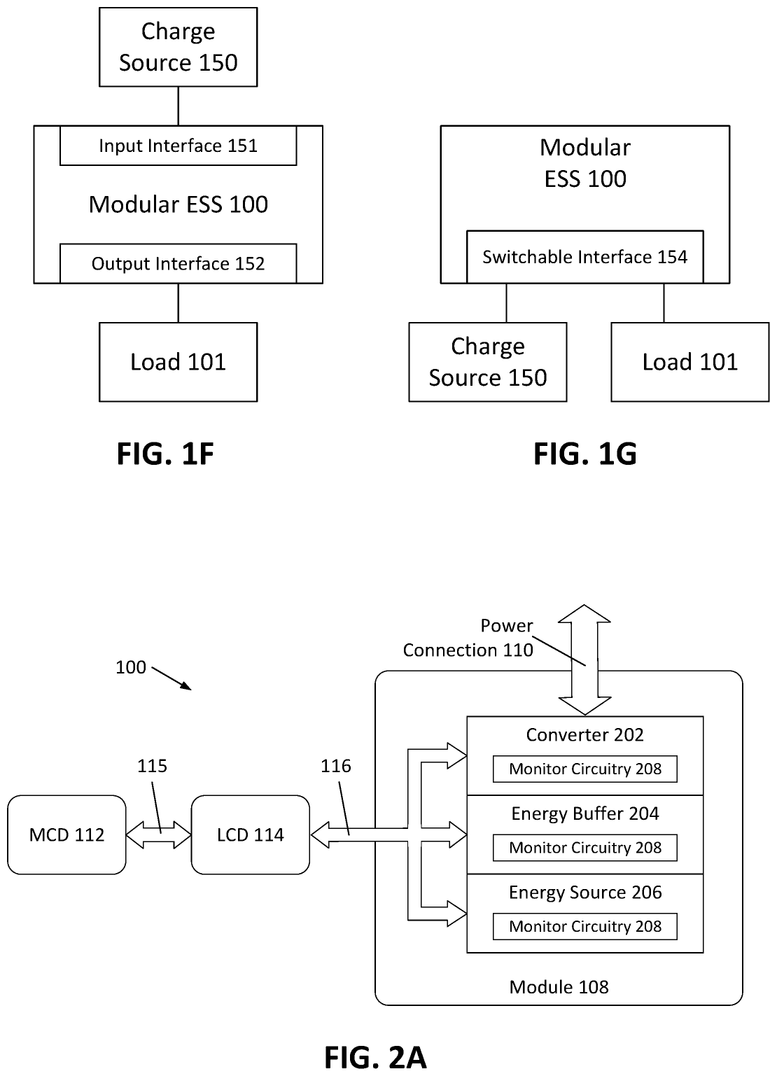

Before describing the example implementations pertaining to modular energy systems and their communication interfaces, it is first useful to describe these underlying systems in greater detail. With reference to FIGS. 1A through 10F, the following sections describe various applications in which examples of the modular energy systems can be implemented, examples of control systems or devices for the modular energy systems, configurations of the modular energy system examples with respect to charging sources and loads, examples of individual modules, examples of topologies for arrangement of the modules within the systems, examples of control methodologies, examples of balancing operating characteristics of modules within the systems, and examples of the use of interconnection modules.

### Examples of Applications

Stationary applications are those in which the modular energy system is located in a fixed location during use, although it may be capable of being transported to alternative locations when not in use. The module-based energy system resides in a static location while providing electrical energy for consumption by one or more other entities, or storing or buffering energy for later consumption. Examples of stationary applications include, but are not limited to: energy systems for use by or within one or more residential structures or locales, energy systems for use by or within one or more industrial structures or locales, energy systems for use by or within one or more commercial structures or locales, energy systems for use by or within one or more governmental structures or locales (including both military and non-military uses), energy systems for charging the mobile applications described below (e.g., a charge source or a charging station), and systems that convert solar power, wind, geothermal energy, fossil fuels, or nuclear reactions into electricity for storage. Stationary applications often supply loads such as grids and microgrids, motors, and data centers. A stationary energy system can be used in either a storage or non-storage role.

Mobile applications, sometimes referred to as traction applications, are generally ones where a module-based energy system is located on or within an entity, and stores and provides electrical energy for conversion into motive force by a motor to move or assist in moving that entity. Examples of mobile entities include, but are not limited to, electric and/or hybrid entities that move over or under land, over or under sea, above and out of contact with land or sea (e.g., flying or hovering in the air), or through outer space. Examples of mobile entities also include, but are not limited to, vehicles, trains, trams, ships, vessels, aircraft, and spacecraft. Examples of mobile vehicles include, but are not limited to, those having only one wheel or track, those having only two-wheels or tracks, those having only three wheels or tracks, those having only four wheels or tracks, and those having five or more wheels or tracks. Examples of mobile entities also include, but are not limited to, a car, a bus, a truck, a motorcycle, a scooter, an industrial vehicle, a mining vehicle, a flying vehicle (e.g., a plane, a helicopter, a drone, etc.), a maritime vessel (e.g., commercial shipping vessels, ships, yachts, boats or other watercraft), a submarine, a locomotive or rail-based vehicle (e.g., a train, a tram, etc.), a military vehicle, a spacecraft, and a satellite.

In this specification, reference may be made to a particular stationary application (e.g., grid, micro-grid, data centers, cloud computing environments) or mobile application (e.g., an electric car). Such references are made for ease of explanation and do not mean that a particular implementation is limited for use to only that particular mobile or stationary application. Implementations of systems providing power to a motor can be used in both mobile and stationary applications. While certain configurations may be more suitable to some applications over others, all example implementations disclosed herein are capable of use in both mobile and stationary applications unless otherwise noted.

### Module-Based Energy System Examples

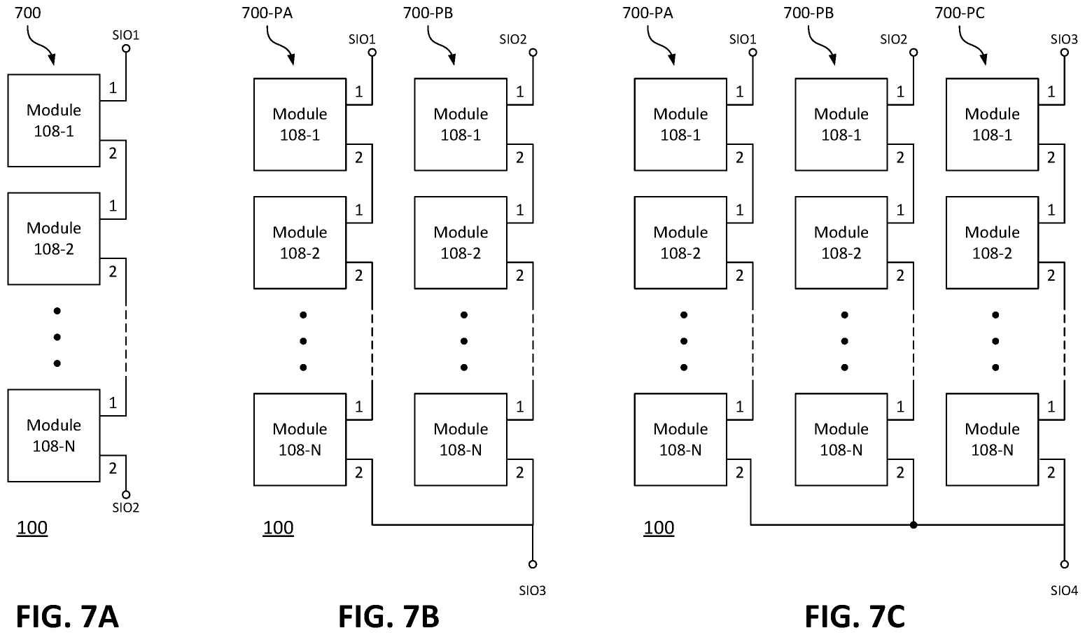

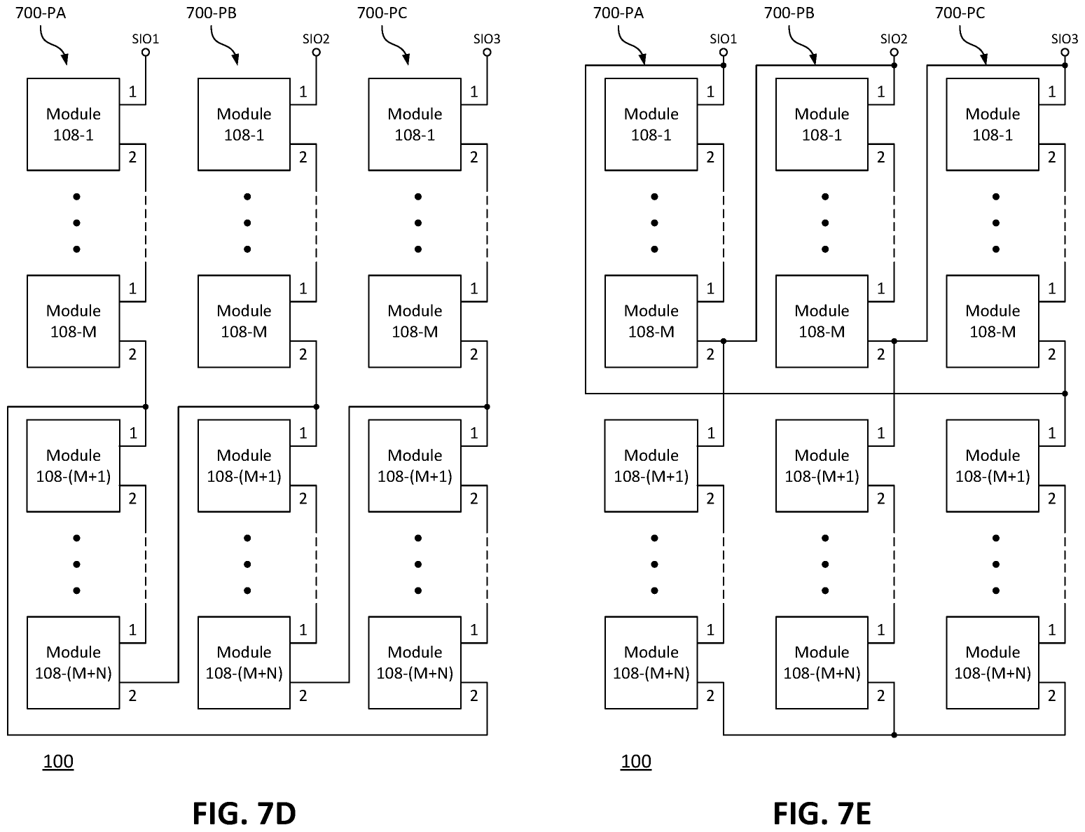

FIG. 1A is a block diagram depicts an example of a module-based energy system 100. Here, system 100 includes control system 102 communicatively coupled with N converter-source modules 108-1 through 108-N, over communication paths or links 106-1 through 106-N, respectively. Modules 108 are configured to store energy and output the energy as needed to a load 101 (or other modules 108). In these implementations, any number of two or more modules 108 can be used (e.g., N is greater than or equal to two). Modules 108 can be connected to each other in a variety of manners as will be described in more detail with respect to FIGS. 7A-7E. For ease of illustration, in FIGS. 1A-1C, modules 108 are shown connected in series, or as a one dimensional array, where the Nth module is coupled to load 101.

System 100 is configured to supply power to load 101. Load 101 can be any type of load such as a motor or a grid 1130. System 100 is also configured to store power received from a charge source. FIG. 1F is a block diagram depicting an example of system 100 with a power input interface 151 for receiving power from a charge source 150 and a power output interface for outputting power to load 101. In this implementation system 100 can receive and store power over interface 151 at the same time as outputting power over interface 152. FIG. 1G is a block diagram depicting another example of system 100 with a switchable interface 154. In this implementation, system 100 can select, or be instructed to select, between receiving power from charge source 150 and outputting power to load 101. System 100 can be configured to supply multiple loads 101, including both primary and auxiliary loads, and/or receive power from multiple charge sources 150 (e.g., a utility-operated power grid 1130 and a local renewable energy source (e.g., solar)).

FIG. 1B depicts another example of system 100. Here, control system 102 is implemented as a master control device (MCD) 112 communicatively coupled with N different local control devices (LCDs) 114-1 through 114-N over communication paths or links 115-1 through 115-N, respectively. Each LCD 114-1 through 114-N is communicatively coupled with one module 108-1 through 108-N over communication paths or links 116-1 through 116-N, respectively, such that there is a 1:1 relationship between LCDs 114 and modules 108. In some implementations, two or more modules 108 can share an LCD 114.

FIG. 1C depicts another example of system 100. Here, MCD 112 is communicatively coupled with M different LCDs 114-1 to 114-M over communication paths or links 115-1 to 115-M, respectively. Each LCD 114 can be coupled with and control two or more modules 108. In the example shown here, each LCD 114 is communicatively coupled with two modules 108, such that M LCDs 114-1 to 114-M are coupled with 2M modules 108-1 through 108-2M over communication paths or links 116-1 to 116-2M, respectively.

Control system 102 can be configured as a single device (e.g., FIG. 1A) for the entire system 100 or can be distributed across or implemented as multiple devices (e.g., FIGS. 1B-1C). In some implementations, control system 102 can be distributed between LCDs 114 associated with the modules 108, such that no MCD 112 is necessary and can be omitted from system 100.

Control system 102 can be configured to execute control using software (instructions stored in memory that are executable by processing circuitry), hardware, or a combination thereof. The one or more devices of control system 102 can each include processing circuitry 120 and memory 122 as shown here. Example implementations of processing circuitry and memory are described further below.

Control system 102 can have a communicative interface for communicating with devices 104 external to system 100 over a communication link or path 105. For example, control system 102 (e.g., MCD 112) can output data or information about system 100 to another control device 104 (e.g., the Electronic Control Unit (ECU) or Motor Control Unit (MCU) of a vehicle in a mobile application, grid controller in a stationary application, etc.).

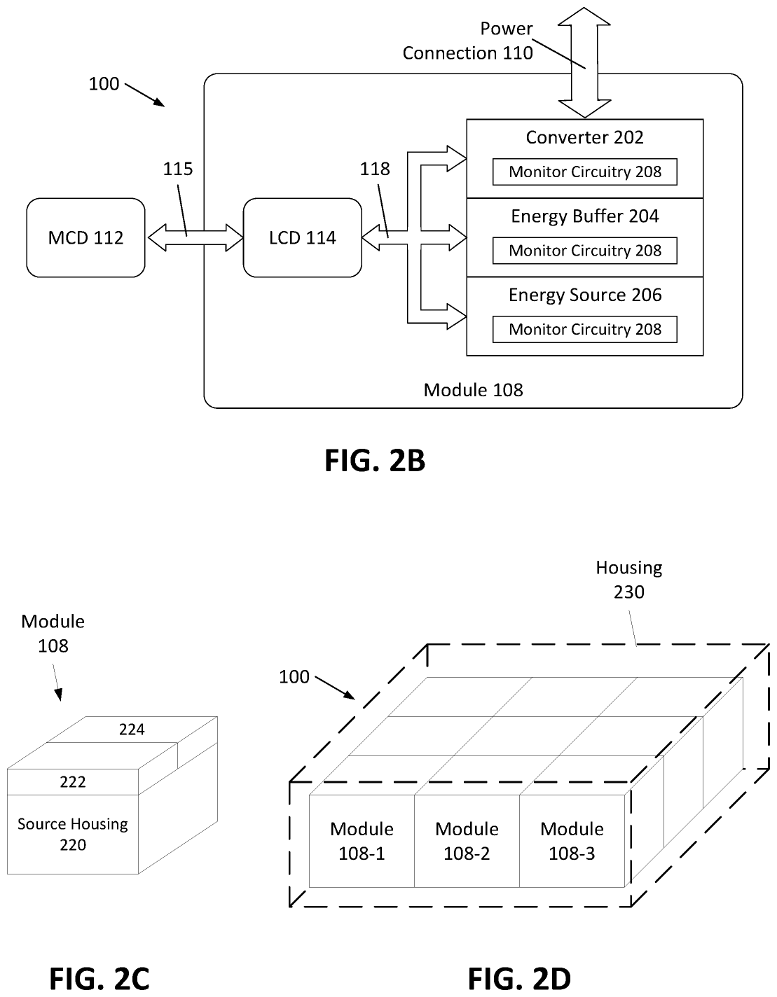

Communication paths or links 105, 106, 115, 116, and 118 (FIG. 2B) can each be wired (e.g., electrical, optical) or wireless communication paths that communicate data or information bidirectionally, in parallel or series fashion. Data can be communicated in a standardized (e.g., IEEE, ANSI) or custom (e.g., proprietary) format. In automotive applications, communication paths 115 can be configured to communicate according to FlexRay or CAN protocols. Communication paths 106, 115, 116, and 118 can also provide wired power to directly supply the operating power for system 102 from one or more modules 108. For example, the operating power for each LCD 114 can be supplied only by the one or more modules 108 to which that LCD 114 is connected and the operating power for MCD 112 can be supplied indirectly from one or more of modules 108 (e.g., such as through a car's power network).

Control system 102 is configured to control one or more modules 108 based on status information received from the same or different one or more of modules 108. Control can also be based on one or more other factors, such as requirements of load 101. Controllable aspects include, but are not limited to, one or more of voltage, current, phase, and/or output power of each module 108.

Status information of every module 108 in system 100 can be communicated to control system 102, which can independently control every module 108-1 . . . 108-N. Other variations are possible. For example, a particular module 108 (or subset of modules 108) can be controlled based on status information of that particular module 108 (or subset), based on status information of a different module 108 that is not that particular module 108 (or subset), based on status information of all modules 108 other than that particular module 108 (or subset), based on status information of that particular module 108 (or subset) and status information of at least one other module 108 that is not that particular module 108 (or subset), or based on status information of all modules 108 in system 100.

The status information can be information about one or more aspects, characteristics, or parameters of each module 108. Types of status information include, but are not limited to, the following aspects of a module 108 or one or more components thereof (e.g., energy source, energy buffer, converter, monitor circuitry): State of Charge (SOC) (e.g., the level of charge of an energy source relative to its capacity, such as a fraction or percent) of the one or more energy sources of the module, State of Health (SOH) (e.g., a figure of merit of the condition of an energy source compared to its ideal conditions) of the one or more energy sources of the module, temperature of the one or more energy sources or other components of the module, capacity of the one or more energy sources of the module, voltage of the one or more energy sources and/or other components of the module, current of the one or more energy sources and/or other components of the module, State of Power (SOP) (e.g., the available power limitation of the energy source during discharge and/or charge), State of Energy (SOE) (e.g., the present level of available energy of an energy source relative to the maximum available energy of the source), and/or the presence of absence of a fault in any one or more of the components of the module.

LCDs 114 can be configured to receive the status information from each module 108, or determine the status information from monitored signals or data received from or within each module 108, and communicate that information to MCD 112. In some implementations, each LCD 114 can communicate raw collected data to MCD 112, which then algorithmically determines the status information on the basis of that raw data. MCD 112 can then use the status information of modules 108 to make control determinations accordingly. The determinations may take the form of instructions, commands, or other information (such as a modulation index described herein) that can be utilized by LCDs 114 to either maintain or adjust the operation of each module 108.

For example, MCD 112 may receive status information and assess that information to determine a difference between at least one module 108 (e.g., a component thereof) and at least one or more other modules 108 (e.g., comparable components thereof). For example, MCD 112 may determine that a particular module 108 is operating with one of the following conditions as compared to one or more other modules 108: with a relatively lower or higher SOC, with a relatively lower or higher SOH, with a relatively lower or higher capacity, with a relatively lower or higher voltage, with a relatively lower or higher current, with a relatively lower or higher temperature, or with or without a fault. In such examples, MCD 112 can output control information that causes the relevant aspect (e.g., output voltage, current, power, temperature) of that particular module 108 to be reduced or increased (depending on the condition). In this manner, the utilization of an outlier module 108 (e.g., operating with a relatively lower SOC or higher temperature), can be reduced so as to cause the relevant parameter of that module 108 (e.g., SOC or temperature) to converge towards that of one or more other modules 108.

The determination of whether to adjust the operation of a particular module 108 can be made by comparison of the status information to predetermined thresholds, limits, or conditions, and not necessarily by comparison to statuses of other modules 108. The predetermined thresholds, limits, or conditions can be static thresholds, limits, or conditions, such as those set by the manufacturer that do not change during use. The predetermined thresholds, limits, or conditions can be dynamic thresholds, limits, or conditions, that are permitted to change, or that do change, during use. For example, MCD 112 can adjust the operation of a module 108 if the status information for that module 108 indicates it to be operating in violation (e.g., above or below) of a predetermined threshold or limit, or outside of a predetermined range of acceptable operating conditions. Similarly, MCD 112 can adjust the operation of a module 108 if the status information for that module 108 indicates the presence of an actual or potential fault (e.g., an alarm, or warning) or indicates the absence or removal of an actual or potential fault. Examples of a fault include, but are not limited to, an actual failure of a component, a potential failure of a component, a short circuit or other excessive current condition, an open circuit, an excessive voltage condition, a failure to receive a communication, the receipt of corrupted data, and the like. Depending on the type and severity of the fault, the faulty module's utilization can be decreased to avoid damaging the module, or the module's utilization can be ceased altogether. For example, if a fault occurs in a given module, then MCD 112 or LCD 114 can cause that module to enter a bypass state as described herein.

MCD 112 can control modules 108 within system 100 to achieve or converge towards a desired target. The target can be, for example, operation of all modules 108 at the same or similar levels with respect to each other, or within predetermined thresholds limits, or conditions. This process is also referred to as balancing or seeking to achieve balance in the operation or operating characteristics of modules 108. The term “balance” as used herein does not require absolute equality between modules 108 or components thereof, but rather is used in a broad sense to convey that operation of system 100 can be used to actively reduce disparities in operation (or operative state) between modules 108 that would otherwise exist.

MCD 112 can communicate control information to LCD 114 for the purpose of controlling the modules 108 associated with the LCD 114. The control information can be, e.g., a modulation index and a reference signal as described herein, a reference signal, or otherwise. Each LCD 114 can use (e.g., receive and process) the control information to generate switch signals that control operation of one or more components (e.g., a converter) within the associated module(s) 108. In some implementations, MCD 112 generates the switch signals directly and outputs them to LCD 114, which relays the switch signals to the intended module component.

All or a portion of control system 102 can be combined with a system external control device 104 that controls one or more other aspects of the mobile or stationary application. When integrated in this shared or common control device (or subsystem), control of system 100 can be implemented in any desired fashion, such as one or more software applications executed by processing circuitry of the shared device, with hardware of the shared device, or a combination thereof. Non-exhaustive examples of external control devices 104 include: a vehicular ECU or MCU having control capability for one or more other vehicular functions (e.g., motor control, driver interface control, traction control, etc.); a grid or micro-grid controller having responsibility for one or more other power management functions (e.g., load interfacing, load power requirement forecasting, transmission and switching, interface with charge sources (e.g., diesel, solar, wind), charge source power forecasting, back up source monitoring, asset dispatch, etc.); and a data center control subsystem (e.g., environmental control, network control, backup control, etc.).

FIGS. 1D and 1E are block diagrams depicting examples of a shared or common control device (or system) 132 in which control system 102 can be implemented. In FIG. 1D, common control device 132 includes master control device 112 and external control device 104. Master control device 112 includes an interface 141 for communication with LCDs 114 over path 115, as well as an interface 142 for communication with external control device 104 over internal communication bus 136. External control device 104 includes an interface 143 for communication with master control device 112 over bus 136, and an interface 144 for communication with other entities (e.g., components of the vehicle or grid 1130) of the overall application over communication path 136. In some implementations, common control device 132 can be integrated as a common housing or package with devices 112 and 104 implemented as discrete integrated circuit (IC) chips or packages contained therein.

In FIG. 1E, external control device 104 acts as common control device 132, with the master control functionality implemented as a component within device 104. This component 112 can be or include software or other program instructions stored and/or hardcoded within memory of device 104 and executed by processing circuitry thereof. The component can also contain dedicated hardware. The component can be a self-contained module or core, with one or more internal hardware and/or software interfaces (e.g., application program interface (API)) for communication with the operating software of external control device 104. External control device 104 can manage communication with LCDs 114 over interface 141 and other devices over interface 144. In various implementations, device 104/132 can be integrated as a single IC chip, can be integrated into multiple IC chips in a single package, or integrated as multiple semiconductor packages within a common housing.

In the implementations of FIGS. 1D and 1E, the master control functionality of system 102 is shared in common device 132, however, other divisions of shared control or permitted. For example, part of the master control functionality can be distributed between common device 132 and a dedicated MCD 112. In another example, both the master control functionality and at least part of the local control functionality can be implemented in common device 132 (e.g., with remaining local control functionality implemented in LCDs 114). In some implementations, all of control system 102 is implemented in common device (or subsystem) 132. In some implementations, local control functionality is implemented within a device shared with another component of each module 108, such as a Battery Management System (BMS).

Examples of Modules within Cascaded Energy Systems

Module 108 can include one or more energy sources and a power electronics converter and, if desired, an energy buffer. FIGS. 2A-2B are block diagrams depicting additional examples of system 100 with module 108 having a power converter 202, an energy buffer 204, and an energy source 206. Converter 202 can be a voltage converter or a current converter. The implementations are described herein with reference to voltage converters, although the implementations are not limited to such. Converter 202 can be configured to convert a direct current (DC) signal from energy source 204 into an alternating current (AC) signal and output it over power connection 110 (e.g., an inverter). Converter 202 can also receive an AC or DC signal over connection 110 and apply it to energy source 204 with either polarity in a continuous or pulsed form. Converter 202 can be or include an arrangement of switches (e.g., power transistors) such as a half bridge of full bridge (H-bridge). In some implementations converter 202 includes only switches and the converter (and the module as a whole) does not include a transformer.

Converter 202 can be also (or alternatively) be configured to perform AC to DC conversion (e.g., a rectifier) such as to charge a DC energy source from an AC source, DC to DC conversion, and/or AC to AC conversion (e.g., in combination with an AC-DC converter). In some implementations, such as to perform AC-AC conversion, converter 202 can include a transformer, either alone or in combination with one or more power semiconductors (e.g., switches, diodes, thyristors, and the like). In other implementations, such as those where weight and cost is a significant factor, converter 202 can be configured to perform the conversions with only power switches, power diodes, or other semiconductor devices and without a transformer.

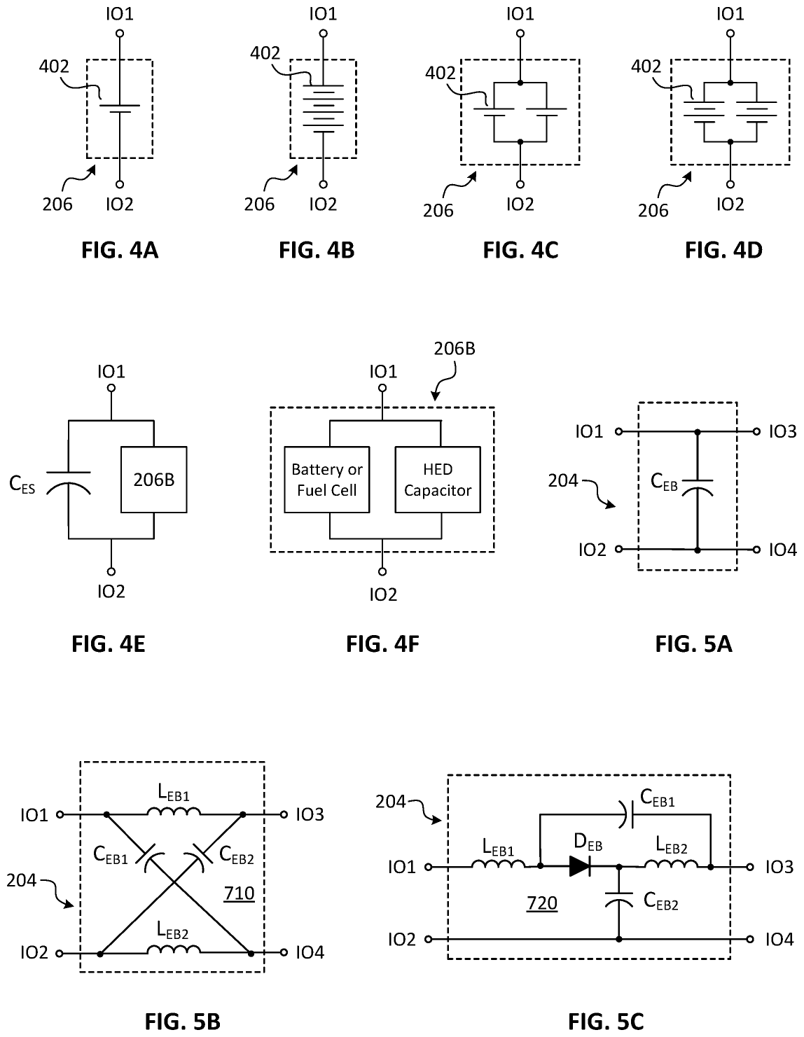

Energy source 206 is preferably a robust energy storage device capable of outputting direct current and having an energy density suitable for energy storage applications for electrically powered devices. Energy source 206 can be an electrochemical battery, such as a single battery cell or multiple battery cells connected together in a battery module or array, or any combination thereof. FIGS. 4A-4D are schematic diagrams depicting examples of energy source 206 configured as a single battery cell 402 (FIG. 4A), a battery module with a series connection of multiple (e.g., four) cells 402 (FIG. 4B), a battery module with a parallel connection of single cells 402 (FIG. 4C), and a battery module with a parallel connection with legs having two cells 402 each (FIG. 4D). A non-exhaustive list of examples of battery types is set forth elsewhere herein.

Energy source 206 can also be a high energy density (HED) capacitor, such as an ultracapacitor or supercapacitor. An HED capacitor can be configured as a double layer capacitor (electrostatic charge storage), pseudo capacitor (electrochemical charge storage), hybrid capacitor (electrostatic and electrochemical), or otherwise, as opposed to a solid dielectric type of a typical electrolytic capacitor. The HED capacitor can have an energy density of 10 to 100 times (or higher) that of an electrolytic capacitor, in addition to a higher capacity. For example, HED capacitors can have a specific energy greater than 1.0 watt hours per kilogram (Wh/kg), and a capacitance greater than 10-100 farads (F). As with the batteries described with respect to FIGS. 4A-4D, energy source 206 can be configured as a single HED capacitor or multiple HED capacitors connected together in an array (e.g., series, parallel, or a combination thereof).

Energy source 206 can also be a fuel cell. The fuel cell can be a single fuel cell, multiple fuel cells connected in series or parallel, or a fuel cell module. Examples of fuel cell types include proton-exchange membrane fuel cells (PEMFC), phosphoric acid fuel cells (PAFC), solid acid fuel cells, alkaline fuel cells, high temperature fuel cells, solid oxide fuel cells, molten electrolyte fuel cells, and others. As with the batteries described with respect to FIGS. 4A-4D, energy source 206 can be configured as a single fuel cell or multiple fuel cells connected together in an array (e.g., series, parallel, or a combination thereof). The aforementioned examples of source classes (e.g., batteries, capacitors, and fuel cells) and types (e.g., chemistries and/or structural configurations within each class) are not intended to form an exhaustive list, and those of ordinary skill in the art will recognize other variants that fall within the scope of the present subject matter.

Energy buffer 204 can dampen or filter fluctuations in current across the DC line or link (e.g., +V_{DCL} and −V_{DCL} as described below), to assist in maintaining stability in the DC link voltage. These fluctuations can be relatively low (e.g., kilohertz) or high (e.g., megahertz) frequency fluctuations or harmonics caused by the switching of converter 202, or other transients. These fluctuations can be absorbed by buffer 204 instead of being passed to source 206 or to ports IO3 and IO4 of converter 202.

Power connection 110 is a connection for transferring energy or power to, from and through module 108. Module 108 can output energy from energy source 206 to power connection 110, where it can be transferred to other modules of the system or to a load. Module 108 can also receive energy from other modules 108 or a charging source (DC charger, single phase charger, multi-phase charger). Signals can also be passed through module 108 bypassing energy source 206. The routing of energy or power into and out of module 108 is performed by converter 202 under the control of LCD 114 (or another entity of system 102).

In the implementation of FIG. 2A, LCD 114 is implemented as a component separate from module 108 (e.g., not within a shared module housing) and is connected to and capable of communication with converter 202 via communication path 116. In the implementation of FIG. 2B, LCD 114 is included as a component of module 108 and is connected to and capable of communication with converter 202 via internal communication path 118 (e.g., a shared bus or discrete connections). LCD 114 can also be capable of receiving signals from, and transmitting signals to, energy buffer 204 and/or energy source 206 over paths 116 or 118.

Module 108 can also include monitor circuitry 208 configured to monitor (e.g., collect, sense, measure, and/or determine) one or more aspects of module 108 and/or the components thereof, such as voltage, current, temperature or other operating parameters that constitute status information (or can be used to determine status information by, e.g., LCD 114). A main function of the status information is to describe the state of the one or more energy sources 206 of the module 108 to enable determinations as to how much to utilize the energy source in comparison to other sources in system 100, although status information describing the state of other components (e.g., voltage, temperature, and/or presence of a fault in buffer 204, temperature and/or presence of a fault in converter 202, presence of a fault elsewhere in module 108, etc.) can be used in the utilization determination as well. Monitor circuitry 208 can include one or more sensors, shunts, dividers, fault detectors, Coulomb counters, controllers or other hardware and/or software configured to monitor such aspects. Monitor circuitry 208 can be separate from the various components 202, 204, and 206, or can be integrated with each component 202, 204, and 206 (as shown in FIGS. 2A-2B), or any combination thereof. In some implementations, monitor circuitry 208 can be part of or shared with a Battery Management System (BMS) for a battery energy source 204. Discrete circuitry is not needed to monitor each type of status information, as more than one type of status information can be monitored with a single circuit or device, or otherwise algorithmically determined without the need for additional circuits.

LCD 114 can receive status information (or raw data) about the module components over communication paths 116, 118. LCD 114 can also transmit information to module components over paths 116, 118. Paths 116 and 118 can include diagnostics, measurement, protection, and control signal lines. The transmitted information can be control signals for one or more module components. The control signals can be switch signals for converter 202 and/or one or more signals that request the status information from module components. For example, LCD 114 can cause the status information to be transmitted over paths 116, 118 by requesting the status information directly, or by applying a stimulus (e.g., voltage) to cause the status information to be generated, in some cases in combination with switch signals that place converter 202 in a particular state.

The physical configuration or layout of module 108 can take various forms. In some implementations, module 108 can include a common housing in which all module components, e.g., converter 202, buffer 204, and source 206, are housed, along with other optional components such as an integrated LCD 114. In other implementations, the various components can be separated in discrete housings that are secured together. FIG. 2C is a block diagram depicting an example of a module 108 having a first housing 220 that holds an energy source 206 of the module and accompanying electronics such as monitor circuitry, a second housing 222 that holds module electronics such as converter 202, energy buffer 204, and other accompany electronics such as monitor circuitry, and a third housing 224 that holds LCD 114 (not shown) for the module 108. In alternative implementations the module electronics and LCD 114 can be housed within the same single housing. In still other implementations, the module electronics, LCD 114, and energy source(s) can be housed within the same single housing for the module 108. Electrical connections between the various module components can proceed through the housings 220, 222, 224 and can be exposed on any of the housing exteriors for connection with other devices such as other modules 108 or MCD 112.

Modules 108 of system 100 can be physically arranged with respect to each other in various configurations that depend on the needs of the application and the number of loads. For example, in a stationary application where system 100 provides power for a microgrid, modules 108 can be placed in one or more racks or other frameworks. Such configurations may be suitable for larger mobile applications as well, such as maritime vessels. Alternatively, modules 108 can be secured together and located within a common housing, referred to as a pack. A rack or a pack may have its own dedicated cooling system shared across all modules. Pack configurations are useful for smaller mobile applications such as electric cars. System 100 can be implemented with one or more racks (e.g., for parallel supply to a microgrid) or one or more packs (e.g., serving different motors of the vehicle), or combination thereof. FIG. 2D is a block diagram depicting an example of system 100 configured as a pack with nine modules 108 electrically and physically coupled together within a common housing 230.

Examples of these and further configurations are described in Int'l. Appl. No. PCT/US20/25366, filed Mar. 27, 2020 and titled Module-Based Energy Systems Capable of Cascaded and Interconnected Configurations, and Methods Related Thereto, which is incorporated by reference herein in its entirety for all purposes.

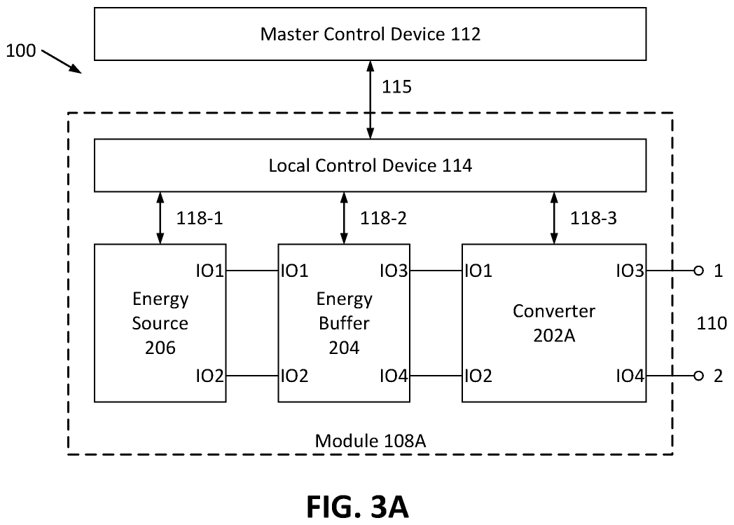

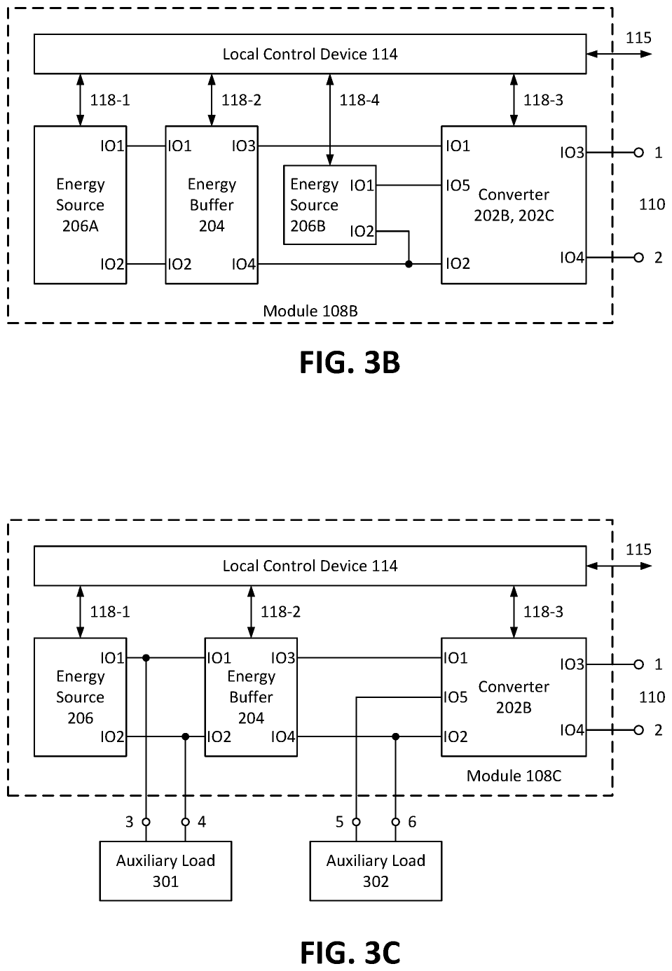

FIGS. 3A-3C are block diagrams depicting examples of modules 108 having various electrical configurations. These implementations are described as having one LCD 114 per module 108, with the LCD 114 housed within the associated module, but can be configured otherwise as described herein. FIG. 3A depicts a first example configuration of a module 108A within system 100. Module 108A includes energy source 206, energy buffer 204, and converter 202A. Each component has power connection ports (e.g., terminals, connectors) into which power can be input and/or from which power can be output, referred to herein as IO ports. Such ports can also be referred to as input ports or output ports depending on the context.

Energy source 206 can be configured as any of the energy source types described herein (e.g., a battery as described with respect to FIGS. 4A-4D, an HED capacitor, a fuel cell, or otherwise). Ports IO1 and IO2 of energy source 206 can be connected to ports IO1 and IO2, respectively, of energy buffer 204. Energy buffer 204 can be configured to buffer or filter high and low frequency energy pulsations arriving at buffer 204 through converter 202, which can otherwise degrade the performance of module 108. The topology and components for buffer 204 are selected to accommodate the maximum permissible amplitude of these high frequency voltage pulsations. Several (non-exhaustive) examples of energy buffer 204 are depicted in the schematic diagrams of FIGS. 5A-5C. In FIG. 5A, buffer 204 is an electrolytic and/or film capacitor C_{EB}, in FIG. 5B buffer 204 is a Z-source network 710, formed by two inductors L_{EB1} and L_{EB2} and two electrolytic and/or film capacitors C_{EB1} and C_{EB2}, and in FIG. 5C buffer 204 is a quasi Z-source network 720, formed by two inductors L_{EB1} and L_{EB2}, two electrolytic and/or film capacitors C_{EB1} and C_{EB2} and a diode D_{EB}.

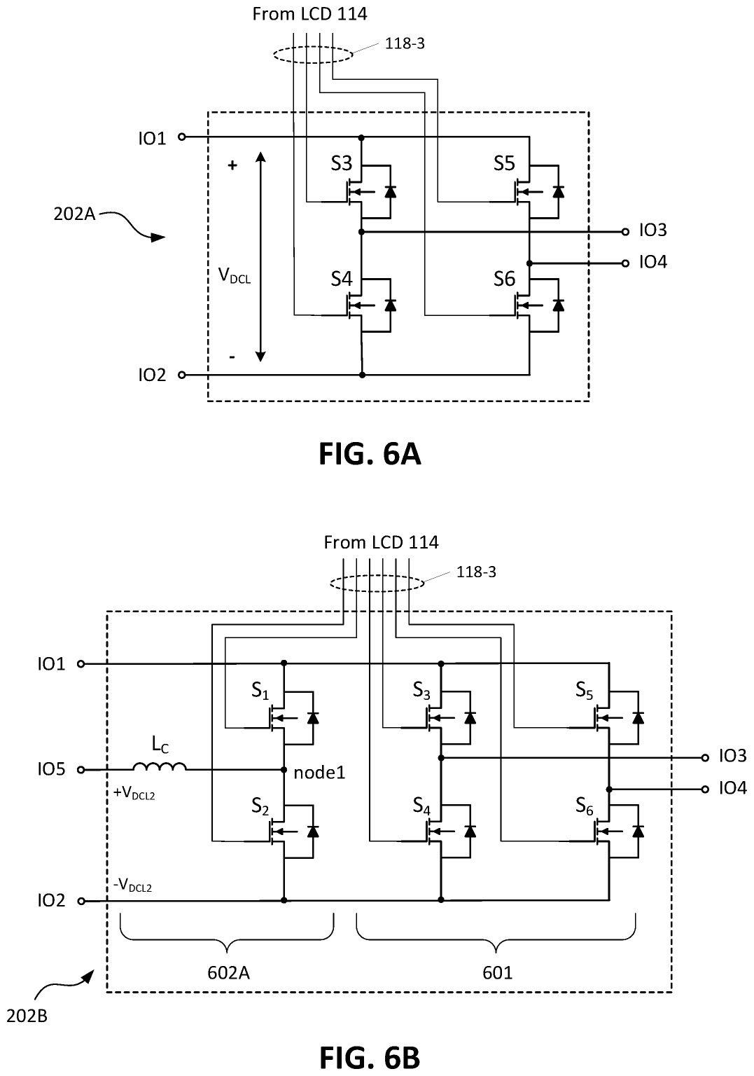

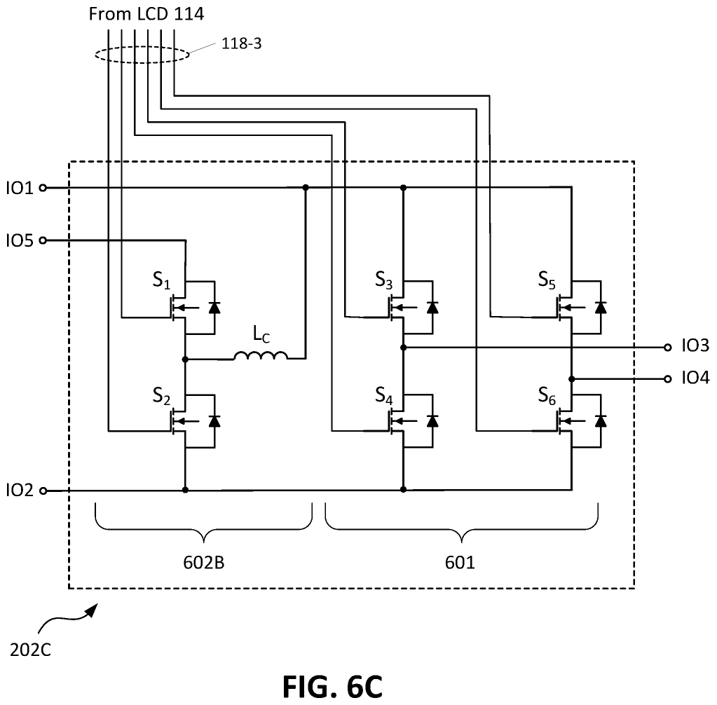

Ports IO3 and IO4 of energy buffer 204 can be connected to ports IO1 and IO2, respectively, of converter 202A, which can be configured as any of the power converter types described herein. FIG. 6A is a schematic diagram depicting an example of converter 202A configured as a DC-AC converter that can receive a DC voltage at ports IO1 and IO2 and switch to generate pulses at ports IO3 and IO4. Converter 202A can include multiple switches, and here converter 202A includes four switches S3, S4, S5, S6 arranged in a full bridge configuration. Control system 102 or LCD 114 can independently control each switch via control input lines 118-3 to each gate.

The switches can be any suitable switch type, such as power semiconductors like the metal-oxide-semiconductor field-effect transistors (MOSFETs) shown here, insulated gate bipolar transistors (IGBTs), or gallium nitride (GaN) transistors. Semiconductor switches can operate at relatively high switching frequencies, thereby permitting converter 202 to be operated in pulse-width modulated (PWM) mode if desired, and to respond to control commands within a relatively short interval of time. This can provide a high tolerance of output voltage regulation and fast dynamic behavior in transient modes. Further, the switching frequency can depend on the number of converters in a multilevel topology. Thus increasing the number of converters can reduce the response time, e.g., reduce the response time from 141 ms to 14 ms.

In this implementation, a DC line voltage V_{DCL} can be applied to converter 202 between ports IO1 and IO2. By connecting V_{DCL} to ports IO3 and IO4 by different combinations of switches S3, S4, S5, S6, converter 202 can generate three different voltage outputs at ports IO3 and IO4: +V_{DCL}, 0, and −V_{DCL}. A switch signal provided to each switch controls whether the switch is on (closed) or off (open). To obtain +V_{DCL}, switches S3 and S6 are turned on while S4 and S5 are turned off, whereas −V_{DCL} can be obtained by turning on switches S4 and S5 and turning off S3 and S6. The output voltage can be set to zero (including near zero) or a reference voltage by turning on S3 and S5 with S4 and S6 off, or by turning on S4 and S6 with S3 and S5 off. These voltages can be output from module 108 over power connection 110. Ports IO3 and IO4 of converter 202 can be connected to (or form) module IO ports 1 and 2 of power connection 110, so as to generate the output voltage for use with output voltages from other modules 108.

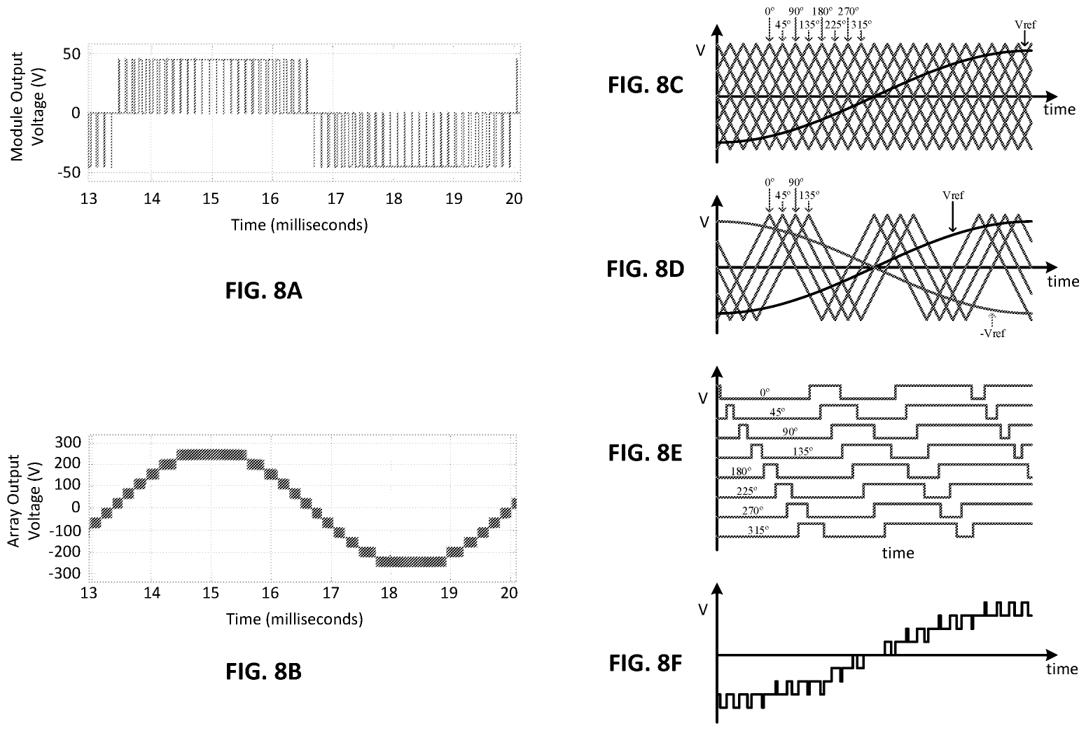

The control or switch signals for the implementations of converter 202 described herein can be generated in different ways depending on the control technique utilized by system 100 to generate the output voltage of converter 202. In some implementations, the control technique is a PWM technique such as space vector pulse-width modulation (SVPWM) or sinusoidal pulse-width modulation (SPWM), or variations thereof. FIG. 8A is a graph of voltage versus time depicting an example of an output voltage waveform 802 of converter 202. For ease of description, the implementations herein will be described in the context of a PWM control technique, although the implementations are not limited to such. Other classes of techniques can be used. One alternative class is based on hysteresis, examples of which are described in Int'l Publ. Nos. WO 2018/231810A1, WO 2018/232403A1, and WO 2019/183553A1, which are incorporated by reference herein for all purposes.

Each module 108 can be configured with multiple energy sources 206 (e.g., two, three, four, or more). Each energy source 206 of module 108 can be controllable (switchable) to supply power to connection 110 (or receive power from a charge source) independent of the other sources 206 of the module. For example, all sources 206 can output power to connection 110 (or be charged) at the same time, or only one (or a subset) of sources 206 can supply power (or be charged) at any one time. In some implementations, the sources 206 of the module can exchange energy between them, e.g., one source 206 can charge another source 206. Each of the sources 206 can be configured as any energy source described herein (e.g., battery, HED capacitor, fuel cell). Each of the sources 206 can be the same class (e.g., each can be a battery, each can be an HED capacitor, or each can be a fuel cell), or a different class (e.g., a first source can be a battery and a second source can be an HED capacitor or fuel cell, or a first source can be an HED capacitor and a second source can be a fuel cell). FIG. 3B is a block diagram depicting an example of a module 108B in a dual energy source configuration with a primary energy source 206A and secondary energy source 206B. Ports IO1 and IO2 of primary source 202A can be connected to ports IO1 and IO2 of energy buffer 204. Module 108B includes a converter 202B having an additional IO port. Ports IO3 and IO4 of buffer 204 can be connected ports IO1 and IO2, respectively, of converter 202B. Ports IO1 and IO2 of secondary source 206B can be connected to ports IO5 and IO2, respectively, of converter 202B (also connected to port IO4 of buffer 204).

In this example of module 108B, primary energy source 202A, along with the other modules 108 of system 100, supplies the average power needed by the load. Secondary source 202B can serve the function of assisting energy source 202 by providing additional power at load power peaks, or absorbing excess power, or otherwise.

As mentioned both primary source 206A and secondary source 206B can be utilized simultaneously or at separate times depending on the switch state of converter 202B. If at the same time, an electrolytic and/or a film capacitor (CEO) can be placed in parallel with source 206B as depicted in FIG. 4E to act as an energy buffer for the source 206B, or energy source 206B can be configured to utilize an HED capacitor in parallel with another energy source (e.g., a battery or fuel cell) as depicted in FIG. 4F.

FIGS. 6B and 6C are schematic views depicting examples of converters 202B and 202C, respectively. Converter 202B includes switch circuitry portions 601 and 602A. Portion 601 includes switches S3 through S6 configured as a full bridge in similar manner to converter 202A, and is configured to selectively couple IO1 and IO2 to either of IO3 and IO4, thereby changing the output voltages of module 108B. Portion 602A includes switches S1 and S2 configured as a half bridge and coupled between ports IO1 and IO2. A coupling inductor L_{C} is connected between port IO5 and a node1 present between switches S1 and S2 such that switch portion 602A is a bidirectional converter that can regulate (boost or buck) voltage (or inversely current). Switch portion 602A can generate two different voltages at node1, which are +V_{DCL2} And 0, referenced to port IO2, which can be at virtual zero potential. The current drawn from or input to energy source 202B can be controlled by regulating the voltage on coupling inductor L_{C}, using, for example, a pulse-width modulation technique or a hysteresis control method for commutating switches S1 and S2. Other techniques can also be used.

Converter 202C differs from that of 202B as switch portion 602B includes switches S1 and S2 configured as a half bridge and coupled between ports IO5 and IO2. A coupling inductor L_{C} is connected between port IO1 and a node1 present between switches S1 and S2 such that switch portion 602B is configured to regulate voltage.

Control system 102 or LCD 114 can independently control each switch of converters 202B and 202C via control input lines 118-3 to each gate. In these implementations and that of FIG. 6A, LCD 114 (not MCD 112) generates the switching signals for the converter switches. Alternatively, MCD 112 can generate the switching signals, which can be communicated directly to the switches, or relayed by LCD 114. In some implementations, driver circuitry for generating the switching signals can be present in or associated with MCD 112 and/or LCD 114.

The aforementioned zero voltage configuration for converter 202 (turning on S3 and S5 with S4 and S6 off, or turning on S4 and S6 with S3 and S5 off) can also be referred to as a bypass state for the given module. This bypass state can be entered if a fault is detected in the given module, or if a system fault is detected warranting shut-off of more than one (or all modules) in an array or system. A fault in the module can be detected by LCD 114 and the control switching signals for converter 202 can be set to engage the bypass state without intervention by MCD 112. Alternatively, fault information for a given module can be communicated by LCD 114 to MCD 112, and MCD 112 can then make a determination whether to engage the bypass state, and if so, can communicate instructions to engage the bypass state to the LCD 114 associated with the module having the fault, at which point LCD 114 can output switching signals to cause engagement of the bypass state.

In implementations where a module 108 includes three or more energy sources 206, converters 202B and 202C can be scaled accordingly such that each additional energy source 206B is coupled to an additional IO port leading to an additional switch circuitry portion 602A or 602B, depending on the needs of the particular source. For example a dual source converter 202 can include both switch portions 202A and 202B.

Modules 108 with multiple energy sources 206 are capable of performing additional functions such as energy sharing between sources 206, energy capture from within the application (e.g., regenerative braking), charging of the primary source by the secondary source even while the overall system is in a state of discharge, and active filtering of the module output. The active filtering function can also be performed by modules having a typical electrolytic capacitor instead of a secondary energy source. Examples of these functions are described in more detail in Int'l. Appl. No. PCT/US20/25366, filed Mar. 27, 2020 and titled Module-Based Energy Systems Capable of Cascaded and Interconnected Configurations, and Methods Related Thereto, and Int'l. Publ. No. WO 2019/183553, filed Mar. 22, 2019, and titled Systems and Methods for Power Management and Control, both of which are incorporated by reference herein in their entireties for all purposes.

Each module 108 can be configured to supply one or more auxiliary loads with its one or more energy sources 206. Auxiliary loads are loads that require lower voltages than the primary load 101. Examples of auxiliary loads can be, for example, an on-board electrical network of an electric vehicle, or an HVAC system of an electric vehicle. The load of system 100 can be, for example, one of the phases of the electric vehicle motor or electrical grid 1130. This implementation can allow a complete decoupling between the electrical characteristics (terminal voltage and current) of the energy source and those of the loads.

FIG. 3C is a block diagram depicting an example of a module 108C configured to supply power to a first auxiliary load 301 and a second auxiliary load 302, where module 108C includes an energy source 206, energy buffer 204, and converter 202B coupled together in a manner similar to that of FIG. 3B. First auxiliary load 301 requires a voltage equivalent to that supplied from source 206. Load 301 is coupled to IO ports 3 and 4 of module 108C, which are in turn coupled to ports IO1 and IO2 of source 206. Source 206 can output power to both power connection 110 and load 301. Second auxiliary load 302 requires a constant voltage lower than that of source 206. Load 302 is coupled to IO ports 5 and 6 of module 108C, which are coupled to ports IO5 and IO2, respectively, of converter 202B. Converter 202B can include switch portion 602 having coupling inductor L_{C} coupled to port IO5 (FIG. 6B). Energy supplied by source 206 can be supplied to load 302 through switch portion 602 of converter 202B. It is assumed that load 302 has an input capacitor (a capacitor can be added to module 108C if not), so switches S1 and S2 can be commutated to regulate the voltage on and current through coupling inductor L_{C} and thus produce a stable constant voltage for load 302. This regulation can step down the voltage of source 206 to the lower magnitude voltage is required by load 302.

Module 108C can thus be configured to supply one or more first auxiliary loads in the manner described with respect to load 301, with the one or more first loads coupled to IO ports 3 and 4. Module 108C can also be configured to supply one or more second auxiliary loads in the manner described with respect to load 302. If multiple second auxiliary loads 302 are present, then for each additional load 302 module 108C can be scaled with additional dedicated module output ports (like 5 and 6), an additional dedicated switch portion 602, and an additional converter IO port coupled to the additional portion 602.

Energy source 206 can thus supply power for any number of auxiliary loads (e.g., 301 and 302), as well as the corresponding portion of system output power needed by primary load 101. Power flow from source 206 to the various loads can be adjusted as desired.

Module 108 can be configured as needed with two or more energy sources 206 (FIG. 3B) and to supply first and/or second auxiliary loads (FIG. 3C) through the addition of a switch portion 602 and converter port IO5 for each additional source 206B or second auxiliary load 302. Additional module IO ports (e.g., 3, 4, 5, 6) can be added as needed. Module 108 can also be configured as an interconnection module to exchange energy (e.g., for balancing) between two or more arrays, two or more packs, or two or more systems 100 as described further herein. This interconnection functionality can likewise be combined with multiple source and/or multiple auxiliary load supply capabilities.

Control system 102 can perform various functions with respect to the components of modules 108A, 108B, and 108C. These functions can include management of the utilization (amount of use) of each energy source 206, protection of energy buffer 204 from over-current, over-voltage and high temperature conditions, and control and protection of converter 202.

For example, to manage (e.g., adjust by increasing, decreasing, or maintaining) utilization of each energy source 206, LCD 114 can receive one or more monitored voltages, temperatures, and currents from each energy source 206 (or monitor circuitry). The monitored voltages can be at least one of, preferably all, voltages of each elementary component independent of the other components (e.g., each individual battery cell, HED capacitor, and/or fuel cell) of the source 206, or the voltages of groups of elementary components as a whole (e.g., voltage of the battery array, HED capacitor array, and/or fuel cell array). Similarly the monitored temperatures and currents can be at least one of, preferably all, temperatures and currents of each elementary component independent of the other components of the source 206, or the temperatures and currents of groups of elementary components as a whole, or any combination thereof. The monitored signals can be status information, with which LCD 114 can perform one or more of the following: calculation or determination of a real capacity, actual State of Charge (SOC) and/or State of Health (SOH) of the elementary components or groups of elementary components; set or output a warning or alarm indication based on monitored and/or calculated status information; and/or transmission of the status information to MCD 112. LCD 114 can receive control information (e.g., a modulation index, synchronization signal) from MCD 112 and use this control information to generate switch signals for converter 202 that manage the utilization of the source 206.

To protect energy buffer 204, LCD 114 can receive one or more monitored voltages, temperatures, and currents from energy buffer 204 (or monitor circuitry). The monitored voltages can be at least one of, preferably all, voltages of each elementary component of buffer 204 (e.g., of C_{EB}, C_{EB1}, C_{EB2}, L_{EB1}, L_{EB2}, D_{EB}) independent of the other components, or the voltages of groups of elementary components or buffer 204 as a whole (e.g., between 101 and IO2 or between IO3 and IO4). Similarly the monitored temperatures and currents can be at least one of, preferably all, temperatures and currents of each elementary component of buffer 204 independent of the other components, or the temperatures and currents of groups of elementary components or of buffer 204 as a whole, or any combination thereof. The monitored signals can be status information, with which LCD 114 can perform one or more of the following: set or output a warning or alarm indication; communicate the status information to MCD 112; or control converter 202 to adjust (increase or decrease) the utilization of source 206 and module 108 as a whole for buffer protection.

To control and protect converter 202, LCD 114 can receive the control information from MCD 112 (e.g., a modulated reference signal, or a reference signal and a modulation index), which can be used with a PWM technique in LCD 114 to generate the control signals for each switch (e.g., S1 through S6). LCD 114 can receive a current feedback signal from a current sensor of converter 202, which can be used for overcurrent protection together with one or more fault status signals from driver circuits (not shown) of the converter switches, which can carry information about fault statuses (e.g., short circuit or open circuit failure modes) of all switches of converter 202. Based on this data, LCD 114 can make a decision on which combination of switching signals to be applied to manage utilization of module 108, and potentially bypass or disconnect converter 202 (and the entire module 108) from system 100.

If controlling a module 108C that supplies a second auxiliary load 302, LCD 114 can receive one or more monitored voltages (e.g., the voltage between IO ports 5 and 6) and one or more monitored currents (e.g., the current in coupling inductor L_{C}, which is a current of load 302) in module 108C. Based on these signals, LCD 114 can adjust the switching cycles (e.g., by adjustment of modulation index or reference waveform) of S1 and S2 to control (and stabilize) the voltage for load 302.

### Cascaded Energy System Topology Examples

Two or more modules 108 can be coupled together in a cascaded array that outputs a voltage signal formed by a superposition of the discrete voltages generated by each module 108 within the array. FIG. 7A is a block diagram depicting an example of a topology for system 100 where N modules 108-1, 108-2 . . . 108-N are coupled together in series to form a serial array 700. In this and all implementations described herein, N can be any integer greater than one. Array 700 includes a first system IO port SIO1 and a second system IO port SIO2 across which is generated an array output voltage. Array 700 can be used as a DC or single phase AC energy source for DC or AC single-phase loads, which can be connected to SIO1 and SIO2 of array 700. FIG. 8A is a plot of voltage versus time depicting an example output signal produced by a single module 108 having a 48 volt energy source. FIG. 8B is a plot of voltage versus time depicting an example single phase AC output signal generated by array 700 having six 48V modules 108 coupled in series.

System 100 can be arranged in a broad variety of different topologies to meet varying needs of the applications. System 100 can provide multi-phase power (e.g., two-phase, three-phase, four-phase, five-phase, six-phase, etc.) to a load by use of multiple arrays 700, where each array can generate an AC output signal having a different phase angle.

FIG. 7B is a block diagram depicting system 100 with two arrays 700-PA and 700-PB coupled together. Each array 700 is one-dimensional, formed by a series connection of N modules 108. The two arrays 700-PA and 700-PB can each generate a single-phase AC signal, where the two AC signals have different phase angles PA and PB (e.g., 180 degrees apart). IO port 1 of module 108-1 of each array 700-PA and 700-PB can form or be connected to system IO ports SIO1 and SIO2, respectively, which in turn can serve as a first output of each array that can provide two phase power to a load (not shown). Or alternatively ports SIO1 and SIO2 can be connected to provide single phase power from two parallel arrays. IO port 2 of module 108-N of each array 700-PA and 700-PB can serve as a second output for each array 700-PA and 700-PB on the opposite end of the array from system IO ports SIO1 and SIO2, and can be coupled together at a common node and optionally used for an additional system IO port SIO3 if desired, which can serve as a neutral. This common node can be referred to as a rail, and IO port 2 of modules 108-N of each array 700 can be referred to as being on the rail side of the arrays.

FIG. 7C is a block diagram depicting system 100 with three arrays 700-PA, 700-PB, and 700-PC coupled together. Each array 700 is one-dimensional, formed by a series connection of N modules 108. The three arrays 700-1 and 700-2 can each generate a single-phase AC signal, where the three AC signals have different phase angles PA, PB, PC (e.g., 120 degrees apart). IO port 1 of module 108-1 of each array 700-PA, 700-PB, and 700-PC can form or be connected to system IO ports SIO1, SIO2, and SIO3, respectively, which in turn can provide three phase power to a load (not shown). IO port 2 of module 108-N of each array 700-PA, 700-PB, and 700-PC can be coupled together at a common node and optionally used for an additional system IO port SIO4 if desired, which can serve as a neutral.

The concepts described with respect to the two-phase and three-phase implementations of FIGS. 7B and 7C can be extended to systems 100 generating still more phases of power. For example, a non-exhaustive list of additional examples includes: system 100 having four arrays 700, each of which is configured to generate a single phase AC signal having a different phase angle (e.g., 90 degrees apart): system 100 having five arrays 700, each of which is configured to generate a single phase AC signal having a different phase angle (e.g., 72 degrees apart); and system 100 having six arrays 700, each array configured to generate a single phase AC signal having a different phase angle (e.g., 60 degrees apart).

System 100 can be configured such that arrays 700 are interconnected at electrical nodes between modules 108 within each array. FIG. 7D is a block diagram depicting system 100 with three arrays 700-PA, 700-PB, and 700-PC coupled together in a combined series and delta arrangement. Each array 700 includes a first series connection of M modules 108, where M is two or greater, coupled with a second series connection of N modules 108, where N is two or greater. The delta configuration is formed by the interconnections between arrays, which can be placed in any desired location. In this implementation, IO port 2 of module 108-(M+N) of array 700-PC is coupled with IO port 2 of module 108-M and IO port 1 of module 108-(M+1) of array 700-PA, IO port 2 of module 108-(M+N) of array 700-PB is coupled with IO port 2 of module 108-M and IO port 1 of module 108-(M+1) of array 700-PC, and IO port 2 of module 108-(M+N) of array 700-PA is coupled with IO port 2 of module 108-M and IO port 1 of module 108-(M+1) of array 700-PB.

FIG. 7E is a block diagram depicting system 100 with three arrays 700-PA, 700-PB, and 700-PC coupled together in a combined series and delta arrangement. This implementation is similar to that of FIG. 7D except with different cross connections. In this implementation, IO port 2 of module 108-M of array 700-PC is coupled with IO port 1 of module 108-1 of array 700-PA, IO port 2 of module 108-M of array 700-PB is coupled with IO port 1 of module 108-1 of array 700-PC, and IO port 2 of module 108-M of array 700-PA is coupled with IO port 1 of module 108-1 of array 700-PB. The arrangements of FIGS. 7D and 7E can be implemented with as little as two modules in each array 700. Combined delta and series configurations enable an effective exchange of energy between all modules 108 of the system (interphase balancing) and phases of power grid 1130 or load, and also allows reducing the total number of modules 108 in an array 700 to obtain the desired output voltages.

In the implementations described herein, although it is advantageous for the number of modules 108 to be the same in each array 700 within system 100, such is not required and different arrays 700 can have differing numbers of modules 108. Further, each array 700 can have modules 108 that are all of the same configuration (e.g., all modules are 108A, all modules are 108B, all modules are 108C, or others) or different configurations (e.g., one or more modules are 108A, one or more are 108B, and one or more are 108C, or otherwise). As such, the scope of topologies of system 100 covered herein is broad.

In conventional systems the energy sources, typically batteries, are connected together in a non-switchable arrangement (e.g., serial) that yields a single output voltage (Vc_out). A conventional inverter oscillates this voltage between positive (+Vc_out) and negative (−Vc_out) to create the AC signal for each desired phase that, after filtering, is output to the load or grid. The AC signals output by conventional systems are limited to the frequency of the switches of the conventional inverter. For example, high power IGBT-based conventional inverters typically have an output frequency less than 5 kHz. Conversely, system 100 provides switch ability for every energy source 206 by way of module converters 202, and thus has a dynamic range that exceeds conventional systems, whether for stationary or mobility applications. In an implementation where MOSFETs are used for converter 202A (FIG. 6A), the switching frequency of each MOSFET (Fsw) can be in a range of 1 Khz-2 kHz, or more. If there are eight modules 108 in each phase array 700, then the resulting frequency of pulsations in the AC output voltage will be 2Fsw*N=16 kHz-32 kHz, or more, which allows the injection of signals at much higher frequencies than conventional systems.

### Control Methodology Examples

As mentioned, control of system 100 can be performed according to various methodologies, such as hysteresis or PWM. Several examples of PWM include space vector modulation and sine pulse width modulation, where the switching signals for converter 202 are generated with a phase shifted carrier technique that continuously rotates utilization of each module 108 to equally distribute power among them.

FIGS. 8C-8F are plots depicting an example of a phase-shifted PWM control methodology that can generate a multilevel output PWM waveform using incrementally shifted two-level waveforms. An X-level PWM waveform can be created by the summation of (X−1)/2 two-level PWM waveforms. These two-level waveforms can be generated by comparing a reference waveform Vref to carriers incrementally shifted by 360°/(X−1). The carriers are triangular, but the implementations are not limited to such. A nine-level example is shown in FIG. 8C (using four modules 108). The carriers are incrementally shifted by 360°/(9−1)=45° and compared to Vref. The resulting two-level PWM waveforms are shown in FIG. 8E. These two-level waveforms may be used as the switching signals for semiconductor switches (e.g., S1 though S6) of converters 202. As an example with reference to FIG. 8E, for a one-dimensional array 700 including four modules 108 each with a converter 202, the 0° signal is for control of S3 and the 180° signal for S6 of the first module 108-1, the 45° signal is for S3 and the 225° signal for S6 of the second module 108-2, the 90 signal is for S3 and the 270 signal is for S6 of the third module 108-3, and the 135 signal is for S3 and the 315 signal is for S6 of the fourth module 108-4. The signal for S3 is complementary to S4 and the signal for S5 is complementary to S6 with sufficient dead-time to avoid shoot through of each half-bridge. FIG. 8F depicts an example single phase AC waveform produced by superposition (summation) of output voltages from the four modules 108.

An alternative is to utilize both a positive and a negative reference signal with the first (N−1)/2 carriers. A nine-level example is shown in FIG. 8D. In this example, the 0° to 135° switching signals (FIG. 8E) are generated by comparing +Vref to the 0° to 135° carriers of FIG. 8D and the 180° to 315° switching signals are generated by comparing −Vref to the 0° to 135° carriers of FIG. 8D. However, the logic of the comparison in the latter case is reversed. Other techniques such as a state machine decoder may also be used to generate gate signals for the switches of converter 202.

In multi-phase system implementations, the same carriers can be used for each phase, or the set of carriers can be shifted as a whole for each phase. For example, in a three phase system with a single reference voltage (Vref), each array 700 can use the same number of carriers with the same relative offsets as shown in FIGS. 8C and 8D, but the carriers of the second phase are shift by 120 degrees as compared to the carriers of the first phase, and the carriers of the third phase are shifted by 240 degrees as compared to the carriers of the first phase. If a different reference voltage is available for each phase, then the phase information can be carried in the reference voltage and the same carriers can be used for each phase. In many cases the carrier frequencies will be fixed, but in some example implementations, the carrier frequencies can be adjusted, which can help to reduce losses in EV motors under high current conditions.

The appropriate switching signals can be provided to each module by control system 102. For example, MCD 112 can provide Vref and the appropriate carrier signals to each LCD 114 depending upon the module or modules 108 that LCD 114 controls, and the LCD 114 can then generate the switching signals. Or all LCDs 114 in an array can be provided with all carrier signals and the LCD can select the appropriate carrier signals.

The relative utilizations of each module 108 can adjusted based on status information to perform balancing or of one or more parameters as described herein. Balancing of parameters can involve adjusting utilization to minimize parameter divergence over time as compared to a system where individual module utilization adjustment is not performed. The utilization can be the relative amount of time a module 108 is discharging when system 100 is in a discharge state, or the relative amount of time a module 108 is charging when system 100 is in a charge state.

As described herein, modules 108 can be balanced with respect to other modules in an array 700, which can be referred to as intra array or intraphase balancing, and different arrays 700 can be balanced with respect to each other, which can be referred to as interarray or interphase balancing. Arrays 700 of different subsystems can also be balanced with respect to each other. Control system 102 can simultaneously perform any combination of intraphase balancing, interphase balancing, utilization of multiple energy sources within a module, active filtering, and auxiliary load supply.

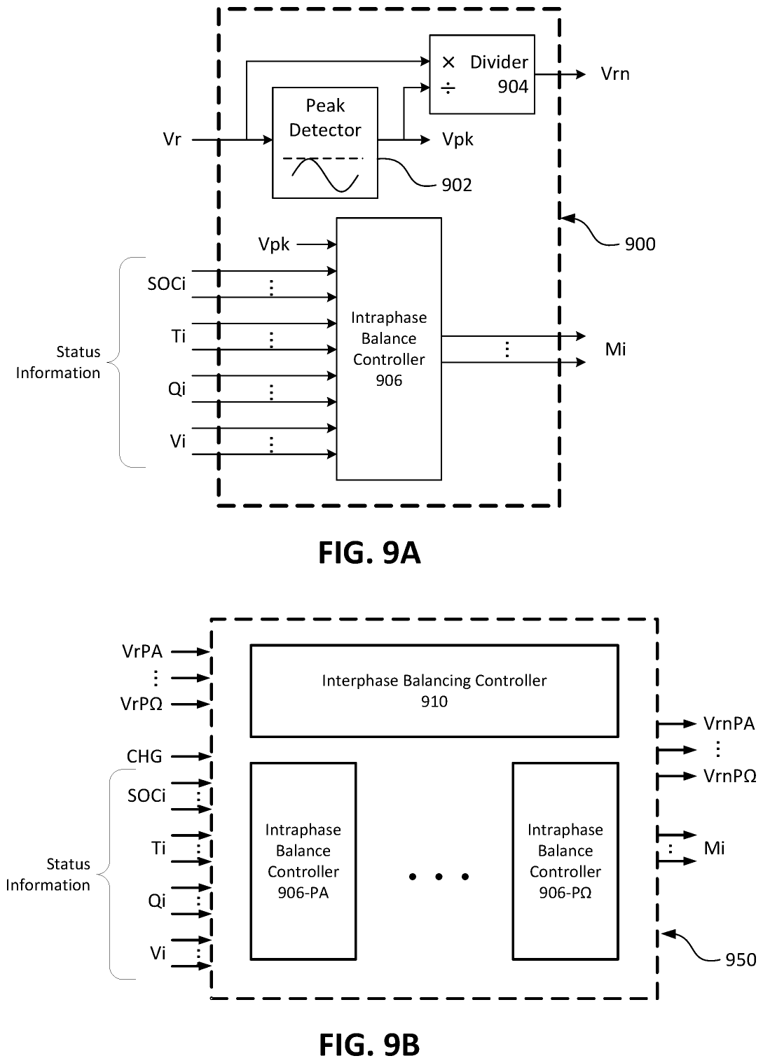

FIG. 9A is a block diagram depicting an example of an array controller 900 of control system 102 for a single-phase AC or DC array. Array controller 900 can include a peak detector 902, a divider 904, and an intraphase (or intra array) balance controller 906. Array controller 900 can receive a reference voltage waveform (Vr) and status information about each of the N modules 108 in the array (e.g., state of charge (SOCi), temperature (Ti), capacity (Qi), and voltage (Vi)) as inputs, and generate a normalized reference voltage waveform (Vrn) and modulation indexes (Mi) as outputs. Peak detector 902 detects the peak (Vpk) of Vr, which can be specific to the phase that controller 900 is operating with and/or balancing. Divider 904 generates Vrn by dividing Vr by its detected Vpk. Intraphase balance controller 906 uses Vpk along with the status information (e.g., SOCi, Ti, Qi, Vi, etc.) to generate modulation indexes Mi for each module 108 within the array 700 being controlled.

The modulation indexes and Vrn can be used to generate the switching signals for each converter 202. The modulation index can be a number between zero and one (inclusive of zero and one). For a particular module 108, the normalized reference Vrn can be modulated or scaled by Mi, and this modulated reference signal (Vrnm) can be used as Vref (or −Vref) according to the PWM technique described with respect to FIGS. 8C-8F, or according to other techniques. In this manner, the modulation index can be used to control the PWM switching signals provided to the converter switching circuitry (e.g., S3-S6 or S1-S6), and thus regulate the operation of each module 108. For example, a module 108 being controlled to maintain normal or full operation may receive an Mi of one, while a module 108 being controlled to less than normal or full operation may receive an Mi less than one, and a module 108 controlled to cease power output may receive an Mi of zero. This operation can be performed in various ways by control system 102, such as by MCD 112 outputting Vrn and Mi to the appropriate LCDs 114 for modulation and switch signal generation, by MCD 112 performing modulation and outputting the modulated Vrnm to the appropriate LCDs 114 for switch signal generation, or by MCD 112 performing modulation and switch signal generation and outputting the switch signals to the LCDs or the converters 202 of each module 108 directly. Vrn can be sent continually with Mi sent at regular intervals, such as once for every period of the Vrn, or one per minute, etc.

Controller 906 can generate an Mi for each module 108 using any type or combination of types of status information (e.g., SOC, temperature (T), Q, SOH, voltage, current) described herein. For example, when using SOC and T, a module 108 can have a relatively high Mi if SOC is relatively high and temperature is relatively low as compared to other modules 108 in array 700. If either SOC is relatively low or T is relatively high, then that module 108 can have a relatively low Mi, resulting in less utilization than other modules 108 in array 700. Controller 906 can determine Mi such that the sum of module voltages does not exceed Vpk. For example, Vpk can be the sum of the products of the voltage of each module's source 206 and Mi for that module (e.g., Vpk=M₁V₁+M₂V₂+M₃V₃ . . . +M_{N}V_{N}, etc). A different combination of modulation indexes, and thus respective voltage contributions by the modules, may be used but the total generated voltage should remain the same.

Controller 900 can control operation, to the extent it does not prevent achieving the power output requirements of the system at any one time (e.g., such as during maximum acceleration of an EV), such that SOC of the energy source(s) in each module 108 remains balanced or converges to a balanced condition if they are unbalanced, and/or such that temperature of the energy source(s) or other component (e.g., energy buffer) in each module remains balanced or converges to a balanced condition if they are unbalanced. Power flow in and out of the modules can be regulated such that a capacity difference between sources does not cause an SOC deviation. Balancing of SOC and temperature can indirectly cause some balancing of SOH. Voltage and current can be directly balanced if desired, but in many implementations the main goal of the system is to balance SOC and temperature, and balancing of SOC can lead to balance of voltage and current in a highly symmetric systems where modules are of similar capacity and impedance.

Since balancing all parameters may not be possible at the same time (e.g., balancing of one parameter may further unbalance another parameter), a combination of balancing any two or more parameters (SOC, T, Q, SOH, V, I) may be applied with priority given to either one depending on the requirements of the application. Priority in balancing can be given to SOC over other parameters (T, Q, SOH, V, I), with exceptions made if one of the other parameters (T, Q, SOH, V, I) reaches a severe unbalanced condition outside a threshold.

Balancing between arrays 700 of different phases (or arrays of the same phase, e.g., if parallel arrays are used) can be performed concurrently with intraphase balancing. FIG. 9B depicts an example of an Ω-phase (or Ω-array) controller 950 configured for operation in an Ω-phase system 100, having at least Ω arrays 700, where Ω is any integer greater than one. Controller 950 can include one interphase (or interarray) controller 910 and Ω intraphase balance controllers 906-PA . . . 906-PΩ for phases PA through PΩ, as well as peak detector 902 and divider 904 (FIG. 9A) for generating normalized references VrnPA through VrnPΩ from each phase-specific reference VrPA through VrPΩ. Intraphase controllers 906 can generate Mi for each module 108 of each array 700 as described with respect to FIG. 9A. Interphase balance controller 910 is configured or programmed to balance aspects of modules 108 across the entire multi-dimensional system, for example, between arrays of different phases. This may be achieved through injecting common mode to the phases (e.g., neutral point shifting) or through the use of interconnection modules (described herein) or through both. Common mode injection involves introducing a phase and amplitude shift to the reference signals VrPA through VrPΩ to generate normalized waveforms VrnPA through VrnPΩ to compensate for unbalance in one or more arrays, and is described further in Int'l. Appl. No. PCT/US20/25366 incorporated herein.

Controllers 900 and 950 (as well as balance controllers 906 and 910) can be implemented in hardware, software or a combination thereof within control system 102. Controllers 900 and 950 can be implemented within MCD 112, distributed partially or fully among LCDs 114, or may be implemented as discrete controllers independent of MCD 112 and LCDs 114.

### Interconnection (IC) Module Examples

Modules 108 can be connected between the modules of different arrays 700 for the purposes of exchanging energy between the arrays, acting as a source for an auxiliary load, or both. Such modules are referred to herein as interconnection (IC) modules 108IC. IC module 108IC can be implemented in any of the already described module configurations (108A, 108B, 108C) and others to be described herein. IC modules 108IC can include any number of one or more energy sources, an optional energy buffer, switch circuitry for supplying energy to one or more arrays and/or for supplying power to one or more auxiliary loads, control circuitry (e.g., a local control device), and monitor circuitry for collecting status information about the IC module itself or its various loads (e.g., SOC of an energy source, temperature of an energy source or energy buffer, capacity of an energy source, SOH of an energy source, voltage and/or current measurements pertaining to the IC module, voltage and/or current measurements pertaining to the auxiliary load(s), etc.).

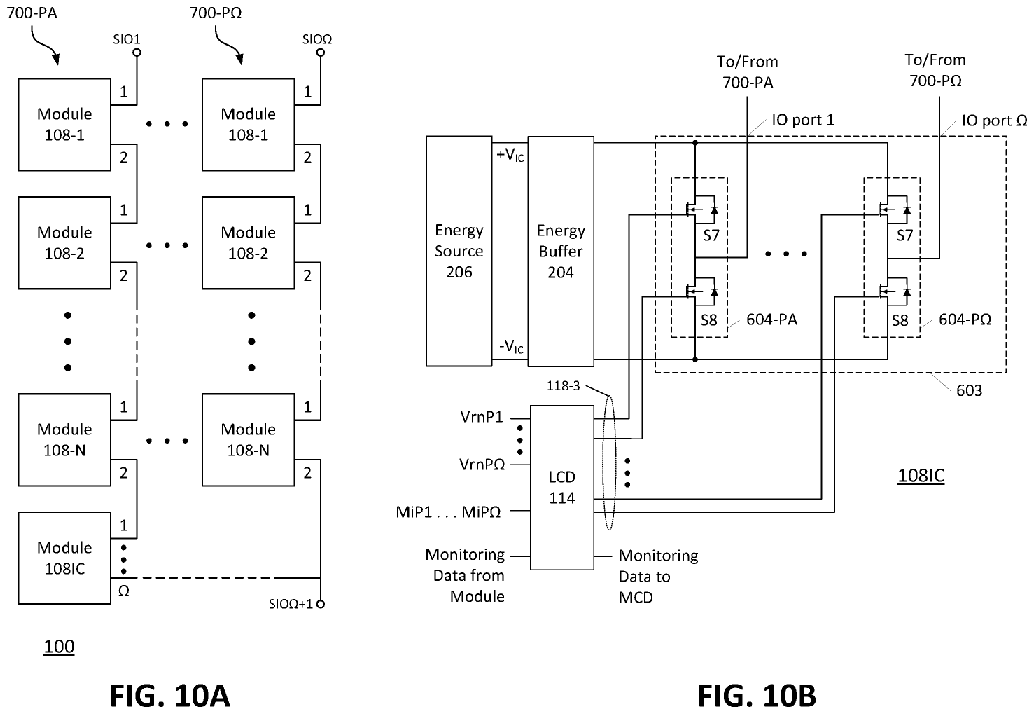

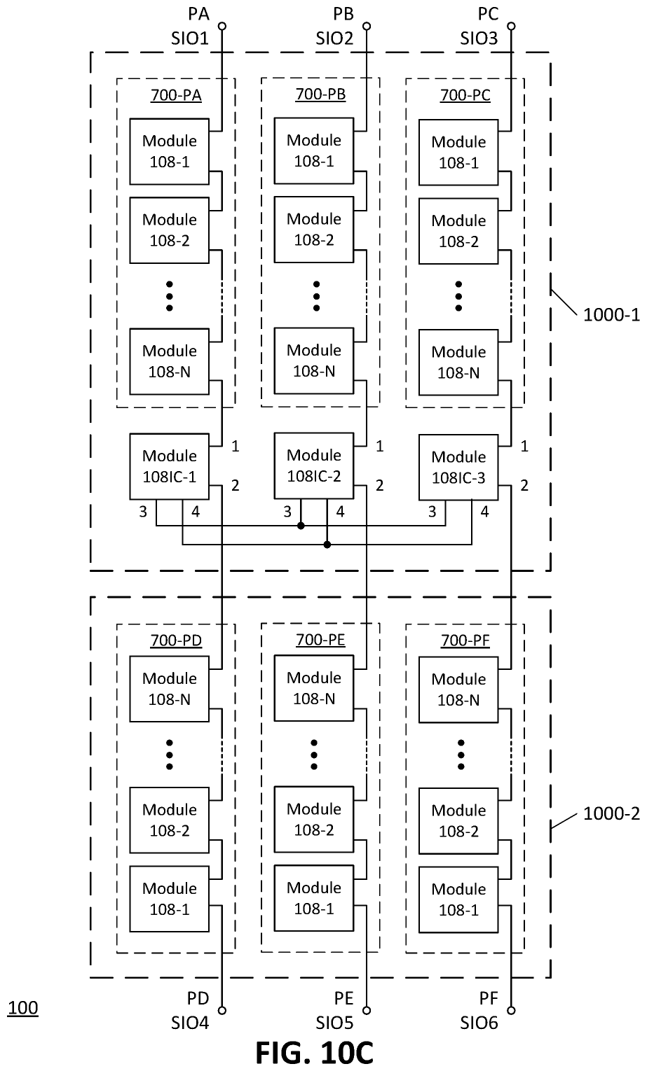

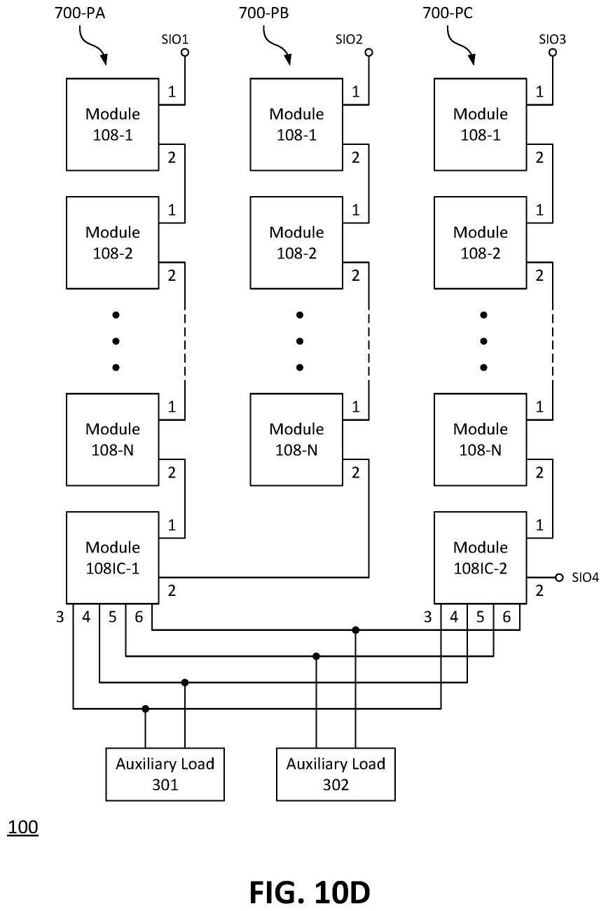

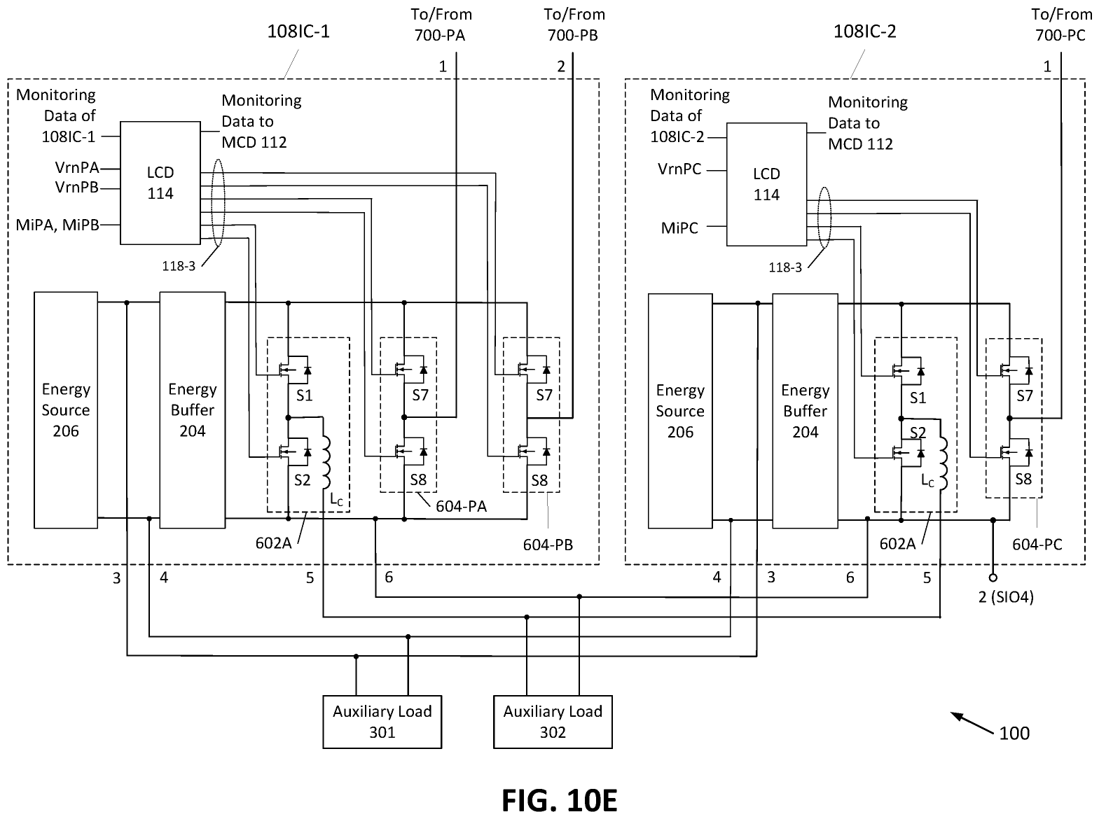

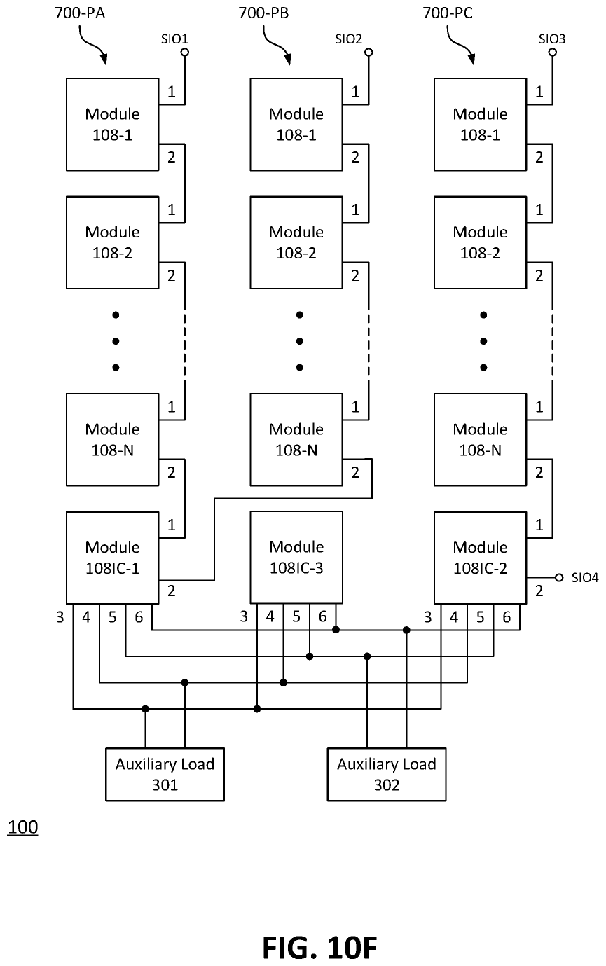

FIG. 10A is a block diagram depicting an example of a system 100 capable of producing Ω-phase power with Ω arrays 700-PA through 700-PΩ, where Ω can be any integer greater than one. In this and other implementations, IC module 108IC can be located on the rail side of arrays 700 such the arrays 700 to which module 108IC are connected (arrays 700-PA through 700-PQ in this implementation) are electrically connected between module 108IC and outputs (e.g., SIO1 through SIOΩ) to the load. Here, module 108IC has Ω IO ports for connection to IO port 2 of each module 108-N of arrays 700-PA through 700-PΩ. In the configuration depicted here, module 108IC can perform interphase balancing by selectively connecting the one or more energy sources of module 108IC to one or more of the arrays 700-PA through 700-PΩ (or to no output, or equally to all outputs, if interphase balancing is not required). System 100 can be controlled by control system 102 (not shown, see FIG. 1A).

FIG. 10B is a schematic diagram depicting an example of module 108IC. In this implementation module 108IC includes an energy source 206 connected with energy buffer 204 that in turn is connected with switch circuitry 603. Switch circuitry 603 can include switch circuitry units 604-PA through 604-PΩ for independently connecting energy source 206 to each of arrays 700-PA through 700-PΩ, respectively. Various switch configurations can be used for each unit 604, which in this implementation is configured as a half-bridge with two semiconductor switches S7 and S8. Each half bridge is controlled by control lines 118-3 from LCD 114. This configuration is similar to module 108A described with respect to FIG. 3A. As described with respect to converter 202, switch circuitry 603 can be configured in any arrangement and with any switch types (e.g., MOSFET, IGBT, Silicon, GaN, etc.) suitable for the requirements of the application.

Switch circuitry units 604 are coupled between positive and negative terminals of energy source 206 and have an output that is connected to an IO port of module 108IC. Units 604-PA through 604-PΩ can be controlled by control system 102 to selectively couple voltage +V_{IC} or —V_{IC} to the respective module I/O ports 1 through Ω. Control system 102 can control switch circuitry 603 according to any desired control technique, including the PWM and hysteresis techniques mentioned herein. Here, control circuitry 102 is implemented as LCD 114 and MCD 112 (not shown). LCD 114 can receive monitoring data or status information from monitor circuitry of module 108IC. This monitoring data and/or other status information derived from this monitoring data can be output to MCD 112 for use in system control as described herein. LCD 114 can also receive timing information (not shown) for purposes of synchronization of modules 108 of the system 100 and one or more carrier signals (not shown), such as the sawtooth signals used in PWM (FIGS. 8C-8D).

For interphase balancing, proportionally more energy from source 206 can be supplied to any one or more of arrays 700-PA through 700-PΩ that is relatively low on charge as compared to other arrays 700. Supply of this supplemental energy to a particular array 700 allows the energy output of those cascaded modules 108-1 thru 108-N in that array 700 to be reduced relative to the unsupplied phase array(s).

For example, in some example implementations applying PWM, LCD 114 can be configured to receive the normalized voltage reference signal (Vrn) (from MCD 112) for each of the one or more arrays 700 that module 108IC is coupled to, e.g., VrnPA through VrnPΩ. LCD 114 can also receive modulation indexes MiPA through MiPΩ for the switch units 604-PA through 604-PQ for each array 700, respectively, from MCD 112. LCD 114 can modulate (e.g., multiply) each respective Vrn with the modulation index for the switch section coupled directly to that array (e.g., VrnA multiplied by MiA) and then utilize a carrier signal to generate the control signal(s) for each switch unit 604. In other implementations, MCD 112 can perform the modulation and output modulated voltage reference waveforms for each unit 604 directly to LCD 114 of module 108IC. In still other implementations, all processing and modulation can occur by a single control entity that can output the control signals directly to each unit 604.

This switching can be modulated such that power from energy source 206 is supplied to the array(s) 700 at appropriate intervals and durations. Such methodology can be implemented in various ways.

Based on the collected status information for system 100, such as the present capacity (Q) and SOC of each energy source in each array, MCD 112 can determine an aggregate charge for each array 700 (e.g., aggregate charge for an array can be determined as the sum of capacity times SOC for each module of that array). MCD 112 can determine whether a balanced or unbalanced condition exists (e.g., through the use of relative difference thresholds and other metrics described herein) and generate modulation indexes MiPA through MiPΩ accordingly for each switch unit 604-PA through 604-PΩ.

During balanced operation, Mi for each switch unit 604 can be set at a value that causes the same or similar amount of net energy over time to be supplied by energy source 206 and/or energy buffer 204 to each array 700. For example, Mi for each switch unit 604 could be the same or similar, and can be set at a level or value that causes the module 108IC to perform a net or time average discharge of energy to the one or more arrays 700-PA through 700-PQ during balanced operation, so as to drain module 108IC at the same rate as other modules 108 in system 100. In some implementations, Mi for each unit 604 can be set at a level or value that does not cause a net or time average discharge of energy during balanced operation (causes a net energy discharge of zero). This can be useful if module 108IC has a lower aggregate charge than other modules in the system.

When an unbalanced condition occurs between arrays 700, then the modulation indexes of system 100 can be adjusted to cause convergence towards a balanced condition or to minimize further divergence. For example, control system 102 can cause module 108IC to discharge more to the array 700 with low charge than the others, and can also cause modules 108-1 through 108-N of that low array 700 to discharge relatively less (e.g., on a time average basis). The relative net energy contributed by module 108IC increases as compared to the modules 108-1 through 108-N of the array 700 being assisted, and also as compared to the amount of net energy module 108IC contributes to the other arrays. This can be accomplished by increasing Mi for the switch unit 604 supplying that low array 700, and by decreasing the modulation indexes of modules 108-1 through 108-N of the low array 700 in a manner that maintains Vout for that low array at the appropriate or required levels, and maintaining the modulation indexes for other switch units 604 supplying the other higher arrays relatively unchanged (or decreasing them).

The configuration of module 108IC in FIGS. 10A-10B can be used alone to provide interphase or interarray balancing for a single system, or can be used in combination with one or more other modules 108IC each having an energy source and one or more switch portions 604 coupled to one or more arrays. For example, a module 108IC with S2 switch portions 604 coupled with S2 different arrays 700 can be combined with a second module 108IC having one switch portion 604 coupled with one array 700 such that the two modules combine to service a system 100 having S2+1 arrays 700. Any number of modules 108IC can be combined in this fashion, each coupled with one or more arrays 700 of system 100.

Furthermore, IC modules can be configured to exchange energy between two or more subsystems of system 100. FIG. 10C is a block diagram depicting an example of system 100 with a first subsystem 1000-1 and a second subsystem 1000-2 interconnected by IC modules. Specifically, subsystem 1000-1 is configured to supply three-phase power, PA, PB, and PC, to a first load (not shown) by way of system I/O ports SIO1, SIO2, and SIO3, while subsystem 1000-2 is configured to supply three-phase power PD, PE, and PF to a second load (not shown) by way of system I/O ports SIO4, SIO5, and SIO06, respectively. For example, subsystems 1000-1 and 1000-2 can be configured as different packs supplying power for different motors of an EV or as different racks supplying power for different microgrids.

In this implementation each module 108IC is coupled with a first array of subsystem 1000-1 (via IO port 1) and a first array of subsystem 1000-2 (via IO port 2), and each module 108IC can be electrically connected with each other module 108IC by way of I/O ports 3 and 4, which are coupled with the energy source 206 of each module 108IC as described with respect to module 108C of FIG. 3C. This connection places sources 206 of modules 108IC-1, 108IC-2, and 108IC-3 in parallel, and thus the energy stored and supplied by modules 108IC is pooled together by this parallel arrangement. Other arrangements such as serious connections can also be used. Modules 108IC are housed within a common enclosure of subsystem 1000-1, however the interconnection modules can be external to the common enclosure and physically located as independent entities between the common enclosures of both subsystems 1000.

Each module 1081C has a switch unit 604-1 coupled with IO port 1 and a switch unit 604-2 coupled with I/O port 2, as described with respect to FIG. 10B. Thus, for balancing between subsystems 1000 (e.g., inter-pack or inter-rack balancing), a particular module 108IC can supply relatively more energy to either or both of the two arrays to which it is connected (e.g., module 108IC-1 can supply to array 700-PA and/or array 700-PD). The control circuitry can monitor relative parameters (e.g., SOC and temperature) of the arrays of the different subsystems and adjust the energy output of the IC modules to compensate for imbalances between arrays or phases of different subsystems in the same manner described herein as compensating for imbalances between two arrays of the same rack or pack. Because all three modules 108IC are in parallel, energy can be efficiently exchanged between any and all arrays of system 100. In this implementation, each module 108IC supplies two arrays 700, but other configurations can be used including a single IC module for all arrays of system 100 and a configuration with one dedicated IC module for each array 700 (e.g., six IC modules for six arrays, where each IC module has one switch unit 604). In all cases with multiple IC modules, the energy sources can be coupled together in parallel so as to share energy as described herein.

In systems with IC modules between phases, interphase balancing can also be performed by neutral point shifting (or common mode injection) as described above. Such a combination allows for more robust and flexible balancing under a wider range of operating conditions. System 100 can determine the appropriate circumstances under which to perform interphase balancing with neutral point shifting alone, interphase energy injection alone, or a combination of both simultaneously.

IC modules can also be configured to supply power to one or more auxiliary loads 301 (at the same voltage as source 206) and/or one or more auxiliary loads 302 (at voltages stepped down from source 302). FIG. 10D is a block diagram depicting an example of a three-phase system 100 A with two modules 108IC connected to perform interphase balancing and to supply auxiliary loads 301 and 302. FIG. 10E is a schematic diagram depicting this example of system 100 with emphasis on modules 108IC-1 ad 108IC-2. Here, control circuitry 102 is again implemented as LCD 114 and MCD 112 (not shown). The LCDs 114 can receive monitoring data from modules 108IC (e.g., SOC of ES1, temperature of ES1, Q of ES1, voltage of auxiliary loads 301 and 302, etc.) and can output this and/or other monitoring data to MCD 112 for use in system control as described herein. Each module 108IC can include a switch portion 602A (or 602B described with respect to FIG. 6C) for each load 302 being supplied by that module, and each switch portion 602 can be controlled to maintain the requisite voltage level for load 302 by LCD 114 either independently or based on control input from MCD 112. In this implementation, each module 108IC includes a switch portion 602A connected together to supply the one load 302, although such is not required.

FIG. 10F is a block diagram depicting another example of a three-phase system configured to supply power to one or more auxiliary loads 301 and 302 with modules 108IC-1, 108IC-2, and 108IC-3. In this implementation, modules 108IC-1 and 108IC-2 are configured in the same manner as described with respect to FIGS. 10D-10E. Module 108IC-3 is configured in a purely auxiliary role and does not actively inject voltage or current into any array 700 of system 100. In this implementation, module 108IC-3 can be configured like module 108C of FIG. 3B, having a converter 202B,C (FIGS. 6B-6C) with one or more auxiliary switch portions 602A, but omitting switch portion 601. As such, the one or more energy sources 206 of module 108IC-3 are interconnected in parallel with those of modules 108IC-1 and 108IC-2, and thus this implementation of system 100 is configured with additional energy for supplying auxiliary loads 301 and 302, and for maintaining charge on the sources 206A of modules 108IC-1 and 108IC-2 through the parallel connection with the source 206 of module 108IC-3.

The energy source 206 of each IC module can be at the same voltage and capacity as the sources 206 of the other modules 108-1 through 108-N of the system, although such is not required. For example, a relatively higher capacity can be desirable in an implementation where one module 108IC applies energy to multiple arrays 700 (FIG. 10A) to allow the IC module to discharge at the same rate as the modules of the phase arrays themselves. If the module 108IC is also supplying an auxiliary load, then an even greater capacity may be desired so as to permit the IC module to both supply the auxiliary load and discharge at relatively the same rate as the other modules.

### Second Life Energy Source Examples

Energy sources 206 described herein can be used in systems 100 described herein in both first life and second life applications. A first life of a source 206 is an original application in which source 206 is used. For example, the first life application is the first implementation in which sources 206 are put to use by the first customer of sources 206 after their original manufacture (and not refurbishment). The user of sources 206 in their first life will typically have received sources 206 from the manufacturer, distributor, or original equipment manufacturer (OEM). Batteries 206 used in a first life application will typically have the same electrochemistry (e.g., will have the same variant of lithium ion electrochemistry (e.g., LFP, NMC)) and will have the same nominal voltage and will have a capacity variation across the pack or system that is minimal (e.g., 5% or less). Use of an energy storage system with batteries 206 in their first life application will result in batteries 206 having a longer lifespan in that first life application, and upon removal from that first life application, the batteries 206 will be more similar in terms of capacity degradation than batteries from a first life application not using the energy storage system.

As used herein, a “second life” application is any application or implementation after the first life application (e.g., a second implementation, third implementation, fourth implementation, etc.) of source 206. A second life energy source refers to any energy source (e.g., battery or HED capacitor) implemented in that source's second life application.

An example of a first life application for batteries 206 is within an energy storage system for an EV. Then, at the end of that life (e.g., after 100,000 miles of driving, or after degradation of the batteries within that battery pack by a threshold amount), the batteries 206 can be removed from the battery pack, optionally subjected to refurbishing and testing, and then implemented in a second life application that can be, e.g., used within a stationary energy storage system (e.g., residential, commercial, or industrial energy buffering, EV charging station energy buffering, renewable source (e.g., wind, solar, hydroelectric), energy buffering, and the like) or another mobile energy storage system (e.g., battery pack for an electric car, bus, train, or truck). Similarly, the first life application can be a first stationary application and the second life application can be a stationary or mobile application.

For the second life application, sources 206 can be selected and/or utilized by system 100 to minimize (or at least reduce) any differences in initial capacity and nominal voltage. For example, sources 206 having a capacity difference of 5% or more can be included within system 100 and operated to provide energy for a load. In another example, an operator or automated system can select sources 206 for system 100 that have a capacity difference within a threshold amount, e.g., to reduce the initial capacity differences between sources of system 206. If modules 108 are compatible with both the first and second life application (e.g., with or without reconfiguration), modules 108 can be selected for the second life application based on the capacity difference of sources 206 of modules 108.

System 100 can adjust utilization of each source 206 individually such that sources 206 within system 100 or packs of system 100 are relatively balanced in terms of SOC or total charge (SOC times capacity) as the pack or system 100 is discharged, even though the sources 206 in system 100 can have widely varying capacities. Similarly, system 100 can maintain balance as the pack or system 100 is charged. Sources 206 can vary not only in terms of capacity but also in nominal voltage, power rating, electrochemical type (e.g., a combination of LFP and NMC batteries) and the like. Thus, system 100 can be used such that all modules 206 within system 100 or each pack of system 100 are second life energy sources (or such that a combination of first life and second life energy sources are used), having various combinations of different characteristics.

In one example, system 100 can include second life energy sources 206 (and optionally one or more first life energy sources 206) having energy capacity variations of 2% or more, 5% or more, 10% or more, 15% or more, 20% or more, or 25% or more, 30% or more, 5-30%, 10-30%, and/or 20-30%.

In another example, system 100 can include second energy life sources 206 (and optionally one or more first life energy sources 206) having energy capacity per mass density variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having peak power per mass density variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having nominal voltage variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having operating voltage range variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having maximum specified current rise time variations of 2% or more, 5% or more, 10% or more, 15% or more, 20% or more, or 25% or more, 30% or more, 5-30%, 10-30%, and/or 20-30%.

In another example, system 100 can include second life energy sources 206 (and optionally one or more first life energy sources 206) having specified peak current variations of 2% or more, 5% or more, 10% or more, 15% or more, 20% or more, or 25% or more, 30% or more, 5-30%, 10-30%, and/or 20-30%.

A variation of X % (e.g., 5% or more, or 5 to 30%) can be met by a variation between the module 108 having the highest value for that parameter and the module 108 having the lowest value for that parameter within system 100. For example, a variation of 5% or more in capacity can be met by a system 100 where the module 108 with the lowest capacity source 206 has a capacity that is 95% or less than that of the module 108 with the highest capacity source 206. For each and every embodiment and parameter disclosed herein, the time at which the system 100 having one or more second life sources satisfies the X % variation condition in that parameter can be at installation of the system 100, at commissioning of the system 100, after replacement of one source 206 with another source 206, after operation of system 100 for 10 hours or more, after operation of system 100 for 100 hours or more, after operation of system 100 for 1000 hours or more, and/or after operation of system 100 for 10,000 hours or more. For example, a variation of capacity of 5% or more can occur after system 100 is operated for 1000 hours, even though the variation in capacity was not present at the time of commissioning. This reflects the capability of the embodiments of system 100 to continue to operate with and account for capacity differences between sources 206 that grow over time of operation.

In another example, system 100 can include second life energy sources 206 (and optionally one or more first life energy sources 206) having variations of electrochemical type (e.g., lithium ion batteries with non-lithium ion batteries, or different lithium ion batteries (e.g., any combination of NMC, LFP, LTO, or other lithium ion battery types).

System 100 can include second life energy sources 206 (and optionally one or more first life energy sources 206) having any combination of the characteristics provides in the preceding examples.

### Islanding Condition Detection Examples

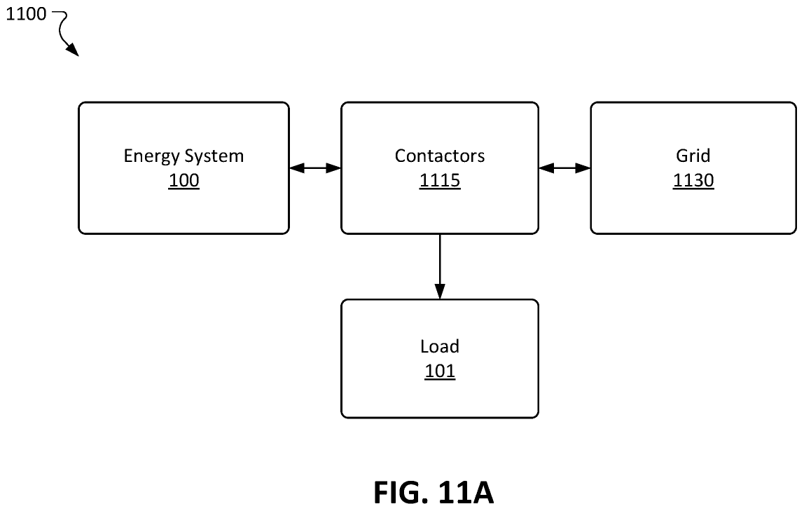

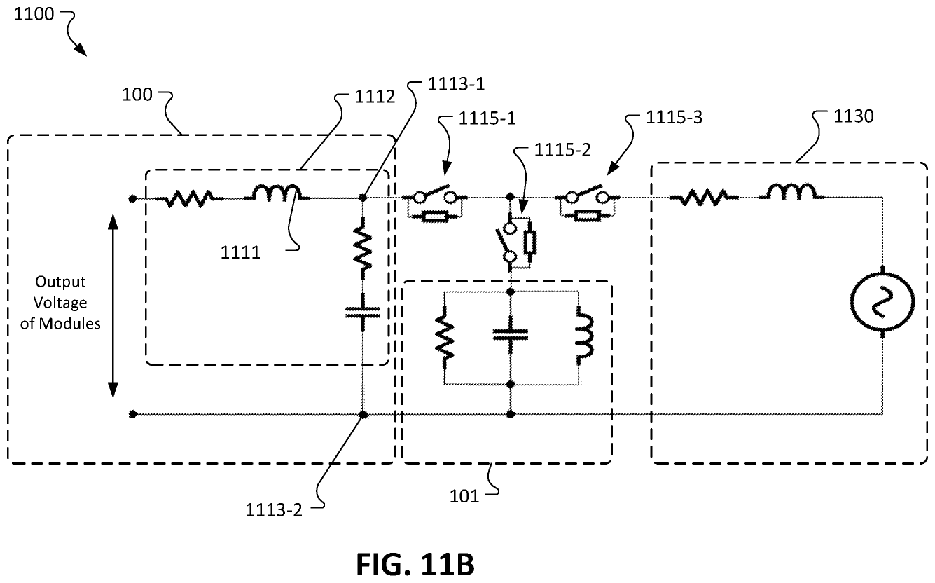

FIG. 11A is a block diagram depicting an example of grid-connected system 1100 in which an energy system 100 is connected to a load 101, such as auxiliary loads 301 or 302 in FIG. 10E, and a grid 1130. The system 100 can include an MCD 112 and modules 108 that can be arranged in one or more arrays 700, as described above in relation to FIGS. 10A-10F. Any of the implementations of system 100 described in this specification can be used in grid-connected system 1100.

System 100 is connected to load 101 and grid 1130 using circuit contactors 1115. System 100 is configured to provide power to load 101 and/or to grid 1130. System 100 can also receive power from grid 1130. In this example, system 100 and load 101 can be referred to as a micro-grid that is connected to grid 1130. Grid 1130 can be a utility-operated power grid that also provides power to the micro-grid load 101.

System 100 can be configured to operate in multiple modes. One example mode is grid-tied mode, which can also be referred to as grid-following mode. When system 100 is connected to grid 1130 and grid 1130 is operating normally, e.g., without an error or other condition causing system 100 to disconnect from grid 1130, system 100 can operate in the grid-tied mode in which system 100 follows the voltage, frequency, and phase of grid 1130 while regulating the amount of current provided to load 101. In other words, system 100 can provide, to load 101, AC power (e.g., single-phase AC signal or multi-phase AC signals) having a regulated current at the same voltage, frequency, and phase as the one or more AC signals provided by grid 1130.

Another example mode is stand-alone mode In this case, the system 100 supplies the load 101 with a voltage whose frequency, amplitude, and/or phase could be different from that of the grid 1130. When system 100 detects an error or other condition for which system 100 is configured to disconnect from grid 1130, e.g., an island or islanding condition, system 100 can disconnect from grid 1130 and operate in stand-alone mode. An example of an islanding condition is a blackout or other short term or long term loss of power from grid 1130. During an islanding condition and until disconnected from grid 1130, system 100 may still provide power to grid 1130, which is unsafe. System 100 can disconnect from grid 1130 and continue providing power to load 101 in stand-alone mode. In stand-alone mode, system 100 can act as a voltage controller to regulate the voltage provided to load 101. System 100 can regulate the voltage provided to load 101 such that the voltage, frequency, and phase of the AC power provided to load 101 matches the last known voltage, frequency, and phase of grid 1130 before system 100 disconnected from grid 1130.

System 100 can also be configured to operate in other modes. For example, system 100 can be configured to operate in a grid-tied rectifier mode, grid-tied charger/discharger mode. Grid-tied rectifier mode is a mode in which system 100 is connected to grid 1130 and modules 108 of system 100 regulate a DC bus voltage to provide power to a DC load 101. Grid-tied charger/discharger mode is a mode in which system 100 is connected to grid 1130 and modules 108 of system 100 regulate a charging or discharging current to charge or discharge an energy source 206.

FIG. 11B is an electrical equivalence diagram depicting the example of the grid-connected system 1100 in which the energy system 100 is connected to the micro-grid load 101 and the grid 1130. System 100 includes an output filter 1112 configured to filter the voltage output by all of modules 108 of system 100 to provide precise and accurate output voltages. The filtered output voltage is connected to load 101 and grid 1130 at nodes 1113-1 and 1113-2, which may include terminals. To measure the output impedance of system 100, and therefore the output impedance of modules 108 of system 100, the voltage across points 1113-1 and 1113-2 can be measured along with the current flowing between points 1113-1 and 1113-2. The ratio of the voltage across points 1113-1 and 1113-2 and the current flowing between points 1113-1 and 1113-2 provides the impedance of load 101 when the contactors 1115 are closed. As described herein, this output impedance of system 100 can be used to detect an islanding condition for system 100.

Contactors 1115 can switch between a closed state that permits current flow and an open state that blocks current flow. Contactors 1115 include a main contactor 1115-1 configured to connect and disconnect system 100 to and from both load 101 and grid 1130 (depending on the states of contactors 1115-2 and 1115-3). Contactor 1115-2 is configured to connect and disconnect load 101 from system 100 and grid 1130 (depending on the states of contactors 1115-1 and 1115-3). Contactor 1115-3 is configured to connect and disconnect grid 1130 to system 100 and load 101 (depending on the states of contactors 1115-1 and 1115-2).

MCD 112 of system 100 can be communicably coupled to contactors 1115 to control operation of contactors 1115. MCD 112 can issue a control signal that causes contactors 1115 to selectively open and close, in any combination, depending on the mode of operation of system 100 and/or the status of system 100, load 101, or grid 1130. For example, when system 100 detects an islanding condition, MCD 112 can open contactor 1115-3 to disconnect system 100 and load 101 from grid 1130. MCD 112 can also transition to the stand-alone mode of operation in response to detecting the islanding condition.

Load 101 has an impedance that can be represented by a resistor, capacitor, and/or inductor depending on the type(s) of load(s) connected to system 100. Similarly, grid 1130 has an impedance that can be represented by a resistor and inductor. The impedance of grid 1130 can vary based on the quality of grid 1130 and the current condition of grid 1130, e.g., whether power is present on grid 1130.

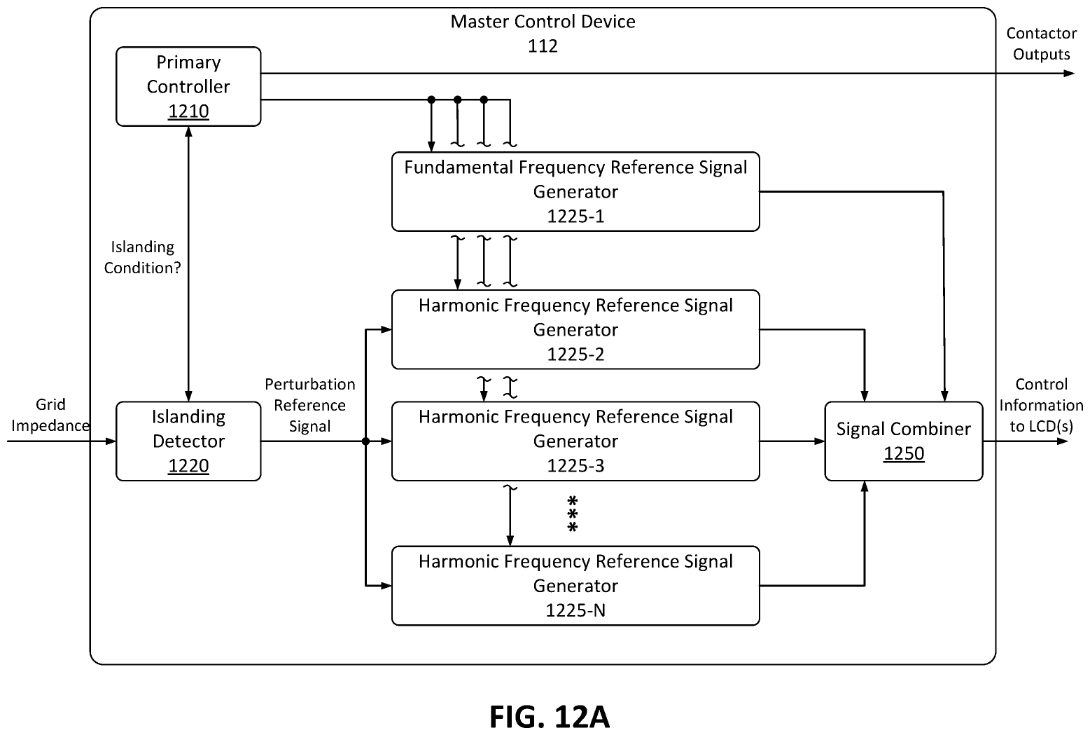

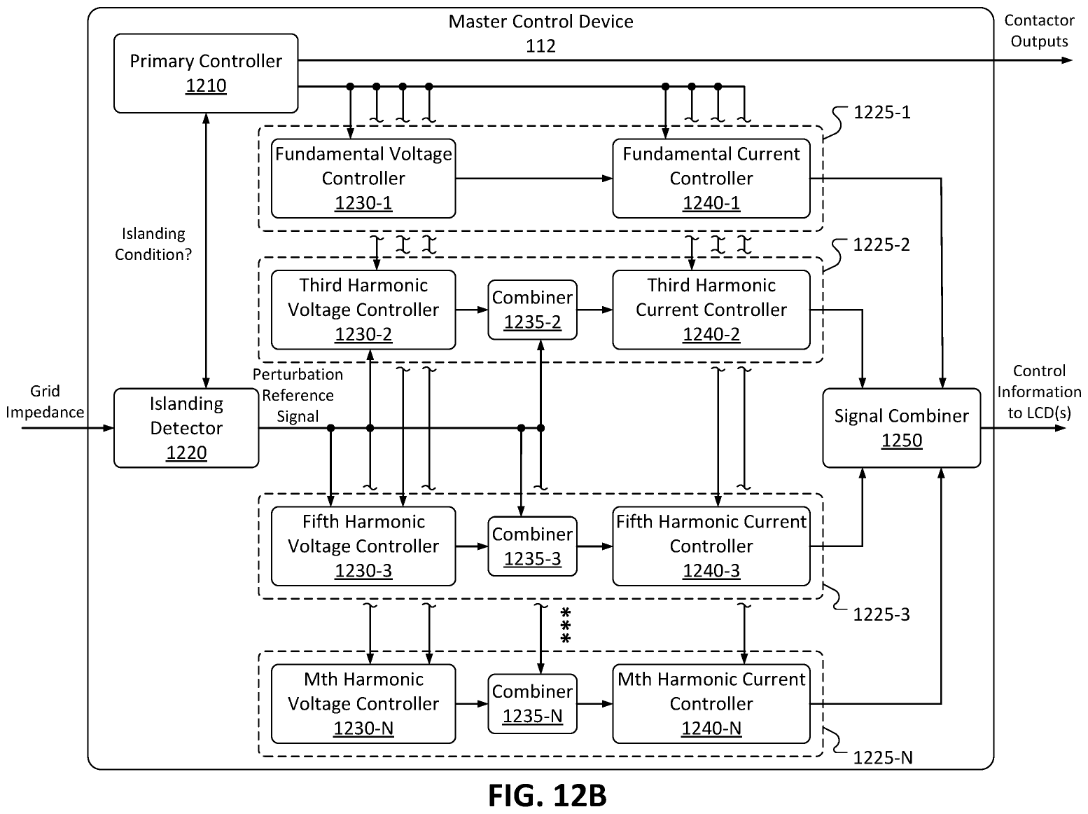

FIG. 12A is a block diagram depicting an example of an MCD 112. MCD 112 includes a primary controller 1210, an islanding detector 1220, a fundamental frequency reference signal generator 1225-1, a number of harmonic frequency reference signal generators 1225-2-1225-N, and a signal combiner 1250. In some implementations, the islanding detector 1220 can be distributed throughout LCDs 114. Additionally or alternatively, a single tunable generator can generate multiple harmonic frequencies. MCD 112 can include other components described herein. Primary controller 1210 and each reference signal generator 1225 can be implemented in hardware, e.g., by processing circuitry described herein, software, e.g., using software modules and/or routines with specific functions, or a combination of hardware and software.

In general, MCD 112 generates control information and sends the control information to modules 108 of system 100. The control information can include a normalized reference signal Vrn for each module 108 of system 100 and a modulation index Mi for each module 108. The normalized reference signal can be the same for each module 108 in an array 700, while the modulation index Mi can differ for different modules 108 in each array 700. In some implementations, the control information includes a modulated reference signal. For example, MCD 112 can scale or modulate the normalized reference signal Vrn for each module 108 using its modulation index Mi.

The normalized reference signal can be a normalized reference voltage waveform (Vrn) or a normalized reference current waveform (Irn). For a particular module 108, the normalized reference signal Vrn can be modulated or scaled by Mi and this modulated reference signal Vrnm can be used as a Vref (or −Vref) according to the PWM technique described with reference to FIGS. 8C-8F, or according to other techniques. Similarly, for a particular module 108, the normalized reference current waveform Irn can be modulated or scaled by Mi and this modulated reference signal Irmm can be used as a Vref (or −Vref) according to the PWM technique described with reference to FIGS. 8C-8F, or according to other techniques.

MCD 112 can send the control information to modules 108 of system 100 on an ongoing basis, e.g., continuously or periodically, and the control information can change over time based on any changing status of modules 108 or requirements of load 101. To detect when system 100 is in an islanding condition, MCD 112 can insert a perturbation signal into the control information, e.g., into the normalized reference signal Vrn or Irn, that causes modules 108 of system 100 to inject a perturbation current at a harmonic frequency on the output of system 100. For example, the modulated reference signal can be in the form of an AC voltage or current waveform having components at the fundamental frequency and components at the harmonic frequency. In general, fundamental frequency reference signal generator 1225-1 generates the fundamental frequency components of the normalized reference signal and one or more harmonic frequency signal generator 1225-2 to 1225-N generate the harmonic frequency components of the normalized reference signal. In some implementations, a single reference signal generator can generate both the fundamental and the harmonic frequency components of the normalized reference signal. The fundamental frequency components can include an AC waveform at the fundamental frequency and the harmonic frequency components can include one or more AC waveforms at various harmonic frequencies. As described in more detail herein, islanding detector 1220 can determine the output impedance of modules 108 of system 100 at one or more harmonic frequencies and use this impedance to determine whether system 100 is in an islanding condition.

Primary controller 1210 can generate a reference signal for fundamental frequency reference signal generator 1225-1, e.g., based on the power requirements of load 101. Depending on the mode of operation, this reference signal can be a voltage reference signal or a current reference signal. The modes can include, for example, grid-tied mode and stand-alone mode.

Primary controller 1210 can include one or more balance controllers. In single array implementations, primary controller 1210 can include a controller similar to controller 900 of FIG. 9A. However, primary controller 1210 can be configured to output a reference signal rather than a normalized reference signal, e.g., by not dividing the reference signal by the peak prior to outputting the reference signal. Primary controller 1210 can include intraphase balance controller 906, which is configured to generate modulation indexes Mi for modules 108 of an array 700 based on status information, as described herein.

In multi-phase implementations that include multiple arrays 700, primary controller 1210 can include a controller similar to controller 950 of FIG. 9B. However, primary controller 1210 can be configured to output a reference signal for each array 700 rather than a normalized reference signal for each array, e.g., by not dividing the reference signal for each array 700 by the peak for the array 700. Primary controller 1210 can include an interphase balancing controller 910 and respective intraphase balance controllers 906 for the multiple arrays 700 for generating the modulation indexes for each module 108 of each array 700 based on status information, as described herein. Primary controller 1210 can generate the modulation indexes Mi in either mode of system 100. In some implementations, the various controllers of FIGS. 9A and 9B, e.g., controller 900, interphase balancing controller 910, intraphase balance controllers 906, and controller 950, can be combined into a single controller.

In grid-tied mode, MCD 112 controls modules 108 to output an AC waveform having a voltage, frequency, and phase that matches the voltage, frequency, and phase, respectively, of grid 1130. MCD 112 also regulates the current of the AC waveform output by modules 108 based on power requirements of load 101. In some implementations, system 100 includes a phase lock loop (PLL) (not shown) that has a phase detector coupled to grid 1130 and that outputs a voltage reference signal to MCD 112. This voltage reference signal can have a voltage, frequency, and phase that is based on the voltage, frequency, and phase of grid 1130. Primary controller 1210 can receive the voltage reference signal from the PLL. In some implementations, MCD 112 can include the PLL.

System 100 can also receive voltage and current measurements from voltage and current sensors (not shown) electrically coupled to grid. These sensors can report to corresponding inputs of system 100 voltage and current measurements that indicate the current voltage and current of grid 1130. MCD 112 or another appropriate component of system 100 can generate a voltage reference signal that has a voltage, frequency, and phase that is based on the voltage, frequency, and phase of grid 1130. For example, MCD 112 can generate the voltage reference signal using frequency and phase measurements received from the PLL's phase detector and the voltage and current measurements received from the voltage and current sensors.

To regulate the current, primary controller 1210 can generate a current reference signal based on the power requirements of load 101 and provide the current reference signal to fundamental frequency reference signal generator 1225-1. The current reference signal can be in the form of an AC current waveform. Fundamental frequency reference signal generator 1225-1 can be configured to generate a voltage reference signal Vrf at a fundamental frequency for system 100 to regulate the output current of system 100. The fundamental frequency voltage reference signal Vrf can be in the form of an AC voltage waveform. In general, fundamental frequency reference signal generator 1225-1 can use closed loop control techniques, e.g., using one or more controllers, to generate the fundamental frequency voltage reference signal Vrf based on the current reference signal and an actual measurement of the output current of system 100. Example closed loop control techniques are described with reference to FIG. 12B. Fundamental frequency reference signal generator 1225 outputs the fundamental frequency voltage reference signal Vrf to signal combiner 1250. The operation of the harmonic frequency signal generators 1225-2 to 1225-N can be similar to that of the fundamental frequency reference signal generator 1225-1, except that the frequencies are different.

Signal combiner 1250 is configured to combine the fundamental frequency voltage reference signal Vrf with any harmonic frequency voltage reference signals output by harmonic frequency signal generators 1225-2 to 1225-N. For example, signal combiner 1250 can generate a combined voltage reference signal Vrc by summing the individual voltage reference signals.

Signal combiner 1250 can normalize the combined voltage reference signal Vrc, e.g., by dividing by the peak voltage of the fundamental frequency voltage reference signal Vrf, to generate a normalized voltage reference signal Vrn. Signal combiner 1250 sends control information to each module 108 of system 100. The control information for module 108 can include the normalized reference signal and the modulation index for module 108. Signal combiner 1250 can send the control information for a module 108 to LCD 114. As described herein, LCD 114 can control switches of module 108 based on the reference signal and modulation index.

In some implementations, signal combiner 1250 generates, for each module 108, a modulated reference signal by scaling or modulating the normalized reference signal Vrn for the module 108 using the modulating index Mi for the module 108. In this example, the control information for a module 108 can include the modulated reference signal for the module 108.

In stand-alone mode, MCD 112 controls modules 108 of system 100 to output an AC waveform having a voltage, frequency, and phase that matches a last normal, e. g., in specification, voltage, frequency, and phase, respectively, of grid 1130. MCD 112 can operate as a voltage regulator in stand-alone mode, e.g., rather than a current regulator as in grid-tied mode. Primary controller 1210, or other portion of MCD 112, can monitor and record the voltage, frequency, and phases of the AC signal received from grid 1130. Upon detecting an islanding condition, as described in detail below, and disconnecting from grid 1130, primary controller 1210 can determine the last normal voltage, frequency, and phase of grid 1130, e.g., the final measurement of these values before grid 1130 lost power, with comparisons against operating range requirements as necessary to determine the last normal conditions, and control modules 108 of system 100 to output an AC waveform that has a voltage, frequency, and phase that matches the last normal voltage, frequency, and phase of grid 1130, respectively. In some implementations, controller 1210 can use a moving central tendency, e.g., average or median, value taking into account voltage, frequency, and phase measurements over a short time period, e.g., 10 seconds or 30 seconds, prior to the islanding condition. For brevity, the last normal voltage, frequency, and phase can also be referred to as the last normal values of grid 1130.

To regulate the voltage, primary controller 1210 can generate a voltage reference signal based on the last normal values of grid 1130 and provide the voltage reference signal to fundamental frequency reference signal generator 1225-1. The voltage reference signal can be in the form of an AC voltage waveform. Fundamental frequency reference signal generator 1225-1 can be configured to generate a voltage reference signal Vrf at a fundamental frequency for system 100 to regulate the output voltage of system 100. In general, fundamental frequency reference signal generator 1225-1 can use closed loop control techniques to generate the fundamental frequency voltage reference signal Vrf based on the voltage reference signal and an actual measurement of the output voltage of system 100. Example closed loop control techniques are described with reference to FIG. 12B. Fundamental frequency reference signal generator 1225 outputs the fundamental frequency voltage reference signal Vrf to signal combiner 1250.

Signal combiner 1250 can operate the same in either mode, e.g., in grid-tied mode and in stand-alone mode, which can also be referred to as an island mode or grid-forming mode. Island mode refers to when the system 100, e.g., a battery energy storage system (BESS) and the load 101 are disconnected from the grid 1130, although the system 100 and load 101 can still be connected to each other. In either mode, signal combiner 1250 can combine the fundamental frequency voltage reference signal Vrf with any harmonic frequency voltage reference signals output by harmonic frequency signal generators 1225-2 to 1225-N, as described above.

The presence of switching dead time in modules 108 of system 100 can be a cause for the appearance of harmonics that distort the output waveform. For example, the switching dead time can result in the appearance of third and fifth harmonics on the output waveform of modules 108. In some implementations, the switching dead time can vary between modules 108. Due to the cascaded nature of modules 108, these harmonics can accumulate and, if so, should be compensated. If a particular harmonic, e.g., the fifth harmonic, is not compensated completely, it is possible to identify the effect of this harmonic on the output waveform. When the switching dead time varies between modules 108, the various switching dead times can be used to determine how to compensate for each harmonic. The effect of compensating for the accumulated harmonics can be used to compute an approximation of the output impedance of system 100, which can be used to detect an islanding condition. For example, the accumulated harmonics can introduce a harmonic current at the output of modules 108. The output impedance at the fifth harmonic frequency can be calculated as the ratio of the output voltage of system 100 at the fifth harmonic frequency and the output current of system 100 at the fifth harmonic frequency. When system 100 is connected to a utility via grid 1130, the fifth harmonic output impedance is very low. In contrast, the fifth harmonic output impedance is very high when the utility is not providing AC power by way of grid 1130 to system 100 and load 101. In some implementations, higher order harmonic frequencies (e.g., 5^{th} order, 7^{th} order, 9^{th} order, etc.) allow faster detection of islanding conditions.

Islanding detector 1220 is configured to cause some or all modules 108 of system 100 to generate the perturbation signal and to then measure the impedance at the output of modules 108 while the perturbation signal is present. To do so, islanding detector 1220 is configured to cause one or more harmonic frequency reference signal generators 1225-2 to 1225-N to generate and output a harmonic frequency voltage reference signal to signal combiner 1250.

Islanding detector 1220 can be configured to cause modules 108 of system 100 to generate the perturbation signal periodically based on a specified island detection time period. In other words, modules 108 of system 100 may not continuously generate the perturbation signal. Instead, modules 108 can generate the perturbation signal periodically so that islanding detector 1220 can evaluate whether an islanding condition is present during each period in which the perturbation signal is generated. For example, the modules 108 can generate perturbations at a frequency of 5 Hz with an amplitude of 0-1 A. As harmonic currents can increase the THD, generating the perturbation signal periodically rather than continuously can reduce the THD of the output of modules 108 as compared to a continuous perturbation signal, e.g., reduce by 10%. In addition, generating the perturbation signal periodically enables the perturbation signal to have a higher amplitude, which improves the accuracy of the islanding detection while still dissipating the same average power.

Islanding detector 1220 can send a perturbation reference signal to one or more harmonic frequency reference signal generators 1225-2 to 1225-N using the specified island detection time period and using a specified perturbation duty cycle. For example, the islanding detector 1220 determines an upper limit on the duration of the perturbation reference signal using the specified island detection time period. For example, determining an upper limit can include the upper limit to be 75%, 90%, or some other value of the specified island detection time period. Setting an upper limit of the duration of the perturbation reference signal can ensure that enough of the perturbation reference signal can be detected for correct recognition. As another example, islanding detector 1220 can use the specified perturbation duty cycle to determine an upper limit on the frequency of injecting the perturbation reference signal. In some implementations, the duty cycle is 50%. The island detection time period can represent an amount of dead time between injections of the perturbation current. For example, assume that islanding detector 1220 is configured to cause harmonic frequency reference signal generator 1225-2 to output a harmonic frequency voltage reference signal to signal combiner 1250. In the 50% duty cycle example, islanding detector 1220 sends the perturbation reference signal to harmonic frequency reference signal generator 1225-2 for a period time that matches the specified island detection time period. In a particular example, the specified island detection time period can be 25 milliseconds (ms). In this example, for every recurring 50 ms time period, islanding detector 1220 sends the perturbation reference signal to harmonic frequency reference signal generator 1225-2 for a continuous 25 ms and does not send the perturbation reference signal to the harmonic frequency reference signal generator 1225-2 for a continuous 25 ms. In turn, modules 108 generate the perturbation signal at the harmonic frequency of harmonic frequency reference signal generator 1225-2 for 25 ms and do not generate the perturbation signal for 25 ms for each 50 ms time period.

Other appropriate island detection time periods and duty cycles can also be used. For example, shorter duty cycles can be used to further reduce THD. In another example, longer duty cycles can be used and/or multiple impedance measurements can be generated for each injection of perturbation current in implementations in which faster islanding detection is required or desired.

In some implementations, all modules 108 of system 100 generate a portion of the perturbation signal output by system 100 and used for islanding detection. In some implementations, a proper subset of all modules 108 of system 100 generate respective portions of the perturbation signal. For example, signal combiner 1250 can be configured to combine the harmonic frequency voltage reference signal(s) with the fundamental frequency voltage reference signal Vrf for only the modules 108 in the proper subset. For the other modules 108, signal combiner 1250 can normalize the fundamental frequency voltage reference signal Vrf and include this normalized reference signal Vrn in the control information for the other modules 108. The subset can be chosen based on efficiency, temperature, or status of the modules, e.g., selecting more efficient modules, cooler modules, or not selecting modules in bypass-mode.

In an example, islanding detector 1220 may be configured to evaluate whether an islanding condition is present based on an output impedance of modules 108 of system 100 at the fifth harmonic frequency when the perturbation signal is output by modules 108. Other appropriate harmonic frequencies may alternatively be used. Islanding detector 1220 can receive data indicating the output impedance for each islanding detection time period and compare the output impedance to an impedance threshold. If the output impedance satisfies the impedance threshold, e.g., by equaling or exceeding the impedance threshold, islanding detector 1220 can determine that an islanding condition is present and notify primary controller 1210. If the output impedance does not satisfy the impedance threshold, islanding detector 1220 can determine that an islanding condition is not present. If an islanding condition is present, primary controller 1210 can transition from grid-tied mode to stand-alone mode.

To improve the accuracy of islanding detection, islanding detector 1220 can obtain a baseline impedance measurement at the frequency of the harmonic frequency of the perturbation signal. In some implementations, the perturbation signal includes two or more harmonic frequencies, e.g., both the third and fifth harmonic frequencies. The baseline impedance measurement is a measure of the impedance of the output of modules 108 of system 100 when the perturbation signal is not being output by modules 108. Islanding detector 1220 can use the baseline impedance measurement when determining whether an islanding condition is present. For example, islanding detector 1220 can compare the output impedance of modules 108 when the perturbation signal is present to a sum of the baseline impedance measurement and the impedance threshold. In this way, islanding detector 1220 can determine that an islanding condition is present when the output impedance is at least the threshold amount greater than the baseline impedance measurement.

MCD 112 can cause modules 108 to output a perturbation signal, e.g., a perturbation voltage and/or perturbation current, at a specified harmonic frequency, e.g., the fifth harmonic frequency. The islanding detector 1220 can receive data indicating the output impedance of system 100, e.g., the output impedance of modules 108 of system 100, at the specified harmonic frequency. In some implementations, the specified harmonic frequency can be selected by a user in real time. If the measured impedance exceeds an impedance threshold, MCD 112 can determine that an islanding condition is present. In some implementations, system 100 includes integrators that integrate the total impedance over all modules (see FIG. 11B) corresponding to one or more harmonic frequency reference signals over a predetermined period of time.

In some implementations, measurements of impedance of individual modules 108 is used to determine that an islanding condition has occurred. For example, LCDs 114 rather than the MCD 112 can use measurements of the impedance one or more modules 108 compared to a particular impedance threshold for the one or more modules 108 to detect an islanding condition in the one or more modules 108. In those cases, only a subset of modules 108 can receive the perturbation reference signal.

In some implementations, distributed impedance measurements can improve system reliability. For example, if a current or voltage sensor in system 100 communicating with the MCD 112 is not working properly, instead of having the shutdown, the system 100 can rely on sensors communicating with individual LCDs 114. As another example, when impedance measurements for one or more modules 108 disagree, the MCD 114 can run an algorithm for determining an impedance measurement based on different impedance measurements.

In this example, MCD 112 includes a number of harmonic frequency reference signal generators 1225-2 to 1225-N for N−1 harmonic frequencies. In some implementations, MCD 112 can include a harmonic frequency reference signal generator 1225 for a single harmonic frequency used for islanding detection. In some implementations, MCD 112 includes multiple harmonic frequency reference signal generators 1225-2 to 1225-N for multiple harmonic frequencies to provide flexibility in using a harmonic frequency that works best for detecting islanding conditions for a particular grid 1130. Any appropriate harmonic frequencies can be used. For example, MCD 112 can enable system 100, a user, or external system 104 communicably coupled to MCD 112 to select a harmonic frequency for use in detecting islanding conditions. In response, MCD 112 can adjust the instructions from islanding detector 1220 to cause the harmonic frequency reference signal generator 1225 to generate a reference signal for the selected harmonic frequency.

Each harmonic frequency reference signal generator 1225-2 to 1225-N is configured to generate a harmonic frequency voltage reference signal based on perturbation reference signal received from islanding detector 1220. The perturbation reference signal can be in the form of a AC waveform at a harmonic frequency that has the target amplitude. Primary controller 1210 can receive the target amplitude from a user or external system 104. In another example, system 100, e.g., islanding detector 1210, can determine the target amplitude based on, for example, characteristics of grid 1130 and/or an output impedance of system 100 at a harmonic frequency when grid 1130 is normal.

Each harmonic frequency voltage reference signal can be an AC voltage waveform having a particular harmonic frequency. For example, fifth harmonic frequency reference signal generator 1225-3 can be configured to generate and output, as a harmonic frequency voltage reference signal, an AC voltage waveform at the fifth harmonic frequency of the fundamental frequency of system 100. Each harmonic frequency reference signal generator 1225-2 to 1225-N can be configured to generate and output a harmonic frequency voltage reference signal having a different harmonic frequency than each other harmonic frequency reference signal generator 1225-2 to 1225-N.

In general, the amplitude of the harmonic frequency voltage reference signal can be significantly less than the amplitude of the fundamental frequency voltage reference signal Vrf for islanding detection, as the impedance of grid 1130 at the harmonic frequencies is very low when utility power is present on grid 1130. For example, the amplitude of the harmonic frequency voltage reference signal can be less than 5%, e.g., 2% or less, of the amplitude of the fundamental frequency voltage reference signal. Other appropriate ratios or percentages can also be used. Thus, small increases in impedance at the harmonic frequencies can indicate when utility power is no longer present on grid 1130.

Islanding detector 1220 can obtain the baseline impedance measurement prior to applying the perturbation signal for the first time. Islanding detector 1220 can also obtain the baseline impedance measurement periodically, e.g., between successive injections of the perturbation signal. In this way, islanding detector 1220 can use a most recent baseline impedance measurement and dynamically account for any changes to the condition of grid 1130 that affects the baseline impedance at the harmonic frequency.

Islanding detector 1220 can also dynamically adjust the harmonic frequency at which the perturbation signal is generated. The output of islanding detector 1220 can be communicably coupled to an input of each harmonic frequency reference signal generator 1225-2 to 1225-N. Islanding detector 1220 can selectively provide the perturbation reference signal to one or more harmonic frequency reference signal generators 1225-2 to 1225-N to cause the one or more harmonic frequency reference signal generators 1225-2 to 1225-N to generate their respective harmonic frequency voltage reference signals.

Dynamically adjusting the harmonic frequency enables islanding detector 1220 to adjust to changing grid conditions and/or obtain more accurate impedance measurements for more accurate islanding detection. For example, if the baseline impedance at a particular harmonic frequency is high, e.g., greater than a threshold, or unstable, e.g., changing by at least a threshold amount within a time period, islanding detector 1220 can switch to a different harmonic frequency for islanding detection. In another example, if faster islanding detection is required or desired, a higher harmonic frequency can be used.

When an islanding condition is detected, islanding detector 1220 can notify primary controller 1210 that an islanding condition is present. In response, primary controller 1210 can transition system 100 from grid-tied mode to stand-alone mode. For example, primary controller 1210 can issue a control signal to contactors 1115 to disconnect system 100 from grid 1130, as described with reference to FIGS. 11A-11B. In addition, primary controller 1210 can determine the last normal voltage, frequency, and phase of grid 1130 and control modules 108 of system 100 to output an AC waveform that has a voltage, frequency, and phase that matches the last normal voltage, frequency, and phase, respectively, of grid 1130.

Primary controller 1210 can also transition system 100 from stand-alone mode to grid-tied mode when grid 1130 returns to normal, e.g., when utility power is restored to grid 1130. For example, primary controller 1210 can issue a control signal to contactors 1115 to reconnect system to grid 1130, as described with reference to FIGS. 11A-11B. In addition, primary controller 1210 can obtain data indicating the voltage, frequency, and phase of grid 1130, e.g., using a PLL as described above, and control modules 108 to output an AC waveform that has a voltage, frequency, and phase that matches the current voltage, frequency, and phase, respectively, of grid 1130. Primary controller 1210 can also control modules 108 to regulate current to load 101 as described herein.

Primary controller 1210 can receive data from an external system 104 indicating the grid 1130 has returned to normal. Islanding detector 1220 can also be configured to determine when grid 1130 has returned to normal. For example, when the grid 1130 and system 100 are reconnected, islanding detector 1220 can receive data indicating the impedance of grid 1130 at one or more harmonic frequencies and compare the impedance to an impedance threshold. If the impedance of grid 1130 at the harmonic frequency is less than the impedance threshold, islanding detector 1220 can determine that grid 1130 has returned to normal and notify primary controller 1210. The use of an impedance threshold reflects that the grid 1130 ideally has a low impedance, allowing the grid 1130 to supply power to vast areas without voltage collapse. Accordingly, exceeding an impedance threshold generally indicates that something is wrong with the grid 1130.

MCD 112 or an external control device 104 can provide a user interface, e.g., a graphical user interface (GUI), that enables a user to adjust various parameters of MCD 112. For example, MCD 112 can provide a user interface that enables a user to specify the one or more harmonic frequencies at which the perturbation signal is generated, the impedance threshold, the island detection time period, and/or the perturbation reference signal amplitude.

In multi-phase implementations, MCD 112 can be configured to output a perturbation signal on the output of any of the arrays 700, e.g., on one array 700, some but not all arrays 700, or all arrays 700. For example, fundamental frequency reference signal generator 1225-1 can be configured to generate a respective fundamental frequency voltage reference signal Vrf for each array 700. Signal combiner 1250 can be configured to combine the harmonic frequency voltage reference signal(s) with the fundamental frequency voltage reference signal Vrf for one array 700 or with the fundamental frequency voltage reference signal Vrf for multiple arrays 700. Islanding detector 1220 can receive impedance measurements for each array 700 that outputs a perturbation signal and compare the impedance measurements to the impedance threshold to detect when an islanding condition is present.

In some implementations, each module 108 that outputs a portion of the perturbation signal may output the perturbation signal at a same amplitude as each other module 108 that outputs a portion of the perturbation signal. In other words, balancing may not be applied to the perturbation signal in this case. For example, signal combiner 1250 can be configured to generate a modulated reference signal for each module 108 based on the normalized reference signal Vrn and the modulation indexes for modules 108. Then, signal combiner 1250 can combine the modulated reference signals with the harmonic frequency voltage reference signal(s) such that the modulation indexes are not applied to the harmonic frequency voltage reference signal(s).

FIG. 12B is a block diagram depicting an example MCD 112. Compared to FIG. 12A, FIG. 12B depicts a more unified control structure, e.g., offers more dynamic voltage control and can provide current limiting capabilities. MCD 112 includes harmonic frequency reference signal generators 1225-2-1225-N. Each harmonic frequency reference signal generator 1225-2-1225-N includes both a harmonic voltage controller and a harmonic current controllers, collectively referred to as harmonic controllers. The harmonic frequency reference signal generator 1225-2 includes a third harmonic frequency reference signal generator 1230-2 configured to generate a harmonic frequency voltage reference signal at the third harmonic of the fundamental frequency, and the fifth harmonic frequency reference signal generator 1225-3 includes a fifth harmonic frequency reference signal generator 1230-3 configured to generate a harmonic frequency voltage reference signal at the fifth harmonic of the fundamental frequency.

In this example, MCD 112 includes harmonic frequency reference signal generators 1225-2 to 1225-N for odd number harmonics, e.g., the third harmonic, the fifth harmonic, through an M-th harmonic. However, MCD 112 can include harmonic frequency reference signal generators for even number harmonics or a combination of odd and even number harmonics. The harmonics for which harmonic frequency reference signal generators are included can depend on which harmonics work best for harmonic noise suppression and/or islanding detection.

In this example implementation, each reference signal generator 1225 includes a multi-loop controller, e.g., controls the various closed circuit loops in FIG. 12A, that includes an outer voltage controller 1230 and an inner current controller 1240, e.g., signals pass from outer voltage controller 1230 toward the inner current controller 1240. For example, fundamental frequency reference signal generator 1225-1 includes an outer fundamental voltage controller 1230-1 and an inner fundamental current controller 1240-1. Similarly, fifth harmonic frequency reference signal generator 1230-3 includes an outer fifth harmonic voltage controller 1230-3 and an inner fifth harmonic current controller 1240-3. Each multi-loop controller can be implemented in hardware (e.g., by processing circuitry described herein), software (e.g., using software modules and/or routines with specific functions), or a combination of hardware and software.

In general, the multi-loop controller of each reference signal generator 1225 can be operated in a current control mode or a voltage control mode. In the current control mode, the voltage loop controller 1230 can be disabled such that the current controller 1240 generates an output AC voltage waveform having a particular frequency, e.g., at the fundamental frequency for current controller 1240-1, based on an error that represents a difference between a reference current, e.g., an error set point, and an actual current, e.g., feedback, at the output of system 100 at the particular frequency.

In some implementations, the voltage controller 1230, instead of the current controller 1240, generates the output AC voltage waveform based on an error. In these implementations, the output of the current controller 1240 is guided by the voltage error. In the voltage control mode, the voltage controller 1230 is enabled and generates an output AC voltage waveform having the particular frequency based on an error that represents a difference between a reference voltage and an actual voltage at the output of system 100 at the particular frequency. This output AC waveform is provided as an input to the corresponding current controller 1240. For example, voltage controller 1230-1 can generate an output AC voltage waveform at the fundamental frequency based on a difference between a reference voltage waveform and the actual voltage at the fundamental frequency. Current controller 1240-1 receives this output AC voltage waveform as a reference signal. Current controller 1240-1 generates an output AC voltage waveform based on an error that represents a difference between the reference AC voltage waveform received from voltage controller 1230-1 and the actual current waveform measured at the output of system 100 at the fundamental frequency, which can be scaled to match the scale of the reference AC voltage waveform.

Primary controller 1210 can also be configured to generate and provide reference signals as inputs to fundamental voltage controller 1230-1 and/or fundamental current controller 1240-1 depending on the mode, e.g., depending on whether system 100 is in grid-tied mode or stand-alone mode. Fundamental voltage controller 1230-1 and/or fundamental current controller 1240-1 can use the reference signal to generate a target AC voltage waveform at the fundamental frequency.

In grid-tied mode, MCD 112 controls modules 108 to output an AC waveform having a voltage, frequency, and phase that matches the voltage, frequency, and phase of grid 1130, respectively. Primary controller 1210 can disable fundamental voltage controller 1230-1 such that fundamental current controller 1240-1 generates a fundamental frequency voltage reference signal Vrf based on a difference between a target current setpoint and the output current of system 100 at the fundamental frequency for system 100. The target current setpoint can be a current reference signal received from primary controller 1210. Primary controller 1210 can be configured to determine the current reference signal based on power requirements of load 101. In some implementations, primary controller 1210 determines the current reference signal based on a power reference, e.g., received from a user or external system 104. In one example, primary controller 1210 can determine the current reference signal based on the measured grid voltage, and a power reference, e.g., a true power reference (P) and/or a reactive power reference (Q).

In some implementations, the voltage and current controllers 1230 and 1240 are configured to make the energy system 100 follow voltage and current set points, respectively. In some implementations, each of the voltage and current controllers 1230 and 1240 can be an FPGA, CPU, microcontroller, biological cell. In grid-forming mode, the voltage controller 1230 is controlling the voltage, and in grid-following mode, the current controller 1240 is controlling the voltage. In either grid-following or grid-forming mode, the control signal is normalized with a reference signal and passed to the LCD 114.

Fundamental current controller 1240-1 can generate the fundamental frequency voltage reference signal Vrf based at least in part on an error that indicates a difference between the target current setpoint and the actual output current of system 100 at the fundamental frequency. For example, fundamental current controller 1240-1 can include a proportional-resonant (PR) controller, a proportional-integral-derivative (PID) controller, or other appropriate closed-loop controller, such as a proportional-integral (PI) controller. Fundamental current controller 1240-1 can include a model predictive control (MPC) controller that uses a process model to generate the fundamental frequency voltage reference signal Vrf.

In stand-alone mode, primary controller 1210 can enable both fundamental voltage controller 1230-1 and fundamental current controller 1240-1 for more dynamic control. As described above, primary controller 1210 can determine the last normal (in specification) voltage, frequency, and phase of grid 1130, e.g., the final measurement of these values before grid 1130 lost power, and control modules 108 of system 100 to output an AC waveform that has a voltage, frequency, and phase that matches the last normal voltage, frequency, and phase of grid 1130, respectively.

Fundamental voltage controller 1230-1 can regulate the output of modules 108 to match the last normal values of grid 1130. In some implementations, primary controller 1210 can receive a reference voltage from a user or external system 104 and fundamental voltage controller 1230-1 can regulate the output of modules 108 to match the reference voltage.

In some implementations, fundamental voltage controller 1230-1 generates an output AC voltage waveform based on a voltage error that indicates a difference between the voltage reference, e.g., last normal voltage or received voltage reference, and the actual output voltage of modules 108 of system 100 at the fundamental frequency. Similar to fundamental current controller 1240-1, fundamental voltage controller 1230-1 can include a closed-loop controller, e.g., a PI, PR, or PID controller, that generates an output AC voltage waveform based on the error. In another example, fundamental voltage controller 1230-1 can include an MPC controller.

The AC voltage waveform output by fundamental voltage controller 1230-1 is provided as a reference signal input to fundamental current controller 1240-1, thereby generating a reference current. Fundamental current controller 1240-1 is configured to determine the error based on a difference between the reference current and the actual output current (e.g., output AC current waveform) of modules 108 of system 100 at the fundamental frequency.

The multi-loop controller of each harmonic frequency reference signal generators 1225-2-1225-N operates in a similar manner as the multi-loop controller of fundamental frequency reference signal generator 1225-1. As described above, islanding detector 1220 can generate and provide a perturbation reference signal to one or more harmonic frequency reference signal generators 1225-2-1225-N. A respective perturbation reference signal can be provided to the voltage controller 1230 of the one or more harmonic frequency reference signal generators 1225-2-1225-N and to a combiner module 1235 of each of the one or more harmonic frequency reference signal generators 1225-2-1225-N. As the harmonic frequencies differ for the harmonic frequency reference signal generators 1225-2-1225-N, the frequency of the perturbation reference signal for each harmonic frequency reference signal generator 1225-2-1225-N also differs such that the frequency of the perturbation signal for a harmonic frequency reference signal generator 1225 matches the harmonic frequency of the harmonic frequency reference signal generator 1225.

For brevity, operations of the multi-loop controller of harmonic frequency reference signal generator 1225-2 will be described. However, each other harmonic frequency reference signal generator 1225-2 can operate in the same or a similar manner.

In either mode, harmonic frequency reference signal generator 1225-2 generates and outputs a harmonic frequency voltage reference signal based on a perturbation reference signal received from islanding detector 1220. In grid-tied mode, primary controller 1210 can disable voltage controller 1230-2 such that current controller 1240-2 generates the harmonic frequency voltage reference signal based on a difference between a reference current received from combiner module 1235-2 and the output current of system 100 at the third harmonic frequency. Combiner module 1235-2 is configured to combine an output signal from voltage controller 1230-2 and the perturbation reference signal. For example, combiner module 1235-2 can be configured to sum the output signal from voltage controller 1230-2 and the perturbation reference signal. As voltage controller 1230-2 is disabled and has an output of zero, this combination results in the perturbation reference signal.

Current controller 1240-2 can generate a harmonic frequency voltage reference signal based at least in part on an error that indicates a difference between the perturbation reference signal and the actual output current of system 100 at the third harmonic frequency. For example, current controller 1240-2 can include a PR controller, a PID controller, a PI controller, or other appropriate closed-loop controller. Current controller 1240-2 can include an MPC controller that uses a process model to generate the harmonic frequency voltage reference signal.

In stand-alone mode, primary controller 1210 can enable both voltage controller 1230-2 and current controller 1240-2. Rather than provide the perturbation reference signal to combiner module 1235-2, islanding detector 1220 provides the perturbation reference signal to voltage controller 1230-2. An algorithmic switch can provide control over the destination of the perturbation reference signal. Fundamental voltage controller 1230-1 generates an output AC voltage waveform based on a voltage error that indicates a difference between the perturbation reference signal and the actual output voltage of modules 108 of system 100 at the third harmonic frequency. Similar to fundamental voltage controller 1230-1, third harmonic voltage controller 1230-2 can include a closed-loop controller, e.g., a PI, PR, or PID controller, that generates an output AC voltage waveform based on the error. In another example, voltage controller 1230-2 can include an MPC controller.

The AC voltage waveform output by fundamental voltage controller 1230-2 is provided as a reference signal input to current controller 1240-2. Current controller 1240-2 is configured to determine the error based on a difference between the reference current and the actual output current, as in the output AC current waveform, of modules 108 of system 100 at the third harmonic frequency. Current controller 1240-2 can generate the harmonic frequency voltage reference signal based at least in part on the error. In some implementations, the current controller 1240-2 calculates, using instructions form the islanding detector, the harmonic frequency voltage reference signal, which can use a proportional resonant controller for each harmonic.

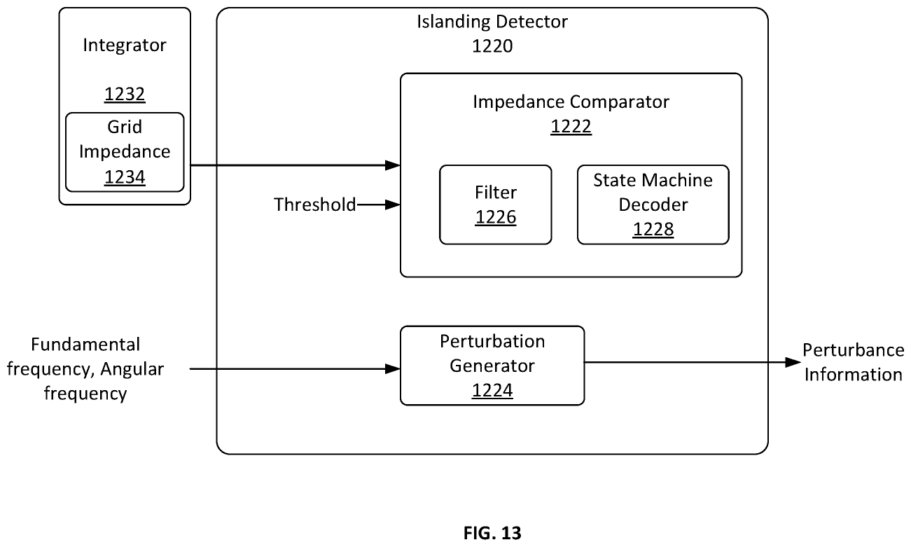

FIG. 13 is a block diagram of an example of an islanding detector 1220, such as islanding detector 1220 in FIGS. 12A and 12B. Islanding detector 1220 is configured to generate a perturbation reference signal and detect islanding conditions. Islanding detector 1220 includes an impedance comparator 1222 received from one or more integrators 1232 and a perturbation generator 1224. The integrators 1232 can, for example, include hardware components that integrate the total output impedance 1234 of system 100 corresponding to one or more harmonic frequency reference signals over a predetermined period of time. Generally, impedance depends on frequency, so the integrators 1232 can calculate the total impedance 1234 as a function of frequency. The integrators 1232 can be included as part of the master control device or not as part of the master control device. The integrators 1232 can include a field programmable gate array (FPGA) processor on the MCD 112.

Impedance comparator 1222 is configured to receive data indicating impedance measurements that each represent a measure of an output impedance of modules 108 of system 100. Impedance comparator 1222 can compare each impedance measurement, e.g., the impedance for each harmonic signal injected onto an output of at least one module of the array of modules, to an impedance threshold. If an impedance measurement satisfies the impedance threshold, e.g., by equaling or exceeding the impedance threshold, the islanding detector 1222 can determine that an islanding condition is present, e.g., that system 100 is experiencing an islanding condition.

In some implementations, the impedance comparator 1222 can determine that an islanding condition is present if a particular, higher-order harmonic signal, e.g., a fifth harmonic, satisfies the impedance threshold for the particular, higher-order harmonic, even if lower-order harmonic signals do not satisfy their respective impedance threshold.

In some implementations, the impedance threshold is an adjustable value. For example, a user may be able to adjust the impedance threshold using a GUI or other interface of a terminal communicably coupled to system 100 and/or a user interface of the system 100. As some grids 1130 have different characteristics, e.g., different normal operation impedance values, than others, enabling impedance threshold adjustments allows system 100 having islanding detector 1220 to be used on grids having different characteristics. In some implementations, machine learning techniques can be used to determine the impedance threshold. For example, a machine learning module can learn what impedance threshold best suits certain times of day or seasons from historical data. If a common impedance threshold was used on every grid 1130, islanding detector 1220 may always detect an islanding condition when connected to grids 1130 that have a normal operating impedance that exceeds the common impedance threshold.

In some implementations, the impedance comparator 1222 includes a filter 1226, such as a digital filter, for filtering feedback signals, e.g., noise from loads in the grid that causes nonzero impedance measurements for a disconnected module 108 that should have a zero impedance measurement. For example, overloads occurring in the grid can lead to high-order harmonic signals external to the modules 108. Alternatively, or in addition, power supplies connected to the grid can cause the generation of high-order harmonic signals external to the modules 108. The term “order” in high-order harmonic signals refers to orders of the fundamental frequency greater than 1, e.g., for n=5, the fifth-order harmonic signal has a frequency of five times the fundamental frequency. External high-order harmonic signals can trick the impedance comparator 1222, causing it to detect an islanding condition when there is none. Accordingly, the filter 1226 can reduce the external, high-order harmonic signals processed by the impedance comparator 1222. For example, using the specified harmonic frequencies, the digital filter 1226 can adjust the bandwidth in real time to pass only specified harmonic frequencies and filter out other frequencies. In some implementations, the digital filter 1226 is based on infinite impulse response (IIR) or finite impulse response (FIR) mechanisms. The digital filter 1226 can be a band-pass filter. In some implementations, the digital filter 1226 is a low-pass filter that approximates, to first order, a band-pass filter.

Perturbation generator 1224 sends a perturbation reference signal to one or more harmonic frequency reference signal generators 1225-2 to 1225-N. Perturbation generator 1224 can be configured to send the perturbation reference signal periodically based on a specified island detection time period. In some implementations, the specified island detection time period is stored in memory of the master control device 112. In some implementations, an island detection time period is specified by a user through, e.g., the GUI or other interface of a terminal communicably coupled to system 100 and/or the user interface of the system 100, as described herein. Similarly, impedance comparator 1222 can be configured to compare each impedance measurement received between successive island detection time periods to an impedance threshold to determine whether an islanding condition is present.

The perturbation generator 1224 can calculate the waveform of the perturbation. For example, to calculate the waveform of the perturbation, the perturbation generator 1224 can receive, as input from the primary controller 1210, the fundamental frequency of the signal and the angular frequency, i. e. t, the phase angle of the fundamental frequency, and calculate as output the fifth harmonic frequency and ω_{T} for the fifth harmonic frequency, e.g., ω_{T5}=2πnƒ_{fundamental}, where n=5. Additionally, the primary controller 1210 provides the amplitude of the perturbation for reference, e.g., to compare to the amplitude of the fundamental frequency voltage reference signal. The higher the frequency of a perturbation signal, the shorter the duration of the pulse, e. g., the period, of the signal. Accordingly, in some implementations, using higher-order harmonic frequency can reduce the total pulse length of the perturbation, and thus reduce the THD.

In some implementations, the perturbation generator 1224 periodically receives input, such as the fundamental/angular frequency, from the primary controller 1210. For instance, in some implementations, the primary controller 1210 sends input to the perturbation generator 1224 in response to receiving instructions from the MCU 112.

State decoder machine 1228 will be discussed later on with reference to a process performed by the islanding detector 1220.

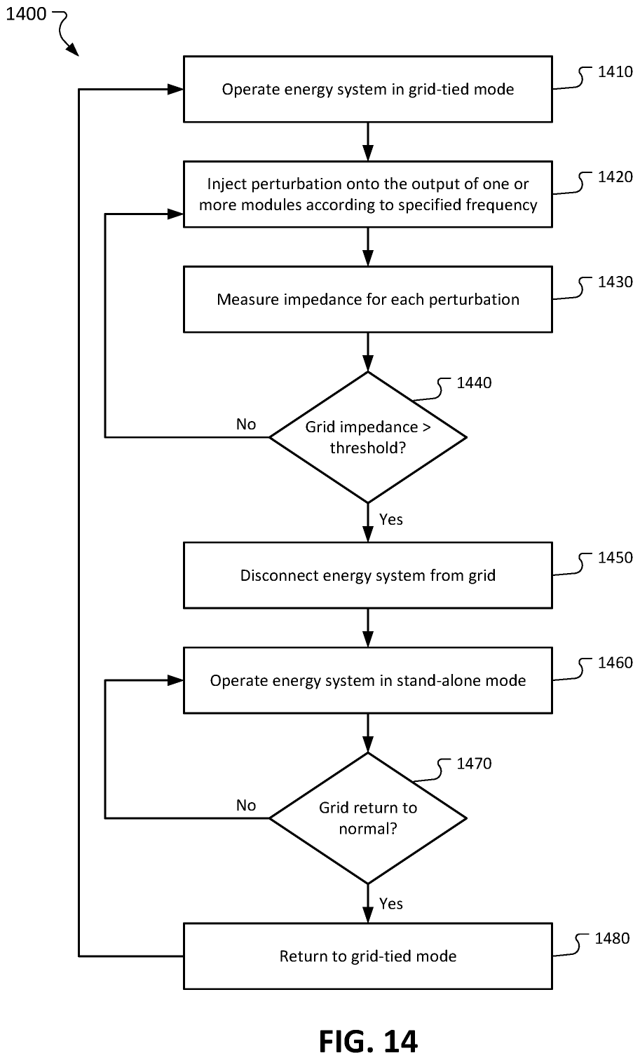

FIG. 14 is a flow diagram depicting an example method 1400 of detecting islanding conditions and operating an energy system based on whether an islanding condition is detected. Method 1400 can be performed by any one of systems 100 described herein.

As a starting point, system 100 operates (1410) in grid-tied mode. System 100 can operate in grid-tied mode when grid 1130 is operating normally, e.g., without an error or other condition that causes system 100 to disconnect from grid 1130.

System 100 periodically injects (1420) a perturbation signal, e.g., a perturbation voltage or current, onto the output of one or modules 108 of system 100. System 100 can inject the perturbation system onto the output of modules 108 by adjusting control information sent to one or more modules 108 of system 100. For example, system 100 can adjust the normalized reference signal (Vrn or Irn) for the one or more modules 108 to include an increased current amplitude at a specified harmonic frequency, as described with reference to FIG. 12.

System 100 measures (1430) an output impedance of modules 108 of system 100 for the time period during which the perturbation current is output by modules 108. The measured impedance can be the impedance at one or more specified harmonic frequencies. For example, the impedance can be determined based on the output voltage of modules 108 at the specified harmonic frequency and the output current of modules 108 at the specified harmonic frequency.

Measuring the output impedance of modules 108 can include measuring the current of the modules 108 and determining the output impedance from the derivative of the output voltage of the modules 108 with respect to the output current. In some implementations, measuring the current of modules 108 includes performing a direct-quadrature-zero transformation, e.g., a Park transformation, on an ABC-format (three phase coordinate system) measurement of the current to convert to a DQ0-format (rotating vector coordinate system with one changeable vector projection) measurement to rotate a reference frame of AC signals into a reference signal for DC signals. In some implementations, there is an intermediate format, e.g., ABO (stationary vector coordinate system, with changeable two vector projections). Performing the direct-quadrature-zero-transformation can simplify analysis, e.g., yield a single vector for voltage and current for a single phase rather than two vectors.

In some implementations, system 100 stores the magnitude of the impedance for each harmonic signal corresponding to each module for use in debugging later, e.g., determining the cause of the islanding condition.

System 100 compares (1440) the measured impedance to a threshold impedance to determine whether the measured impedance satisfies the impedance threshold, e.g., by equaling or exceeding the impedance threshold. If the measured impedance satisfies the impedance threshold, system 100 can determine that an islanding condition is present. If not, system 100 can determine that an islanding condition is not present and continue periodically injecting the perturbation current and measuring the impedance to check whether an islanding condition is present.

In some implementations, the system 100 compares the measured impedance of modules 108 of system 100 for each injected harmonic of the signal to a respective threshold impedance for each harmonic. Impedance measurements corresponding to higher-order harmonics can be weighted more heavily in determining whether an islanding condition is present. For example, if the impedance for the fifth-order harmonic satisfies the fifth-order threshold impedance while the impedance for the second-order harmonic does not satisfy the second-order threshold impedance, the system 100 can determine that an islanding condition is present. In some implementations, the impedance measurements corresponding to the fundamental frequency are more likely to be unrelated to a perturbation generated by the islanding detector 1220 because the fundamental frequency is closer to the operating frequency of other components on the grid. Consequently, impedance measurements for higher order frequencies can be more likely to have been created by the islanding detector 1220 and are weighted more heavily.

If system 100 determines (1440 “yes”) that an islanding condition is present, system 100 can disconnect (1450) from grid 1130. For example, system 100 can open a contactor 1115-3 that selectively connects system 100 and load 101 to grid 1130.

System 100 can also transition to stand-alone mode. During grid-tied mode, system 100 can measure the voltage, frequency, and phase of power on grid 1130, e.g., using a phase-locked loop (PLL) of system 100. For example, system 100 can use a PLL to track the phase of grid 1130 in grid-tied mode. System 100 can store these measurements such that system 100 can identify the last normal voltage, frequency, and phase of grid 1130 before the islanding condition was detected. As part of the transition to stand-alone mode, system 100 can enable the outer voltage control loop, e.g., by enabling fundamental voltage controller 1230-1 and disable PLL tracking.

System 100 operates (1460) in stand-alone mode. In stand-alone mode, system 100 regulates an output voltage of modules 108 to match the last normal voltage, frequency, and phase of grid 1130. System 100 can operate in stand-alone mode to provide power to load 101, e.g., until grid 1130 returns to normal operation.

In some implementations, the system 100 can use a state machine decoder 1228 to inject a digital signal, e.g., switch from current mode to voltage mode, to continue monitoring the impedance of a module 108 even when the module 108 is disconnected from the grid 1130. In some implementations, the state machine decoder 1228 changes filter coefficients of the allowed frequencies in the bandwidth of the digital filter 1226.

System 100 determines (1470) whether grid has returned to normal operation. System 100 can be configured to monitor grid 1130 to determine whether power has returned to grid 1130. If not, system 100 continues to operate in stand-alone mode.

If grid 1130 has returned to normal operation, system 100 can return (1480) to grid-tied mode. For example, system 100 can enable PLL tracking to track the phase of grid 1130. PLL detects the phase and voltage mode output is synchronized with grid 1130. In some implementations, system 100 can remain in voltage control mode until contactor 1115-3 is closed. In this example, system 100 can disable fundamental voltage controller 1230-1 after contactor 1115-3 is closed and enable fundamental current controller 1240-1. System 100 can also enable island detector 1220 while in grid-tied mode.

In some implementations, the system 100 can reset all used integrators that can accumulate error between steps 1450 and 1480. For example, while the system 100 is in idle mode, the system 100 can detect noise signals coming from external loads connected to the grid. These noise signals can erroneously lead to incorrect impedance values, as the impedance of disconnected modules should be zero. Accordingly, the impedance comparator 1222 can use causal control to reset any nonzero impedance and current values determined by the system while the system is in idle mode. For example, the impedance comparator 1222 can have in-memory instructions to set impedance measurements for a particular module to zero when the particular module is disconnected from the grid.

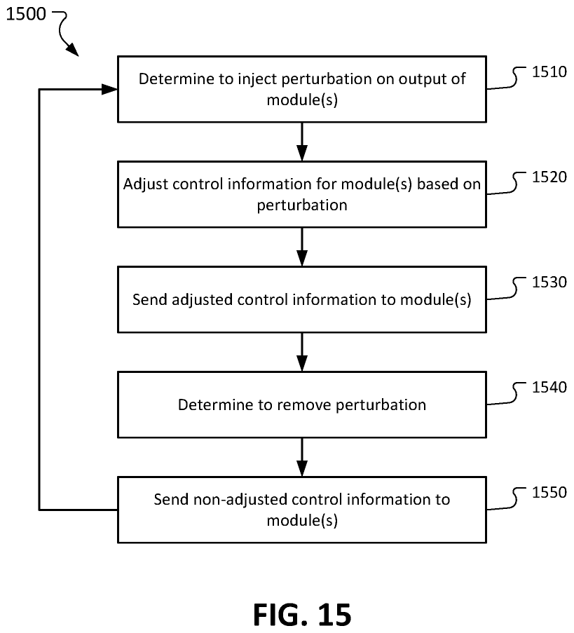

FIG. 15 is a flow diagram depicting an example method 1500 of adjusting control information for one or more modules 108 to inject a perturbation signal on the output of the one or more modules 108. Method 1500 can be performed by any one of systems 100 described herein.

System 100 determines (1510) to inject a perturbation signal on the output of module(s) 108. As described herein, system 100 can cause module(s) 108 to inject the perturbation signal periodically based on a specified island detection time period. Each time this island detection time period lapses, system 100 can determine to inject the perturbation signal on the output of module(s) 108. The perturbation signal can have a specified amplitude and be at a specified harmonic frequency.

System 100 adjusts (1520) control information for module(s) 108 based on the perturbation signal. As described herein, system 100 can adjust the normalized reference signal (Vrn or Irn) for module(s) 108 to include an increased amplitude at a specified harmonic frequency, as described with reference to FIG. 12.

System 100 sends (1530) the adjusted control information to module(s) 108. As described herein, each module 108 can use the control information to operate switches to generate an output AC waveform.

System 100 determines (1540) to remove the perturbation signal. For example, system 100 can be configured to inject the perturbation signal for a short perturbation time period time, e.g., in milliseconds, for each island detection time period to measure an output impedance of system 100 at a specified harmonic frequency. When this time perturbation time period lapses, system 100 can determine to remove the perturbation signal from the output of module(s) 108.

System sends (1550) non-adjusted control information to module(s) 108. For example, system 100 can send the normalized reference signal (Vrn or Irn) for module(s) 108 without the adjustment for the perturbation signal along with a modulation index Mi for each module 108. Method 1500 can be performed repetitively, e.g., while in grid-tied mode, to detect islanding conditions.

Various aspects of the present subject matter are set forth below, in review of, and/or in supplementation to, the implementations described thus far, with the emphasis here being on the interrelation and interchangeability of the following implementations. In other words, an emphasis is on the fact that each feature of the implementations can be combined with each and every other feature unless explicitly stated or taught otherwise.

In many embodiments, the energy system configured to connect to a power grid includes an array of cascaded modules that each output a respective voltage waveform, each module including a local control device; and a master control device communicably coupled to each local control device over a communication interface and including: one or more harmonic controllers configured to periodically cause one or more of the modules to output an increased voltage at a specified harmonic frequency by periodically adjusting control information sent to the local control device of each of the one or more modules according to a specified island detection time period; and an islanding detector configured to detect, based on an output impedance of the modules, when the array of cascaded modules is in an island condition.

In many embodiments, the energy system configured to connect to a power grid includes one or more modules that each output a respective voltage waveform to a load; a controller configured to periodically cause at least a portion of the one or more modules to output an increased voltage at a specified harmonic frequency; and an islanding detector configured to detect, based on an impedance of the grid, when the one or more modules are in an island condition.

In many embodiments, energy system configured to connect to a power grid includes an array of cascaded modules that are each configured to output a respective voltage waveform to a load, each module including a local control device; and a master control device communicably coupled to each local control device over a communication interface. The master control device is configured to: cause one or more of the modules to generate an output signal with a perturbation component; measure or cause measurement of impedance of the power grid during application of the output signal with a perturbation component to the grid; and determine whether an island condition exists based on the impedance measurement and perturbation component.

In many embodiments, a method of detecting an island condition includes controlling, by a master control device, an array of cascaded modules to output a respective voltage waveform to a load, each module including a local control device; controlling, by one or more harmonic controllers of the master control device, one or more of the modules to periodically output an increased voltage at a specified harmonic frequency by periodically adjusting control information sent to the local control device of each of the one or more modules according to a specified island detection time period; and detecting, by an islanding detector of the master control device, based on an output impedance of the modules, when the array of cascaded modules is in an island condition.

In many embodiments, a method of detecting an island condition includes controlling one or more modules to each output a respective voltage waveform to a load; periodically causing at least a portion of the one or more modules to output an increased voltage at a specified harmonic frequency; and detecting, based on an impedance of the grid, when the one or more modules are in an island condition.

In many embodiments, a method of detecting an island condition includes controlling an array of cascaded modules to each output a respective voltage waveform to a load, each module including a local control device; and causing, by a master control device communicably coupled to each local control device over a communication interface, one or more of the modules to generate an output signal with a perturbation component; measuring or causing measurement of impedance of the power grid during application of the output signal to the grid; and determining whether an island condition exists based on the impedance measurement.

In some embodiments, the energy system further includes an impedance measurement circuit configured to: measure an output impedance of the modules at the specified harmonic frequency; and periodically provide, to the islanding detector and based on the specified island detection time period, data indicating the output impedance of the modules.

In some embodiments, the output impedance of the modules at the specified harmonic frequency is a sum of output impedances of each module in the energy system at the specified harmonic frequency.

In some embodiments, the output impedance of the modules at the specified harmonic frequency is a sum of output impedances of a subset of modules in the energy system at the specified harmonic frequency.

In some embodiments, the master control device is configured to, in response to the islanding detector detecting that the array of cascaded modules is in the island condition, disconnect the array of cascaded modules from the grid; obtain data indicating a last normal voltage frequency and voltage phase of the grid; and send instructions to a harmonic controller of the one or more harmonic controllers to control the respective voltage waveform output to the load by each module based on the last normal voltage phase and the last normal voltage frequency.

In some embodiments, the master control device is configured to receive data indicating that the grid has returned to normal operation and, in response, obtain data indicating a present voltage phase and present voltage frequency of the grid; reconnect the array of cascaded modules to the grid; and send instructions to the one or more harmonic controllers to control the respective voltage waveform provided to the load by the array of cascaded modules.

In some embodiments, the master control device is configured to send, to each local control device over the communication interface, the control information that instructs the local control device to operate switch circuitry to output the respective voltage waveform.

In some embodiments, the control information sent to each local control device includes a normalized reference signal for each module of the array of cascaded modules and, for at least one module, a modulation index used by the at least one module to scale the normalized reference signal.

In some embodiments, the normalized reference signal represents (i) a fundamental frequency and (ii) a voltage at a specified harmonic frequency.

In some embodiments, the (i) a fundamental frequency and (ii) a voltage at a specified harmonic frequency are measured concurrently.

In some embodiments, the master control device is configured to periodically send the control information to each local control device such that the control information is sent to each local control device multiple times during each specified island detection time period. Periodically adjusting the control information sent to the local control device of each of the one or more modules according to a specified island detection time period includes, for a first sub-period of each recurring time period, sending, to each local control device, control information that includes a normalized reference signal with the harmonic voltage at a first magnitude; and for a second sub-period of each recurring time period, sending, to each local control device, adjusted control information that includes an adjusted harmonic voltage at a second magnitude greater than the first magnitude.

In some embodiments, the one or more harmonic controllers include a fundamental frequency reference signal generator configured to generate a voltage reference signal at a fundamental frequency.

In some embodiments, the one or more harmonic controllers include one or more harmonic frequency reference signal generators each configured to generate a harmonic frequency voltage reference signal at a respective harmonic frequency relative to the fundamental frequency.

In some embodiments, the master controller includes a signal combiner that generates the control information by combining the fundamental frequency voltage reference signal with the harmonic frequency voltage reference signal of at least one of the one or more harmonic frequency reference signal generators.

In some embodiments, the one or more harmonic frequency reference signal generators include multiple harmonic frequency reference signal generators, the master controller further including a primary controller configured to select between the multiple harmonic frequency reference signal generators for generating the harmonic frequency voltage reference signal that is combined with the fundamental frequency voltage reference signal.

In some embodiments, each harmonic controller of the one or more harmonic controllers includes a multi-loop controller including an outer voltage control loop and an inner current control loop.

In some embodiments, the islanding detector is configured to obtain one or more baseline impedance measurements of the energy system at the specified harmonic frequency.

In some embodiments, the islanding detector is configured to detect when the array of cascaded modules is in the island condition based on the output impedance of the modules, the one or more baseline impedance measurements, and an impedance threshold.

In some embodiments, the islanding detector includes a filter configured to remove parasitic signals from the output impedance of the modules, wherein the parasitic signals originate from sources external to the modules.

In some embodiments, the islanding detector includes a state machine decoder configured to determine filter coefficients for removing frequencies in the output impedance of the modules.

In some embodiments, the energy system further includes a master control device that includes the controller and the islanding detector. Each module of the one or more modules includes a local control device configured to operate switch circuitry based on control information received from the master control device.

In some embodiments, the control information received by each local control device includes a normalized reference signal for the module and a modulation index used by the local control device to scale the normalized reference signal.

In some embodiments, the normalized reference signal represents a voltage at a fundamental frequency and a voltage at a specified harmonic frequency.

In some embodiments, the controller includes a fundamental frequency voltage reference signal generator configured to generate a voltage reference signal at a fundamental frequency.

In some embodiments, the controller includes one or more harmonic frequency reference signal generators each configured to generate a harmonic frequency voltage reference signal at a respective harmonic frequency relative to the fundamental frequency.

In some embodiments, the energy system further includes a signal combiner that (i) generates the control information for each of the one or more modules by combining the fundamental frequency voltage reference signal with the harmonic frequency voltage reference signal of at least one of the one or more harmonic frequency reference signal generators, and (ii) sends the control information for each of the one or more modules to the one or more local control devices.

In some embodiments, the one or more harmonic frequency reference signal generators include multiple harmonic frequency reference signal generators, the energy system further including a primary controller configured to select between the multiple harmonic frequency reference signal generators for generating the harmonic frequency voltage reference signal that is combined with the fundamental frequency voltage reference signal.

In some embodiments, the energy system further includes an impedance measurement circuit configured to measure an output impedance of the modules at the specified harmonic frequency; and periodically provide, to the islanding detector, data indicating the impedance of the grid.

In some embodiments, the islanding detector is configured to obtain one or more baseline impedance measurements at the specified harmonic frequency.

In some embodiments, the islanding detector is configured to detect when one or more modules are in the island condition based on the impedance of the grid, the one or more baseline impedance measurements, and an impedance threshold.

In some embodiments, the master control device is configured to cause the one or more modules to generate the output signal with the perturbation component by sending, each local control device, control information including a normalized reference signal and a modulation index used by the local control device to scale the normalized reference signal.

In some embodiments, the normalized reference signal represents a voltage at a fundamental frequency and a voltage at the specified harmonic frequency.

In some embodiments, the master control device includes a fundamental frequency voltage reference signal generator configured to generate a voltage reference signal at a fundamental frequency.

In some embodiments, the master control device includes one or more harmonic frequency reference signal generators each configured to generate a harmonic frequency voltage reference signal at a respective harmonic frequency relative to the fundamental frequency.

In some embodiments, the master controller includes a signal combiner that (i) generates control information for each of the one or more modules by combining the fundamental frequency voltage reference signal with the harmonic frequency voltage reference signal of at least one of the one or more harmonic frequency reference signal generators, and (ii) sends the control information for each of the one or more modules to the one or more local control devices.

In some embodiments, the one or more harmonic frequency reference signal generators include multiple harmonic frequency reference signal generators, the master control device further including a primary controller configured to select between the multiple harmonic frequency reference signal generators for generating the harmonic frequency voltage reference signal that is combined with the fundamental frequency voltage reference signal.

In some embodiments, the master control device is configured to obtain one or more baseline impedance measurements of the energy system at the specified harmonic frequency.

In some embodiments, the master control device is configured to detect that the island condition exists based on the impedance of the power grid, the one or more baseline impedance measurements, and an impedance threshold.

In some embodiments, the output signal includes an AC waveform having a fundamental frequency. The perturbation component includes an increased voltage or current at a specific harmonic frequency of the fundamental frequency.

In some embodiments, the method further includes controlling an impedance measurement circuit to measure an output impedance to the modules at the specified harmonic frequency; and controlling the impedance measurement circuit to periodically provide, to the islanding detector and based on the specified island detection time period, data indicating the output impedance of the modules.

In some embodiments, the method further includes, in response to detecting that the array of cascaded modules is in the island condition, disconnecting the array of cascaded modules from the grid; obtaining data indicating a last normal phase of voltage of the grid and a last normal frequency of the voltage of the grid; and enabling a voltage controller to control the respective voltage waveform output to the load by each module based on the last normal phase and the last normal frequency.

In some embodiments, the method further includes receiving data indicating that the grid has returned to normal operation; obtaining data indicating a present phase of the voltage of the grid and a present frequency of the voltage of the grid; reconnecting the array of cascaded modules to the grid; disabling the voltage controller; and enabling the one or more harmonic controllers to control current provided to the grid by the array of cascaded modules.

In some embodiments, the method further includes sending, by the master control device and to each local control device over the communication interface, the control information that instructs the local control device to operate switch circuitry to cause the array output the respective voltage waveform.

In some embodiments, the control information sent to each local control device includes a normalized reference signal for each module of the array of cascaded modules and, for at least one module, a modulation index used by the at least one module to scale the normalized reference signal.

In some embodiments, the normalized reference signal represents a fundamental frequency a voltage at a specified harmonic frequency.

In some embodiments, the normalized reference signal represents a current at the specified harmonic frequency.

In some embodiments, the master control device periodically sends the control information to each local control device such that the control information is sent to each local control device multiple times during each specified island detection time period, and periodically adjusting the control information sent to the local control device of each of the one or more modules according to a specified island detection time period includes, for a first sub-period of each recurring time period, sending, to each local control device, control information that includes a normalized reference signal with the harmonic voltage and/or current level at a first magnitude; and for a second sub-period of each recurring time period, sending, to each local control device, adjusted control information that includes an adjusted harmonic voltage and/or current level at a second magnitude greater than the first magnitude.

In some embodiments, the method further includes generating, by a fundamental frequency reference signal generator of the one or more harmonic controllers, a fundamental frequency voltage reference signal at a fundamental frequency.

In some embodiments, the method further includes generating, by each of one or more harmonic frequency reference signal generators of the one or more harmonic controllers, a harmonic frequency voltage reference signal at a respective harmonic frequency relative to the fundamental frequency.

In some embodiments, the method further includes generating, by a signal combiner, the control information by combining the fundamental frequency voltage reference signal with the harmonic frequency voltage reference signal of at least one of the one or more harmonic frequency reference signal generators.

In some embodiments, the one or more harmonic frequency reference signal generators include multiple harmonic frequency reference signal generators, the method further including selecting between the multiple harmonic frequency reference signal generators for generating the harmonic frequency voltage reference signal that is combined with the fundamental frequency voltage reference signal.

In some embodiments, each harmonic controller of the one or more harmonic controllers includes a multi-loop controller including an outer voltage control loop and an inner current control loop.

In some embodiments, the method further includes obtaining, by the islanding detector, one or more baseline impedance measurements at the specified harmonic frequency.

In some embodiments, method further includes detecting, by the islanding detector, when the array of cascaded modules is in the island condition based on the output impedance of the modules, the one or more baseline impedance measurements, and an impedance threshold

In some embodiments, method further includes controlling, by a master control device, the one or more modules to cause the portion of the one or more modules to output the increased voltage at the specified harmonic frequency; and detecting, by an island detector, that the one or more modules are in the island condition. Each module of the one or more modules includes a local control device configured to operate switch circuitry based on control information received from the master control device

In some embodiments, the control information received by each local control device includes a normalized reference signal for the module and a modulation index used by the local control device to scale the normalized reference signal.

In some embodiments, the normalized reference signal represents a fundamental voltage for a fundamental frequency and a harmonic voltage for the specified harmonic frequency.

In some embodiments, the method further includes generating, by a fundamental frequency voltage reference signal generator, a fundamental frequency voltage reference signal at a fundamental frequency.

In some embodiments, the method further includes generating, by one or more harmonic frequency reference signal generators, a harmonic frequency voltage reference signal at a respective harmonic frequency relative to the fundamental frequency.

In some embodiments, the method further includes generating control information for each of the one or more modules by combining the fundamental frequency voltage reference signal with the harmonic frequency voltage reference signal of at least one of the one or more harmonic frequency reference signal generators.

In some embodiments, the one or more harmonic frequency reference signal generators include multiple harmonic frequency reference signal generators, the method further including selecting between the multiple harmonic frequency reference signal generators for generating the harmonic frequency voltage reference signal that is combined with the fundamental frequency voltage reference signal.

In some embodiments, the method further includes measuring, by an impedance measurement circuit and as the impedance of the grid, an output impedance to the modules at the specified harmonic frequency; and periodically providing, to the islanding detector, data indicating the impedance of the grid.

In some embodiments, the method further includes obtaining one or more baseline impedance measurements of the array of cascaded modules at the specified harmonic frequency.

In some embodiments, detecting, based on an impedance of the grid, when the one or more modules are in an island condition includes detecting when one or more modules are in the island condition based on the impedance of the grid, the one or more baseline impedance measurements, and an impedance threshold.

In some embodiments, causing the one or more modules to generate the output signal with the perturbation component includes sending, to the local control device of each module, control information including a normalized reference signal for the module and a modulation index used by the local control device to scale the normalized reference signal.

In some embodiments, the normalized reference signal represents a fundamental voltage for a fundamental frequency and a harmonic voltage for the specified harmonic frequency.

In some embodiments, the method further includes generating, by a fundamental frequency voltage reference signal generator, a voltage reference signal at a fundamental frequency.

In some embodiments, generating, by each of one or more harmonic frequency reference signal generators, a harmonic frequency voltage reference signal at a respective harmonic frequency relative to the fundamental frequency.

In some embodiments, the method further includes generating control information for each of the one or more modules by combining the voltage reference signal with the harmonic frequency voltage reference signal of at least one of the one or more harmonic frequency reference signal generators.

In some embodiments, the one or more harmonic frequency reference signal generators include multiple harmonic frequency reference signal generators, the method further including selecting between the multiple harmonic frequency reference signal generators for generating the harmonic frequency voltage reference signal that is combined with the voltage reference signal.

In some embodiments, the method further includes obtaining one or more baseline impedance measurements of the array of cascaded modules at the specified harmonic frequency.

In some embodiments, determining whether an island condition exists includes detecting that the island condition exists based on the impedance of the power grid, the one or more baseline impedance measurements, and an impedance threshold.

In some embodiments, the output signal includes an AC waveform having a fundamental frequency. The perturbation component includes an increased voltage or current at a specific harmonic frequency of the fundamental frequency.

In some embodiments, the method further includes, after determining whether the island condition exists based on the impedance measurement, resetting integrators used in the measurement of impedance of the power grid.

The term “module” as used herein refers to one of two or more devices or sub-systems within a larger system. The module can be configured to work in conjunction with other modules of similar size, function, and physical arrangement (e.g., location of electrical terminals, connectors, etc.). Modules having the same function and energy source(s) can be configured identical (e.g., size and physical arrangement) to all other modules within the same system (e.g., rack or pack), while modules having different functions or energy source(s) may vary in size and physical arrangement. While each module may be physically removable and replaceable with respect to the other modules of the system (e.g., like wheels on a car, or blades in an information technology (IT) blade server), such is not required. For example, a system may be packaged in a common housing that does not permit removal and replacement any one module, without disassembly of the system as a whole. However, any and all implementations herein can be configured such that each module is removable and replaceable with respect to the other modules in a convenient fashion, such as without disassembly of the system.

The term “master control device” is used herein in a broad sense and does not require implementation of any specific protocol such as a master and slave relationship with any other device, such as the local control device.

The term “output” is used herein in a broad sense, and does not preclude functioning in a bidirectional manner as both an output and an input. Similarly, the term “input” is used herein in a broad sense, and does not preclude functioning in a bidirectional manner as both an input and an output.

The terms “terminal” and “port” are used herein in a broad sense, can be either unidirectional or bidirectional, can be an input or an output, and do not require a specific physical or mechanical structure, such as a female or male configuration.

Processing circuitry can include one or more processors, microprocessors, hardware controllers, and/or microcontrollers, each of which can be a discrete or stand-alone chip or distributed amongst (and a portion of) a number of different chips. Any type of processing circuitry can be implemented, such as, but not limited to, personal computing architectures (e.g., such as used in desktop PC's, laptops, tablets, etc.), programmable gate array architectures, proprietary architectures, custom architectures, and others. Processing circuitry can include a digital signal processor, which can be implemented in hardware and/or software. Processing circuitry can execute software instructions stored on memory that cause processing circuitry to take a host of different actions and control other components.

Processing circuitry can also perform other software and/or hardware routines. For example, processing circuitry can interface with communication circuitry and perform analog-to-digital conversions, encoding and decoding, other digital signal processing, multimedia functions, conversion of data into a format (e.g., in-phase and quadrature) suitable for provision to communication circuitry, and/or can cause communication circuitry to transmit the data (wired or wirelessly).

Processing circuitry can also be adapted to execute the operating system and any software applications, and perform those other functions not related to the processing of communications transmitted and received.

Computer program instructions for carrying out operations in accordance with the described subject matter may be written in any combination of one or more programming languages, including computer and programming languages. A non-exhaustive list of examples includes hardware description languages (HDLs), SystemC, C, C++, C #, Objective-C, Matlab, Simulink, SystemVerilog, SystemVHDL, Handel-C, Python, Java, JavaScript, Ruby, HTML, Smalltalk, Transact-SQL, XML, PHP, Golang (Go), “R” language, and Swift, to name a few.

Memory, storage, and/or computer readable media can be shared by one or more of the various functional units present, or can be distributed amongst two or more of them (e.g., as separate memories present within different chips). Memory can also reside in a separate chip of its own.

To the extent the embodiments disclosed herein include or operate in association with memory, storage, and/or computer readable media, then that memory, storage, and/or computer readable media are non-transitory. Accordingly, to the extent that memory, storage, and/or computer readable media are covered by one or more claims, then that memory, storage, and/or computer readable media is only non-transitory. The terms “non-transitory” and “tangible” as used herein, are intended to describe memory, storage, and/or computer readable media excluding propagating electromagnetic signals, but are not intended to limit the type of memory, storage, and/or computer readable media in terms of the persistency of storage or otherwise. For example, “non-transitory” and/or “tangible” memory, storage, and/or computer readable media encompasses volatile and non-volatile media such as random access media (e.g., RAM, SRAM, DRAM, FRAM, etc.), read-only media (e.g., ROM, PROM, EPROM, EEPROM, flash, etc.) and combinations thereof (e.g., hybrid RAM and ROM, NVRAM, etc.) and variants thereof.

It should be noted that all features, elements, components, functions, and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and steps from different embodiments, or that substitute features, elements, components, functions, and steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

As used herein and in the appended claims, the singular forms “a,” “an,” and “the” include plural referents unless the context clearly dictates otherwise.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, steps, or elements of the embodiments may be recited in or added to the claims, as well as negative limitations that define the inventive scope of the claims by features, functions, steps, or elements that are not within that scope.

1. An energy system configured to connect to a power grid, the energy system comprising:
an array of cascaded modules that each output a respective voltage waveform, each module comprising a local control device; and
a master control device communicably coupled to each local control device over a communication interface and comprising:
one or more harmonic controllers configured to periodically cause one or more of the modules to output an increased voltage at a specified harmonic frequency by periodically adjusting control information sent to the local control device of each of the one or more modules according to a specified island detection time period; and
an islanding detector configured to detect, based on an output impedance of the modules, when the array of cascaded modules is in an island condition.

2. The energy system of claim 1, further comprising an impedance measurement circuit configured to:
measure an output impedance of the modules at the specified harmonic frequency; and
periodically provide, to the islanding detector and based on the specified island detection time period, data indicating the output impedance of the modules.

3. The energy system of claim 1, wherein the master control device is configured to:
in response to the islanding detector detecting that the array of cascaded modules is in the island condition:
disconnect the array of cascaded modules from the grid;
obtain data indicating a last normal voltage frequency and voltage phase of the grid; and
send instructions to a harmonic controller of the one or more harmonic controllers to control the respective voltage waveform output to a load by each module based on the last normal voltage phase and the last normal voltage frequency.

4. The energy system of claim 3, wherein the master control device is configured to:
receive data indicating that the grid has returned to normal operation and, in response:
obtain data indicating a present voltage phase and present voltage frequency of the grid;
reconnect the array of cascaded modules to the grid; and
send instructions to the one or more harmonic controllers to control the respective voltage waveform provided to the load by the array of cascaded modules.

5. The energy system of claim 1, wherein the master control device is configured to send, to each local control device over the communication interface, the control information that instructs the local control device to operate switch circuitry to output the respective voltage waveform.

6. The energy system of claim 1, wherein the control information sent to each local control device comprises a normalized reference signal for each module of the array of cascaded modules and, for at least one module, a modulation index used by the at least one module to scale the normalized reference signal.

7. The energy system of claim 6, wherein the normalized reference signal represents (i) a fundamental frequency and (ii) a voltage at a specified harmonic frequency.

8. The energy system of claim 7, wherein the (i) a fundamental frequency and (ii) a voltage at a specified harmonic frequency are measured concurrently.

9. The energy system of claim 8, wherein:
the master control device is configured to periodically send the control information to each local control device such that the control information is sent to each local control device multiple times during each specified island detection time period, and wherein
periodically adjusting the control information sent to the local control device of each of the one or more modules according to a specified island detection time period comprises:
for a first sub-period of each recurring time period, sending, to each local control device, control information that includes a normalized reference signal with the harmonic voltage at a first magnitude; and
for a second sub-period of each recurring time period, sending, to each local control device, adjusted control information that includes an adjusted harmonic voltage at a second magnitude greater than the first magnitude.

10. The energy system of claim 1, wherein the one or more harmonic controllers comprise a fundamental frequency reference signal generator configured to generate a voltage reference signal at a fundamental frequency.

11. The energy system of claim 10, wherein the one or more harmonic controllers comprise one or more harmonic frequency reference signal generators each configured to generate a harmonic frequency voltage reference signal at a respective harmonic frequency relative to the fundamental frequency.

12. The energy system of claim 11, wherein the master controller comprises a signal combiner that generates the control information by combining the fundamental frequency voltage reference signal with the harmonic frequency voltage reference signal of at least one of the one or more harmonic frequency reference signal generators.

13. The energy system of claim 12, wherein the one or more harmonic frequency reference signal generators comprise a plurality of harmonic frequency reference signal generators, the master controller further comprising a primary controller configured to select between the plurality of harmonic frequency reference signal generators for generating the harmonic frequency voltage reference signal that is combined with the fundamental frequency voltage reference signal.

14. The energy system of claim 1, wherein each harmonic controller of the one or more harmonic controllers comprises a multi-loop controller comprising an outer voltage control loop and an inner current control loop.

15. The energy system of claim 1, wherein the islanding detector is configured to obtain one or more baseline impedance measurements of the energy system at the specified harmonic frequency.

16. The energy system of claim 15, wherein the islanding detector is configured to detect when the array of cascaded modules is in the island condition based on the output impedance of the modules, the one or more baseline impedance measurements, and an impedance threshold.

17. The energy system of claim 1, wherein the islanding detector comprises a filter configured to remove signals from the output impedance of the modules that do not correspond to the modules.

18. The energy system of claim 17, wherein the islanding detector comprises a state machine decoder configured to determined filter coefficients, of the filter, for allowed frequencies in the output impedance of the modules.

19. An energy system configured to connect to a power grid, the energy system comprising:
one or more modules that each output a respective voltage waveform to a load;
a controller configured to periodically cause at least a portion of the one or more modules to output an increased voltage at a specified harmonic frequency; and
an islanding detector configured to detect, based on an impedance of the grid, when the one or more modules are in an island condition.

20. The energy system of claim 19, further comprising a master control device that includes the controller and the islanding detector, wherein each module of the one or more modules comprises a local control device configured to operate switch circuitry based on control information received from the master control device.

21.-77. (canceled)
